(19) United States
(12) Patent Application Publication
(10) Pub. No.: US 2026/0033269 A1
(43) Pub. Date: Jan. 29, 2026

(54) SUBSTRATE PROCESSING APPARATUS

(71) Applicant: SCREEN Holdings Co., Ltd., Kyoto (JP)

(72) Inventor: Hitoshi NAKAI, Kyoto-shi (JP)

(21) Appl. No.: 19/258,328

(22) Filed: Jul. 2, 2025

(30) Foreign Application Priority Data
Jul. 29, 2024 (JP) 2024-122043

(51) Int. Cl. H01L 21/67; H01L 21/677; H01L 21/687

(52) U.S. Cl. CPC H01L 21/67057; H01L 21/67742; H01L 21/68742; H01L 21/68764

(57) ABSTRACT

A substrate processing apparatus includes a chamber, a substrate holding portion, and a turning mechanism. The chamber has a first opening through which an inside and an outside communicate with each other and a substrate is carried in, and a second opening through which the inside and the outside communicate with each other and the substrate is carried out. The substrate holding portion is disposed in the chamber and holds the substrates one by one. The turning mechanism turns the substrate holding portion to move the substrate holding portion between a plurality of processing positions at which the substrate is processed with a processing liquid in the chamber.

### CROSS REFERENCE TO RELATED APPLICATIONS

This application claims the benefit of priority to Japanese Patent Application No. 2024-122043 filed on Jul. 29, 2024. The entire contents of this application are hereby incorporated herein by reference.

### BACKGROUND OF THE INVENTION

### 1. Field of the Invention

The present invention relates to a substrate processing apparatus.

### 2. Description of Related Art

Conventionally, a substrate processing apparatus for processing a substrate is known. The substrate processing apparatus is suitably used for manufacturing a semiconductor substrate. The substrate processing apparatus processes a substrate by using a processing liquid such as a chemical liquid. As such a substrate processing apparatus, a single substrate processing type substrate processing apparatus that processes substrates one by one and a batch type substrate processing apparatus that processes a plurality of substrates by immersing the substrates in a processing bath at one time are known. For example, JP 2020-126886 A discloses a single substrate processing type substrate processing apparatus including a holding and rotating portion that holds and rotates a substrate, and an ejection portion that ejects a processing liquid to the substrate that is being rotated by the holding and rotating portion.

In a single substrate processing type substrate processing apparatus, substrates are processed one by one by supplying a processing liquid to a substrate while horizontally holding and rotating the substrate. In general, since a single substrate processing type substrate processing apparatus can be downsized compared with a batch type substrate processing apparatus, the consumption amount of a processing liquid can be reduced.

However, in a conventional single substrate processing type substrate processing apparatus, generally, there is only one processing position in one chamber. Therefore, it is difficult to cope with various types of processing.

One of objects of the present invention is to provide a substrate processing apparatus capable of handling various types of processing.

### SUMMARY OF THE INVENTION

According to one aspect of the present invention, a substrate processing apparatus includes a chamber, a substrate holding portion, and a turning mechanism. The chamber has a carry-in port through which an inside and an outside of the chamber communicate with each other and a substrate is carried in and a carry-out port through which the inside and the outside communicate with each other and the substrate is carried out. The substrate holding portion is disposed in the chamber and holds the substrates one by one. The turning mechanism moves the substrate holding portion between a plurality of processing positions at which the substrate is processed with a processing liquid in the chamber by turning the substrate holding portion.

In a preferred embodiment, the substrate processing apparatus includes an immersion bath. The immersion bath is disposed at the processing position, stores the processing liquid, accommodates the substrate, and immerses the substrate in the processing liquid.

In a preferred embodiment, the substrate holding portion is turned about a turning axis. The plurality of processing positions are located on a circle centered on the turning axis.

In a preferred embodiment, the substrate holding portion is turnable one or more rotations about the turning axis.

In a preferred embodiment, the number of the plurality of processing positions is three or more. The substrate holding portion sequentially transfers the substrate to the plurality of processing positions in a predetermined turning direction about the turning axis.

In a preferred embodiment, the substrate processing apparatus includes a supporting member. The supporting member is disposed inside the chamber and supports the substrate. A support position at which the supporting member is disposed is provided inside the chamber. The support position is located closer to the carry-in port or the carry-out port than the plurality of processing positions. The substrate holding portion transfers the substrate from the support position to the processing position.

In a preferred embodiment, the plurality of processing positions include a first processing position and a second processing position. The substrate is processed with a first processing liquid at the first processing position. The substrate is processed with a second processing liquid different from the first processing liquid at the second processing position.

In a preferred embodiment, the processing liquid includes a chemical liquid. The plurality of processing positions include at least two processing positions at which the substrate is processed with the same chemical liquid.

In a preferred embodiment, the substrate holding portion processes at least two of the substrates in parallel by sequentially transferring the substrates to the at least two processing positions.

In a preferred embodiment, the plurality of processing positions include a first processing position, a second processing position, and a third processing position. The processing liquid includes a first chemical liquid, a second chemical liquid different from the first chemical liquid, and a rinse liquid. The substrate is processed with the first chemical liquid at the first processing position. The substrate is processed with the second chemical liquid at the second processing position. The substrate is processed with the rinse liquid at the third processing position.

In a preferred embodiment, at the single third processing positions, the substrate processed at the first processing position is rinsed, and the substrate processed at the second processing position is rinsed.

In a preferred embodiment, a plurality of the third processing positions are provided. The plurality of third processing positions include the third processing position at which the substrate processed at the first processing position is rinsed and the third processing position at which the substrate processed at the second processing position is rinsed.

In a preferred embodiment, the substrate holding portion horizontally holds the substrate. The substrate holding portion includes a base that is disposed above the substrate and a plurality of chuck pins that protrude downward from the base and hold a circumferential edge of the substrate.

In a preferred embodiment, the substrate processing apparatus further includes an immersion bath, a processing liquid supplying portion, and a lifting/lowering mechanism. The immersion bath is disposed at the processing position, stores the processing liquid, accommodates the substrate, and immerses the substrate in the processing liquid. The processing liquid supplying portion supplies the processing liquid to the immersion bath. The lifting/lowering mechanism relatively moves the substrate holding portion and the immersion bath in the up-down direction. The lifting/lowering mechanism immerses the substrate in the processing liquid by moving the substrate holding portion or the immersion bath in a state in which the processing liquid is stored in the immersion bath.

In a preferred embodiment, the substrate holding portion rotatably holds the substrate. The lifting/lowering mechanism immerses the substrate in the processing liquid stored in the immersion bath in a state in which the substrate holding portion rotates the substrate.

In a preferred embodiment, the lifting/lowering mechanism immerses the substrate in the processing liquid stored in the immersion bath in a state in which the processing liquid supplying portion supplies the processing liquid toward the substrate.

According to at least one aspect of the present invention, it is possible to provide a substrate processing apparatus capable of handling various types of processing.

### BRIEF DESCRIPTION OF THE DRAWINGS

FIG. 1 is a schematic plan view of a substrate processing apparatus according to a first preferred embodiment.

FIG. 2 is a block diagram of the substrate processing apparatus according to the first preferred embodiment.

FIG. 3 is a flowchart illustrating a substrate processing method according to the first preferred embodiment.

FIG. 4 is a schematic view of a substrate processing unit in the substrate processing apparatus according to the first preferred embodiment.

FIG. 5 is a schematic view illustrating a structure around a substrate holding portion and a moving mechanism of the substrate processing apparatus according to the first preferred embodiment.

FIG. 6 is a detailed flowchart illustrating the substrate processing method according to the first preferred embodiment.

FIG. 7 is a schematic view for describing the substrate processing method according to the first preferred embodiment.

FIG. 8 is a schematic view for describing the substrate processing method according to the first preferred embodiment.

FIG. 9 is a schematic view for describing the substrate processing method according to the first preferred embodiment.

FIG. 10 is a flowchart illustrating a substrate processing method of a substrate processing apparatus according to a first modification example.

FIG. 11 is a detailed flowchart illustrating the substrate processing method according to the first modification example.

FIG. 12 is a flowchart illustrating a substrate processing method of a substrate processing apparatus according to a second modification example.

FIG. 13 is a schematic plan view of a substrate processing apparatus according to a second preferred embodiment.

FIG. 14 is a schematic plan view illustrating the inside of one chamber of the substrate processing apparatus according to the second preferred embodiment.

FIG. 15 is a flowchart illustrating a substrate processing method according to the second preferred embodiment.

FIG. 16 is a schematic view of a substrate processing unit in the substrate processing apparatus according to the second preferred embodiment.

FIG. 17 is a schematic view for describing rinse processing at a processing position Q2 and a processing position Q4 according to the second preferred embodiment.

FIG. 18 is a schematic plan view illustrating the inside of one chamber of a substrate processing apparatus according to a third modification example.

FIG. 19 is a flowchart illustrating a substrate processing method according to the third modification example.

FIG. 20 is a schematic plan view of a substrate processing apparatus according to a fourth modification example.

FIG. 21 is a flowchart illustrating a substrate processing method according to the fourth modification example.

FIG. 22 is a schematic plan view illustrating the inside of one chamber of substrate processing apparatus according to a fifth modification example.

FIG. 23 is a flowchart illustrating a substrate processing method according to the fifth modification example.

FIG. 24 is a schematic view of a substrate processing unit in a substrate processing apparatus according to a third preferred embodiment.

FIG. 25 is a schematic view of the substrate processing unit in the substrate processing apparatus according to the third preferred embodiment.

FIG. 26 is a flowchart illustrating a substrate processing method according to the third preferred embodiment.

FIG. 27 is a detailed flowchart illustrating the substrate processing method according to the third preferred embodiment.

FIG. 28 is a schematic view for describing the substrate processing method at a processing position Q1 according to the third preferred embodiment.

FIG. 29 is a schematic view for describing the substrate processing method at the processing position Q1 according to the third preferred embodiment.

FIG. 30 is a schematic view for describing the substrate processing method at the processing position Q1 according to the third preferred embodiment.

FIG. 31 is a schematic view for describing the substrate processing method at the processing position Q1 according to the third preferred embodiment.

FIG. 32 is a schematic view for describing the substrate processing method at the processing position Q1 according to the third preferred embodiment.

FIG. 33 is a schematic view for describing the substrate processing method at the processing position Q1 according to the third preferred embodiment.

FIG. 34 is a schematic view for describing the substrate processing method at a processing position Q2 according to the third preferred embodiment.

FIG. 35 is a schematic view for describing the substrate processing method at the processing position Q2 according to the third preferred embodiment.

FIG. 36 is a schematic view for describing the substrate processing method at the processing position Q2 according to the third preferred embodiment.

FIG. 37 is a flowchart illustrating a substrate processing method according to a sixth modification example.

FIG. 38 is a detailed flowchart illustrating the substrate processing method according to the sixth modification example.

FIG. 39 is a schematic plan view of a substrate processing unit in a substrate processing apparatus according to a fourth preferred embodiment.

FIG. 40 is a schematic view illustrating a structure around a cleaning bath in the substrate processing apparatus according to the fourth preferred embodiment.

FIG. 41 is a schematic plan view of a substrate processing unit in a substrate processing apparatus according to a fifth preferred embodiment.

FIG. 42 is a schematic view illustrating a substrate processing apparatus according to a seventh modification example.

FIG. 43 is a schematic view illustrating a substrate processing apparatus according to an eighth modification example.

FIG. 44 is a schematic view illustrating a substrate processing apparatus according to a ninth modification example.

FIG. 45 is a flowchart illustrating a substrate processing method at one processing position according to the ninth modification example.

FIG. 46 is a schematic view illustrating a substrate processing apparatus according to a tenth modification example.

FIG. 47 is a schematic view illustrating a substrate processing apparatus according to an eleventh modification example.

FIG. 48 is a schematic view illustrating a substrate processing apparatus according to a twelfth modification example.

FIG. 49 is a schematic view illustrating a substrate processing apparatus according to a thirteenth modification example.

FIG. 50 is a schematic view illustrating a substrate processing apparatus according to a fourteenth modification example.

FIG. 51 is a schematic view illustrating a substrate processing apparatus according to a fifteenth modification example.

FIG. 52 is a schematic view illustrating a substrate processing apparatus according to a sixteenth modification example.

FIG. 53 is a schematic plan view of a substrate processing unit in a substrate processing apparatus according to a seventeenth modification example.

FIG. 54 is a schematic plan view of a substrate processing unit in a substrate processing apparatus according to an eighteenth modification example.

### DETAILED DESCRIPTION OF PREFERRED EMBODIMENTS

Hereinafter, preferred embodiments of a substrate processing apparatus according to the present invention will be described with reference to the drawings. In the drawings, the same or corresponding portions are denoted by the same reference numerals, and the description thereof will not be repeated. In the present specification, an X axis, a Y axis, and a Z axis orthogonal to each other may be described in order to facilitate understanding of the invention. In the present preferred embodiment, the X axis and the Y axis are parallel to the horizontal direction, and the Z axis is parallel to the vertical direction. For easy understanding, a processing liquid may be hatched in the drawings.

### First Preferred Embodiment

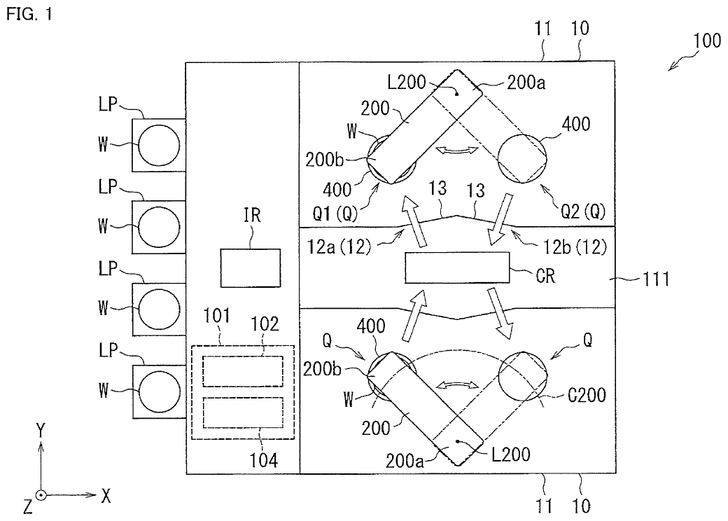

A substrate processing apparatus 100 according to a first preferred embodiment of the present invention will be described with reference to FIGS. 1 to 9. FIG. 1 is a schematic plan view of the substrate processing apparatus 100 according to the first preferred embodiment.

The substrate processing apparatus 100 processes a substrate W. The substrate processing apparatus 100 processes the substrate W to perform at least one of etching, surface processing, characteristics imparting, processing film formation, removal of at least a portion of the film, and cleaning on the substrate W.

The substrate W is used as a semiconductor substrate. The substrate W includes a semiconductor wafer. For example, the substrate W has a substantially disk shape. Here, the substrate processing apparatus 100 processes the substrates W one by one.

As illustrated in FIG. 1, the substrate processing apparatus 100 includes a plurality of substrate processing units 10, a plurality of load ports LP, an indexer robot IR, a center robot CR, and a controller 101.

The controller 101 controls the indexer robot IR and the center robot CR. The controller 101 includes a controlling portion 102 and a storage portion 104.

Each of the load ports LP stacks and accommodates a plurality of substrates W. The indexer robot IR transfers the substrate W between the load port LP and the center robot CR. The center robot CR transfers the substrate W between the indexer robot IR and the substrate processing unit 10. Each of the substrate processing units 10 ejects a processing liquid onto the substrate W to process the substrate W. The processing liquid includes, for example, a chemical liquid, a rinse liquid, a removing liquid, and/or a water repellent.

Specifically, the plurality of substrate processing units 10 form a plurality of towers disposed on both sides in the Y direction across a passage 111 through which the center robot CR passes in plan view. Each tower includes a plurality of (for example, three) substrate processing units 10 stacked one above the other.

The substrate processing apparatus 100 includes a processing liquid cabinet (not illustrated) that supplies a processing liquid to all the substrate processing units included in the substrate processing apparatus 100. The processing liquid cabinet has a pump, a nozzle, a filter and/or a tank to circulate the processing liquid.

The controller 101 controls various operations of the substrate processing apparatus 100. The controller 101 causes the substrate processing unit 10 to process the substrate W.

The controller 101 includes the controlling portion 102 and the storage portion 104. The controlling portion 102 includes a processor. The controlling portion 102 includes, for example, a central processing unit (CPU). Alternatively, the controlling portion 102 may include a general-purpose computing device.

The storage portion 104 stores data and a computer program. The data includes recipe data. The recipe data includes information indicating a plurality of recipes. Each of the plurality of recipes defines processing content and processing procedures of the substrate W. The controlling portion 102 executes the computer program stored in the storage portion 104 to execute a substrate processing operation.

The storage portion 104 includes a main storage device and an auxiliary storage device. The main storage device is, for example, a semiconductor memory. The auxiliary storage device is, for example, a semiconductor memory and/or a hard disk drive. The storage portion 104 may include a removable medium. The controlling portion 102 executes the computer program stored in the storage portion 104 to execute the substrate processing operation.

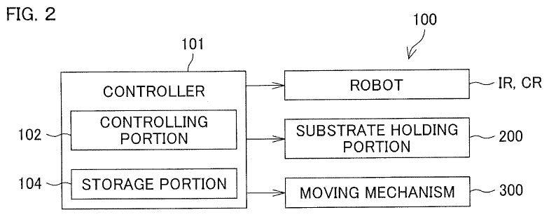

Subsequently, the substrate processing unit 10 will be described with reference to FIG. 1. As illustrated in FIG. 1, the substrate processing unit 10 includes a chamber 11, a substrate holding portion 200, a moving mechanism 300 (see FIG. 2), and an immersion bath 400.

The chamber 11 has a substantially box shape having an internal space. The chamber 11 accommodates the substrates W. Here, the substrate processing apparatus 100 is of a single substrate processing type of processing the substrates W one by one. The substrate W is accommodated in the chamber 11 and processed in the chamber 11. The chamber 11 accommodates the substrate holding portion 200, the moving mechanism 300 (see FIG. 2), and the immersion bath 400. An opening 12 through which the substrate W is carried in or out by the center robot CR is formed at a predetermined position of a side wall that partitions the inside and the outside (here, the passage 111) of the chamber 11. The opening 12 allows the inside of the chamber 11 and the passage 111 to communicate with each other and the substrate W to pass through the opening 12. A shutter 13 that opens and closes the opening 12 is provided at a predetermined position on the side wall of the chamber 11.

The substrate holding portion 200 holds the substrate W. Specifically, the substrate holding portion 200 holds the substrates W one by one. The substrate holding portion 200 horizontally holds the substrate W so that an upper surface (front surface) of the substrate W faces upward and a lower surface (rear surface) of the substrate W faces vertically downward. The substrate holding portion 200 rotates the substrate W while holding the substrate W. For example, a laminated structure in which a recess is formed is provided on the upper surface (front surface) of the substrate W. The detailed structure of the substrate holding portion 200 will be described later.

The moving mechanism 300 (see FIG. 2) moves the substrate holding portion 200. Specifically, the moving mechanism 300 turns the substrate holding portion 200. The moving mechanism 300 turns the substrate holding portion 200 about a turning axis L200 extending in the vertical direction. The turning axis L200 may be located inside or outside the substrate holding portion 200 in plan view. In the present preferred embodiment, the substrate holding portion 200 has a substantially rectangular shape in plan view having a basal end portion 200a and a distal end portion 200b. The turning axis L200 is located at the basal end portion 200a of the substrate holding portion 200. The distal end portion 200b of the substrate holding portion 200 is located above the substrate W and holds the substrate W.

In addition, the moving mechanism 300 moves the substrate holding portion 200 in the vertical direction. That is, the moving mechanism 300 lifts and lowers the substrate holding portion 200. The moving mechanism 300 includes, for example, a ball screw mechanism and an electric motor that applies a driving force to the ball screw mechanism. A detailed structure of the moving mechanism 300 will be described later.

In the substrate processing unit 10, there are a plurality of processing positions Q at which the substrate W is processed with the processing liquid. The plurality of processing positions Q are provided in the chamber 11. In the present preferred embodiment, the plurality of (here, two) processing positions Q are provided in each chamber 11.

For example, among the plurality of processing positions Q, the substrate W is subjected to an immersion processing with the processing liquid at least at one processing position Q. In the present preferred embodiment, the substrate W is subjected to the immersion processing with the processing liquid at each processing position Q. Specifically, the substrate processing unit 10 includes the immersion bath 400 disposed at each processing position Q. The immersion bath 400 stores a processing liquid.

The plurality of processing positions Q are located on a circle C200 centered on the turning axis L200 of the substrate holding portion 200. That is, distances from the turning axis L200 to the plurality of processing positions Q are substantially equal. Thus, the substrate holding portion 200 turns about the turning axis L200, so that the substrate W can be easily delivered to, for example, a member (here, the immersion bath 400) at any processing position Q.

In addition, for example, in each chamber 11, the plurality of (here, two) processing positions Q include at least two processing positions Q at which the substrate W is processed with different chemical liquids. In the present preferred embodiment, in each chamber 11, the substrate W is processed with chemical liquids different from each other at the two processing positions Q. In the present preferred embodiment, different chemical liquids indicate that the chemical liquids are not the same chemical liquid. In the present preferred embodiment, the same chemical liquid indicates that, for example, the kinds and/or components of chemical liquids are the same.

In the present preferred embodiment, the substrate holding portion 200 sequentially transfers the substrate W to at least two (here, two) processing positions Q where the substrate W is processed with different chemical liquids. That is, the substrate holding portion 200 transfers the substrate W to one processing position Q, and then transfers the substrate W to the other processing position Q from the one processing position Q.

In the present preferred embodiment, the plurality of processing positions Q include a first processing position (for example, a processing position Q1 that will be described later) at which the substrate W is processed with a first processing liquid (for example, a chemical liquid) and a second processing position (for example, a processing position Q2 that will be described later) at which the substrate W is processed with a second processing liquid (for example, a rinse liquid) different from the first processing liquid.

The chamber 11 has at least two (here, two) openings 12. At least two (here, two) shutters 13 are provided, that is, provided in the same number as the number of the openings 12. Each opening 12 is located between the center robot CR and the processing position Q in a state in which the center robot CR is disposed at a predetermined position (for example, the position illustrated in FIG. 1).

In the present preferred embodiment, the substrate W is carried in or out through each opening 12. Specifically, one opening 12 of the two openings 12 is set as a first opening 12a, and the other opening 12 of the two openings 12 is set as a second opening 12b. The first opening 12a is a carry-in port through which the substrate W is carried into the chamber 11 from the outside. The second opening 12b is a carry-out port through which the substrate W is carried out of the chamber 11 from the inside. Note that the first opening 12a is an example of a “carry-in port” of the present invention. The second opening 12b is an example of a “carry-out port” of the present invention.

In addition, one processing position Q of the two processing positions Q is set as the processing position Q1, and the other processing position Q of the two processing positions Q is set as the processing position Q2. It is assumed that the substrate W is processed at the processing position Q2 after being processed at the processing position Q1. At that time, the substrate W to be processed at the processing position Q1 is carried into the chamber 11 through the first opening 12a. The substrate W processed at the processing position Q1 is transferred to the processing position Q2 and processed. The substrate W processed at the processing position Q2 is carried out of the chamber 11 through the second opening 12b. Note that, in the present preferred embodiment, the processing position Q1 is an example of a “first processing position” of the present invention. In the present preferred embodiment, the processing position Q2 is an example of a “second processing position” of the present invention.

Next, the substrate processing apparatus 100 according to the first preferred embodiment will be described with reference to FIG. 2. FIG. 2 is a block diagram of the substrate processing apparatus 100 according to the first preferred embodiment.

As illustrated in FIG. 2, the controller 101 controls various operations of the substrate processing apparatus 100. The controller 101 controls the indexer robot IR, the center robot CR, the substrate holding portion 200, and the moving mechanism 300. Specifically, the controller 101 controls the indexer robot IR, the center robot CR, the substrate holding portion 200, and the moving mechanism 300 by transmitting control signals to the indexer robot IR, the center robot CR, the substrate holding portion 200, and the moving mechanism 300.

The controlling portion 102 controls the indexer robot IR to deliver the substrate W by the indexer robot IR.

The controlling portion 102 controls the center robot CR to deliver the substrate W by the center robot CR. For example, the center robot CR receives the unprocessed substrate W and carries the substrate W into one of the plurality of chambers 11. In addition, the center robot CR receives the processed substrate W from the chamber 11 and carries out the substrate W.

The controlling portion 102 controls the substrate holding portion 200 to control attachment/detachment of the substrate W, start of rotation of the substrate W, change of a rotational speed, and stop of rotation of the substrate W. For example, the controlling portion 102 can control the substrate holding portion 200 to change a rotational speed of the substrate holding portion 200. Specifically, the controlling portion 102 can change a rotational speed of the substrate W by changing a rotational speed of an electric motor 204 that will be described later of the substrate holding portion 200.

The controlling portion 102 controls the moving mechanism 300 to change an angular position of the substrate holding portion 200 in the turning direction. For example, the controlling portion 102 controls the moving mechanism 300 to turn the substrate holding portion 200 about the turning axis L200, thereby delivering the substrate W to and from the center robot CR at the two processing positions Q.

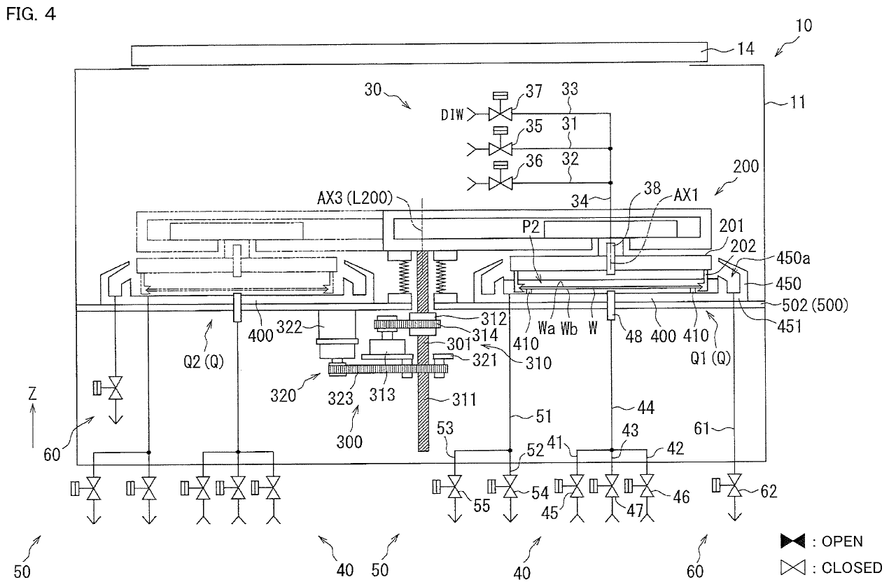

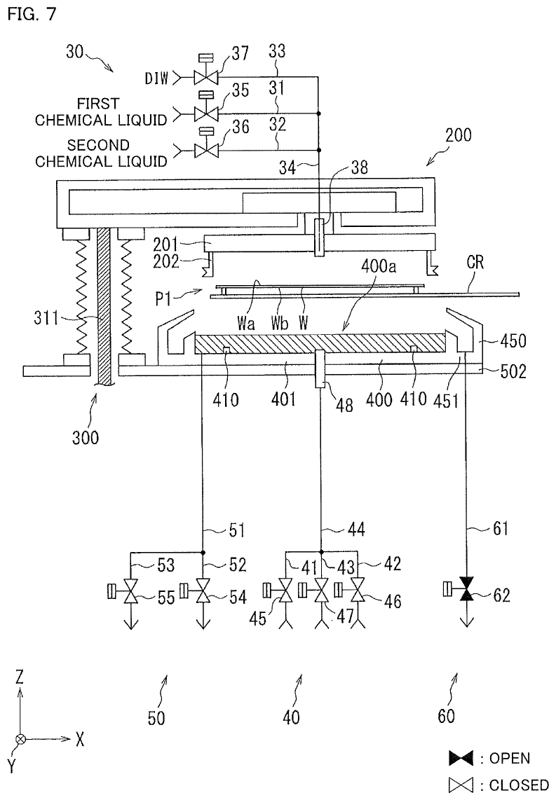

In addition, the controlling portion 102 controls the moving mechanism 300 to change a height position of the substrate holding portion 200. For example, the controlling portion 102 moves the substrate W between a first height position P1 (see FIG. 7) and a second height position P2 (see FIG. 4) by controlling the moving mechanism 300 to move the substrate holding portion 200. The first height position P1 is a height position of the substrate W when the substrate W is delivered between the center robot CR and the substrate holding portion 200. The second height position P2 is a height position of the substrate W when the substrate W is immersed in the processing liquid stored in the immersion bath 400. That is, the state in which the substrate W is disposed at the first height position P1 is a non-immersion state in which the substrate W is located outside the immersion bath 400. The state in which the substrate W is disposed at the second height position P2 is an immersion state in which the substrate W is located inside the immersion bath 400 and immersed in the processing liquid.

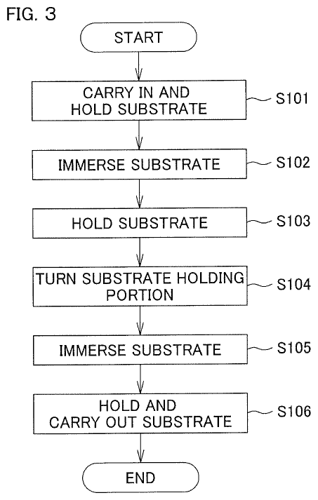

Next, a substrate processing method according to the first preferred embodiment will be described with reference to FIG. 3. FIG. 3 is a flowchart illustrating the substrate processing method according to the first preferred embodiment. The substrate processing method performed by the substrate processing apparatus 100 according to the first preferred embodiment includes steps S101 to S106. Steps S101 to S106 are executed by the controlling portion 102. In the first preferred embodiment, although not particularly limited, for example, a chemical liquid and a rinse liquid are used as processing liquids, and the substrate W is processed with the chemical liquid and then subjected to the rinse processing.

As illustrated in FIG. 3, in step S101, the substrate W is carried into the chamber 11 and held by the substrate holding portion 200. Specifically, the controlling portion 102 controls the center robot CR to carry the substrate W supported by an arm of the center robot CR into the chamber 11. At that time, the substrate holding portion 200 is located at the processing position Q1, and the substrate W is carried into the chamber 11 through the first opening 12a.

The controlling portion 102 controls the center robot CR and the substrate holding portion 200 to deliver the substrate W from the center robot CR to the substrate holding portion 200. As a result, the substrate holding portion 200 holds the substrate W.

Next, in step S102, the substrate W is processed with a chemical liquid. Specifically, the controlling portion 102 controls the moving mechanism 300 to lower the substrate holding portion 200. As a result, the substrate W is immersed in the chemical liquid stored in advance in the immersion bath 400. That is, the moving mechanism 300 immerses the substrate W in the chemical liquid by moving (lowering) the substrate holding portion 200 in a state in which the chemical liquid is stored in the immersion bath 400. In the present preferred embodiment, a predetermined amount of the chemical liquid is stored in the immersion bath 400 before executing step S102.

At that time, in the present preferred embodiment, in a state in which the substrate holding portion 200 rotates the substrate W, the moving mechanism 300 immerses the substrate W in the chemical liquid stored in advance in the immersion bath 400.

The controlling portion 102 then controls the substrate holding portion 200 to release the holding of the substrate W by the substrate holding portion 200. Thereafter, the controlling portion 102 controls the moving mechanism 300 to lift the substrate holding portion 200. At that time, the substrate W is immersed in the chemical liquid.

Next, in step S103, the substrate W is held by the substrate holding portion 200. Specifically, when a predetermined time has elapsed from the start of the processing of the substrate W with the chemical liquid in step S102, the controlling portion 102 controls the moving mechanism 300 to lower the substrate holding portion 200. The controlling portion 102 then controls the substrate holding portion 200 to hold the substrate W by the substrate holding portion 200.

Next, in step S104, the substrate holding portion 200 is turned. Specifically, the controlling portion 102 controls the moving mechanism 300 to turn the substrate holding portion 200 by a predetermined angle. As a result, the substrate holding portion 200 is moved to the processing position Q2.

Next, in step S105, the substrate W is processed with the rinse liquid. Specifically, the controlling portion 102 controls the moving mechanism 300 to lower the substrate holding portion 200. As a result, the substrate W is immersed in the rinse liquid stored in advance in the immersion bath 400. That is, the moving mechanism 300 immerses the substrate W in the rinse liquid by moving (lowering) the substrate holding portion 200 in a state in which the rinse liquid is stored in the immersion bath 400. Note that a method of immersing the substrate W in the rinse liquid is similar to the method of immersing the substrate W in the chemical liquid in step S102.

The controlling portion 102 then controls the substrate holding portion 200 to release the holding of the substrate W by the substrate holding portion 200. Thereafter, the controlling portion 102 controls the moving mechanism 300 to lift the substrate holding portion 200. At that time, the substrate W is immersed in the rinse liquid.

Next, in step S106, the substrate W is held by the substrate holding portion 200 and carried out of the chamber 11. Specifically, when a predetermined time has elapsed from the start of the processing of the substrate W with the rinse liquid in step S105, the controlling portion 102 controls the moving mechanism 300 to lower the substrate holding portion 200. The controlling portion 102 then controls the substrate holding portion 200 to hold the substrate W by the substrate holding portion 200. Thereafter, the controlling portion 102 controls the moving mechanism 300 to lift the substrate holding portion 200.

The controlling portion 102 controls the center robot CR and the substrate holding portion 200 to deliver the substrate W from the substrate holding portion 200 to the center robot CR. Thereafter, the controlling portion 102 controls the center robot CR to carry the substrate W supported by the arm of the center robot CR out of the chamber 11. At that time, the substrate holding portion 200 is located at the processing position Q2, and the substrate W is carried out of the chamber 11 through the second opening 12b.

As described above, the processing on the substrate W ends.

In the first preferred embodiment, an example in which only one substrate W is processed has been described, but the present invention is not limited thereto. For example, two substrates W can be processed in parallel. Hereinafter, for easy understanding, the plurality of substrates W may be referred to as a first substrate W1, a second substrate W2, . . . in order of being carried into the chamber 11.

Specifically, while the first substrate W1 is subjected to the immersion processing at the processing position Q2, the substrate holding portion 200 may be turned to the processing position Q1, and the substrate holding portion 200 may receive the second substrate W2 and perform the immersion processing at the processing position Q1.

In the first preferred embodiment, an example in which the holding of the substrate W by the substrate holding portion 200 is released when the substrate W is processed with the processing liquid at the processing position Q1 and the processing position Q2 has been described, but the present invention is not limited thereto. For example, when the substrate W is processed with the processing liquid at the processing position Q1 and/or the processing position Q2, the holding of the substrate W by the substrate holding portion 200 need not be released. In this case, for example, as described in the processing at the processing position Q1 of a third preferred embodiment that will be described later, the substrate W may be processed while the substrate holding portion 200 is holding the substrate W.

Further, in the first preferred embodiment, an example in which the substrate W is immersed in the rinse liquid when the substrate W is rinsed at the processing position Q2 has been described, but the present invention is not limited thereto. For example, as in a second preferred embodiment that will be described later, a cup 480 may be provided, and the substrate W may be rinsed without being immersed in the rinse liquid.

In the present preferred embodiment, as described above, there are a plurality of processing positions Q in one chamber 11. Therefore, it is possible to perform various types of processing compared with a case where there is only one processing position Q in one chamber 11. For example, as described above, two substrates W can be processed in parallel. For example, one substrate W can also be processed at a plurality of processing positions Q.

In addition, the substrate processing apparatus 100 includes the moving mechanism 300 that moves the substrate holding portion 200 between the plurality of processing positions Q in the chamber 11. Therefore, for example, the number of the substrate holding portions 200 can be reduced compared with the case where the substrate holding portion 200 is provided for each processing position. In addition, since the number of the substrate holding portions 200 can be reduced, it is possible to suppress an increase in size of the substrate processing apparatus 100.

As described above, the substrate processing apparatus 100 includes the immersion bath 400 that stores the processing liquid and in which the substrate W is immersed in the processing liquid. Therefore, when the substrate W is processed with the processing liquid, it is not necessary to continue to supply the processing liquid to the substrate W, and thus, it is possible to suppress an increase in the consumption amount of the processing liquid even when processing for a long time is required. In addition, since it is not necessary to continue to supply the processing liquid to the substrate W, for example, even in a case where a plurality of types of processing using the same processing liquid are performed in parallel in the plurality of chambers 11, it is possible to prevent timings of supplying the processing liquid from the processing liquid cabinet (not illustrated) from overlapping. Therefore, since it is possible to suppress an increase in the liquid feeding amount per unit time of the processing liquid cabinet, the processing liquid cabinet can be downsized.

In addition, since the substrates W are immersed one by one in the immersion bath 400 and processed, it is possible to prevent particles of other substrates W from adhering (transferring) to a certain substrate W.

As described above, the plurality of processing positions Q are located on the circle C200 centered on the turning axis L200. Therefore, the substrate holding portion 200 can be easily moved between the plurality of processing positions Q.

As described above, the plurality of processing positions Q include a first processing position (for example, the processing position Q1) at which the substrate W is processed with a first processing liquid (for example, a chemical liquid) and a second processing position (for example, the processing position Q2) at which the substrate W is processed with a second processing liquid (for example, a rinse liquid) different from the first processing liquid. Therefore, for example, unlike a case where processing using a chemical liquid and processing using a rinse liquid are performed at one processing position Q, processing can be performed in a state in which a processing liquid is stored in the immersion bath 400. In other words, it is not necessary to replace the processing liquid in the immersion bath 400 every time the substrate W is immersed. Therefore, the consumption amount of the processing liquid can be further reduced.

As described above, the moving mechanism 300 moves the substrate holding portion 200 in a state in which the processing liquid is stored in the immersion bath 400 to immerse the substrate W in the processing liquid. Therefore, for example, the processing time can be shortened compared with a case where the substrate W is disposed in the immersion bath 400 in a state in which the processing liquid is not stored, and then the processing liquid is supplied and stored in the immersion bath 400.

In addition, the processing liquid in the immersion bath 400 need not be replaced each time the substrate W is immersed. Therefore, the consumption amount of the processing liquid can be further reduced.

As described above, in a state in which the substrate holding portion 200 rotates the substrate W, the moving mechanism 300 immerses the substrate 3 in the processing liquid stored in advance in the immersion bath 400. Therefore, the air existing between a lower surface Wb of the substrate W and a liquid level of the processing liquid is easily discharged to the radially outer side of the substrate W. Therefore, the substrate W can be easily immersed in the processing liquid.

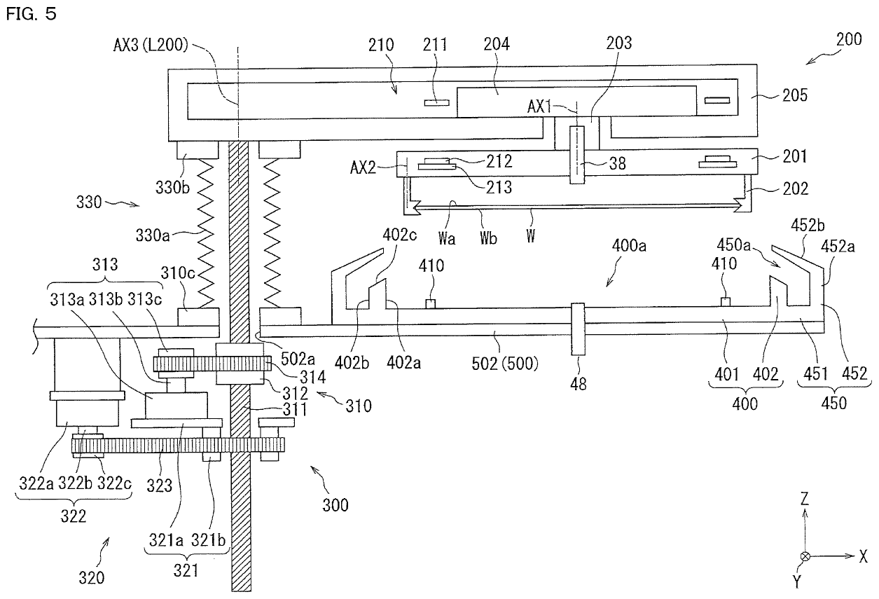

Next, the substrate processing unit 10 in the substrate processing apparatus 100 according to the first preferred embodiment will be described with reference to FIGS. 4 and 5. FIG. 4 is a schematic view of the substrate processing unit 10 in the substrate processing apparatus 100 according to the first preferred embodiment. FIG. 5 is a schematic view illustrating a structure around the substrate holding portion 200 and the moving mechanism 300 of the substrate processing apparatus 100 according to the first preferred embodiment. Note that in FIG. 4 and the subsequent drawings, all of various supplying portions and all of discharge portions may be drawn inside the chamber 11 due to the limitation of the drawing size, but some of various supplying portions and some of the discharge portions are disposed outside the chamber 11.

As illustrated in FIG. 4, the substrate processing unit 10 according to the first preferred embodiment includes the processing position Q1 and the processing position Q2 as described above. In the present preferred embodiment, the processing position Q1 and the processing position Q2 are similarly configured. Therefore, one processing position Q will be described, and description of the other processing position Q will be omitted.

Specifically, the substrate processing unit 10 includes an air blowing unit 14, a cup 450, and an immersion bath supporting portion 500 in addition to the chamber 11, the substrate holding portion 200, the moving mechanism 300, and the immersion bath 400 described above. For example, one chamber 11, one substrate holding portion 200, one moving mechanism 300, one air blowing unit 14, and one immersion bath supporting portion 500 are provided for one substrate processing unit 10. On the other hand, one immersion bath 400 and one cup 450 are provided for one processing position Q. Note that the air blowing unit 14 is controlled by the controlling portion 102.

The air blowing unit 14 is disposed on the upper portion of or above the chamber 11. For example, the air blowing unit 14 is disposed on the top surface of the chamber 11. The air blowing unit 14 sends air into the chamber 11. The air blowing unit 14 includes, for example, a fan filter unit (FFU). A downflow (downward flow) is formed in the chamber 11 by the air blowing unit 14 and an exhaust device (not illustrated).

The immersion bath 400 stores a processing liquid. Specifically, the immersion bath 400 has a container shape with an open upper surface, and the processing liquid is stored in an inner space 400a (see FIG. 5) of the immersion bath 400. In addition, the immersion bath 400 accommodates the substrate W. The substrate W is immersed in the processing liquid stored in the immersion bath 400. As a result, the substrate W is processed with the processing liquid.

The immersion bath 400 has, for example, a substantially circular shape in plan view. The immersion bath 400 may have a circular cylindrical shape with a bottom. The immersion bath 400 is supported in a horizontal posture by the immersion bath supporting portion 500. Note that the immersion bath 400 may be installed in a horizontal posture on the bottom surface (bottom wall) of the chamber 11. For example, the immersion bath 400 may be made of silicon carbide (SiC) or stainless steel. For example, the immersion bath 400 may be made of aluminum coated with a fluororesin. The fluororesin includes, for example, polytetrafluoroethylene (PTFE).

As illustrated in FIG. 5, the immersion bath 400 has a bottom wall 401 and a side wall 402. The bottom wall 401 may have a circular shape in plan view. The side wall 402 is connected to the bottom wall 401. The side wall 402 may be connected to an end portion (peripheral edge portion) of the bottom wall 401. The side wall 402 extends upward from the bottom wall 401. The inner space 400a of the immersion bath 400 is formed by the bottom wall 401 and the side wall 402. In other words, the inner space 400a is a space surrounded by the bottom wall 401 and the side wall 402.

More specifically, the side wall 402 has an inner peripheral surface 402a, an outer peripheral surface 402b, and an upper surface 402c. The inner peripheral surface 402a defines the inner space 400a. The outer peripheral surface 402b is disposed outside the inner peripheral surface 402a. The upper surface 402c connects the upper end of the inner peripheral surface 402a and the upper end of the outer peripheral surface 402b. The upper surface 402c is inclined downward toward the outside.

In the first preferred embodiment, a support table 410 is provided on the bottom wall 401 of the immersion bath 400. The support table 410 supports the substrate W. The support table 410 protrudes upward from the upper surface of the bottom wall 401. The support table 410 is not particularly limited, but has, for example, a cylindrical shape. A plurality of support tables 410 are provided on the bottom wall 401. Note that the support table 410 and the bottom wall 401 may be integrally formed. In other words, the support table 410 and the bottom wall 401 may be a single member.

The cup 450 is disposed around the periphery of the immersion bath 400. In the present preferred embodiment, the cup 450 and the immersion bath 400 are integrally formed. In other words, the cup 450 and the immersion bath 400 are a single member.

The cup 450 is disposed outside the side wall 402 of the immersion bath 400 at a predetermined distance from the side wall 402. Specifically, the cup 450 has a bottom wall 451 and a side wall 452. The bottom wall 451 is connected to the bottom wall 401 or the side wall 402 of the immersion bath 400. The side wall 452 is connected to a peripheral edge portion of the bottom wall 451. The side wall 452 has a lower wall portion 452a and an upper wall portion 452b. The lower wall portion 452a extends upward from the bottom wall 451. The upper wall portion 452b is inclined inward and upward from the upper end of the lower wall portion 452a. The bottom wall 451 and the side wall 452 of the cup 450 and the side wall 402 of the immersion bath 400 define an inner space 450a of the cup 450.

For example, the cup 450 collects the processing liquid that is scattered around the periphery of the substrate W due to the rotation of the substrate W. An exhaust device (not illustrated) may be connected to the cup 450, and a gas in the inner space 450a may be exhausted out of the chamber 11.

The immersion bath supporting portion 500 supports the immersion bath 400. In the present preferred embodiment, the immersion bath supporting portion 500 supports the immersion bath 400 and the cup 450. The immersion bath supporting portion 500 includes a support plate 502. The support plate 502 has a plate shape and is disposed in a horizontal posture. For example, the support plate 502 may be fixed to a side wall of the chamber 11, or may be fixed to an upper surface of a support column, etc., of the immersion bath supporting portion 500. In the present preferred embodiment, the support plate 502 is fixed to the side wall of the chamber 11, and partitions the inside of the chamber 11 into an upper space and a lower space. The support plate 502 supports the immersion bath 400 in a horizontal posture. A through hole 502a penetrating the support plate 502 in the thickness direction is formed at a predetermined position of the support plate 502. A screw shaft 311 that will be described later of the moving mechanism 300 is inserted into the through hole 502a.

As illustrated in FIG. 4, the substrate processing apparatus 100 includes a first supplying portion 30, a second supplying portion 40, a first discharge portion 50, and a second discharge portion 60. The first supplying portion 30, the second supplying portion 40, the first discharge portion 50, and the second discharge portion 60 are controlled by the controlling portion 102. Note that the first supplying portion 30 and the second supplying portion 40 are examples of a “processing liquid supplying portion” of the present invention.

The first supplying portion 30 supplies the processing liquid to the immersion bath 400. The first supplying portion 30 supplies the processing liquid from above the immersion bath 400. In the present preferred embodiment, the first supplying portion 30 can eject the processing liquid toward an upper surface Wa of the substrate W held by the substrate holding portion 200.

Specifically, the first supplying portion 30 includes a first chemical liquid piping 31, a second chemical liquid piping 32, a rinse liquid piping 33, a common piping 34, an opening/closing valve 35, an opening/closing valve 36, an opening/closing valve 37, and a nozzle 38.

The first chemical liquid piping 31, the second chemical liquid piping 32, the rinse liquid piping 33, and the common piping 34 are tubular members, and allow the processing liquid to flow therethrough.

A first chemical liquid is supplied from a supply source to the first chemical liquid piping 31. A downstream end of the first chemical liquid piping 31 is connected to the common piping 34. The opening/closing valve 35 is provided in the first chemical liquid piping 31 and opens and closes a flow path in the first chemical liquid piping 31. The opening/closing valve 35 adjusts the opening degree of the first chemical liquid piping 31 to adjust a flow rate of the first chemical liquid supplied to the first chemical liquid piping 31.

The first chemical liquid is not particularly limited, and includes, for example, an HF (hydrofluoric acid), a DHF (dilute hydrofluoric acid), a phosphoric acid, an SPM (sulfuric acid hydrogen peroxide water mixed solution), or ozone water. The SPM is a sulfuric acid hydrogen peroxide water mixed solution in which a sulfuric acid and hydrogen peroxide water are mixed. In the present preferred embodiment, the first chemical liquid is a phosphoric acid. Note that the first chemical liquid may be, for example, SC1 (a mixed solution of ammonia water, hydrogen peroxide water, and water) or an organic solvent.

A second chemical liquid is supplied from a supply source to the second chemical liquid piping 32. The downstream end of the second chemical liquid piping 32 is connected to the common piping 34. The opening/closing valve 36 is provided in the second chemical liquid piping 32 and opens and closes a flow path in the second chemical liquid piping 32. The opening/closing valve 36 adjusts the opening degree of the second chemical liquid piping 32 to adjust a flow rate of the second chemical liquid supplied to the second chemical liquid piping 32.

The second chemical liquid is not particularly limited, and includes, for example, an HF (hydrofluoric acid), a DHF (dilute hydrofluoric acid), a phosphoric acid, an SPM (sulfuric acid hydrogen peroxide water mixed solution), or ozone water. In the present preferred embodiment, the second chemical liquid is a phosphoric acid having a concentration different from that of the first chemical liquid or a DHF (dilute hydrofluoric acid). Note that the second chemical liquid may be, for example, SC1 (a mixed solution of ammonia water, hydrogen peroxide water, and water) or an organic solvent.

A rinse liquid is supplied from a supply source to the rinse liquid piping 33. The downstream end of the rinse liquid piping 33 is connected to the common piping 34. The opening/closing valve 37 is provided in the rinse liquid piping 33, and opens and closes a flow path in the rinse liquid piping 33. The opening/closing valve 37 adjusts the opening degree of the rinse liquid piping 33 to adjust a flow rate of the rinse liquid supplied to the rinse liquid piping 33.

Examples of the rinse liquid include deionized water (DIW), carbonated water, electrolyzed ion water, ozone water, ammonia water, hydrochloric acid water having a dilution concentration (for example, about 10 ppm to 100 ppm), or reduced water (hydrogen water). In the present preferred embodiment, the rinse liquid is deionized water (DIW).

Each of the opening/closing valve 35 to the opening/closing valve 37 includes a valve body (not illustrated) inside which a valve seat is provided, a valve element that opens and closes the valve seat, and an actuator (not illustrated) that moves the valve element between an open position and a closed position.

The downstream end of the common piping 34 is connected to the nozzle 38. The common piping 34 allows the processing liquid to flow through the nozzle 38.

The nozzle 38 ejects the processing liquid. In the present preferred embodiment, the nozzle 38 ejects the processing liquid toward the upper surface Wa of the substrate W held by the substrate holding portion 200. Note that the nozzle 38 may also eject the processing liquid to the immersion bath 400 in a state in which the substrate holding portion 200 does not hold the substrate W. The nozzle 38 is provided in a spin base 201 that will be described later of the substrate holding portion 200. The nozzle 38 is disposed, for example, at the central portion of the spin base 201. In the present preferred embodiment, the nozzle 38 is disposed on a rotational axis AX1 of the spin base 201. The nozzle 38 may be formed separately from the spin base 201, or may be formed by a portion of the spin base 201. In a case where the nozzle 38 is formed separately from the spin base 201, for example, a through hole extending in the up-down direction may be formed at the central portion of the spin base 201, and the nozzle 38 may be disposed in the through hole of the spin base 201. In this case, the nozzle 38 may be fixed to a housing 205.

The second supplying portion 40 supplies the processing liquid to the immersion bath 400. The second supplying portion 40 supplies the processing liquid from below the immersion bath 400. In the present preferred embodiment, the second supplying portion 40 can eject the processing liquid toward the lower surface Wb of the substrate W held by the substrate holding portion 200.

Specifically, the second supplying portion 40 includes a first chemical liquid piping 41, a second chemical liquid piping 42, a rinse liquid piping 43, a common piping 44, an opening/closing valve 45, an opening/closing valve 46, an opening/closing valve 47, and a nozzle 48.

The first chemical liquid piping 41, the second chemical liquid piping 42, the rinse liquid piping 43, and the common piping 44 are annular members, and allow the processing liquid to flow therethrough.

The first chemical liquid is supplied from a supply source to the first chemical liquid piping 41. The downstream end of the first chemical liquid piping 41 is connected to the common piping 44. The opening/closing valve 45 is provided in the first chemical liquid piping 41 and opens and closes a flow path in the first chemical liquid piping 41. The opening/closing valve 45 adjusts the opening degree of the first chemical liquid piping 41 to adjust a flow rate of the first chemical liquid supplied to the first chemical liquid piping 41.

The second chemical liquid is supplied from a supply source to the second chemical liquid piping 42. The downstream end of the second chemical liquid piping 42 is connected to the common piping 44. The opening/closing valve 46 is provided in the second chemical liquid piping 42 and opens and closes a flow path in the second chemical liquid piping 42. The opening/closing valve 46 adjusts the opening degree of the second chemical liquid piping 42 to adjust a flow rate of the second chemical liquid supplied to the second chemical liquid piping 42.

The rinse liquid is supplied from a supply source to the rinse liquid piping 43. The downstream end of the rinse liquid piping 43 is connected to the common piping 44. The opening/closing valve 47 is provided in the rinse liquid piping 43, and opens and closes a flow path in the rinse liquid piping 43. The opening/closing valve 47 adjusts the opening degree of the rinse liquid piping 43 to adjust a flow rate of the rinse liquid supplied to the rinse liquid piping 43.

Each of the opening/closing valve 45 to the opening/closing valve 47 includes a valve body (not illustrated) inside which a valve seat is provided, a valve element that opens and closes the valve seat, and an actuator (not illustrated) that moves the valve element between an open position and a closed position.

The downstream end of the common piping 44 is connected to the nozzle 48. The common piping 44 allows the processing liquid to flow through the nozzle 48.

The nozzle 48 ejects the processing liquid. In the present preferred embodiment, the nozzle 48 ejects the processing liquid toward the lower surface Wb of the substrate W held by the substrate holding portion 200. Note that the nozzle 48 may also eject the processing liquid to the immersion bath 400 in a state in which the substrate holding portion 200 does not hold the substrate W. The nozzle 48 is disposed at the central portion of the immersion bath 400. The tip (upper end) of the nozzle 48 protrudes upward from the upper surface of the bottom wall 401 of the immersion bath 400. The nozzle 48 may be formed separately from the immersion bath 400, or may be formed by a portion of the immersion bath 400.

The first discharge portion 50 discharges the processing liquid stored in the immersion bath 400 out of the immersion bath 400. In the present preferred embodiment, the first discharge portion 50 discharges the processing liquid stored in the immersion bath 400 out of the chamber 11.

Specifically, the first discharge portion 50 includes a common piping 51, a drain piping 52, a return piping 53, an opening/closing valve 54, and an opening/closing valve 55. The common piping 51, the drain piping 52, and the return piping 53 are tubular members, and allow the processing liquid to flow therethrough.

An upstream end of the common piping 51 is connected to the bottom wall 401 of the immersion bath 400. The common piping 51 communicates with the inner space 400a of the immersion bath 400. The processing liquid in the immersion bath 400 flows into the common piping 51. The downstream end of the common piping 51 is connected to the drain piping 52 and the return piping 53.

The drain piping 52 drains the processing liquid from the common piping 51. For example, the drain piping 52 allows the processing liquid from the common piping 51 to flow through a drain tank (not illustrated). The opening/closing valve 54 is provided in the drain piping 52 and opens and closes a flow path in the drain piping 52.

The return piping 53 returns the processing liquid from the common piping 51 to a processing liquid cabinet (not illustrated) provided in the substrate processing apparatus 100. The processing liquid returned to the processing liquid cabinet is reused. Therefore, since the amount of the processing liquid used can be decreased, the environmental load can be reduced. The opening/closing valve 55 is provided in the return piping 53 and opens and closes a flow path in the return piping 53. Each of the opening/closing valve 54 and the opening/closing valve 55 includes a valve body (not illustrated) inside which a valve seat is provided, a valve element that opens and closes the valve seat, and an actuator (not illustrated) that moves the valve element between an open position and a closed position.

The second discharge portion 60 discharges the processing liquid in the cup 450 out of the cup 450. In the present preferred embodiment, the second discharge portion 60 discharges the processing liquid in the cup 450 out of the chamber 11.

Specifically, the second discharge portion 60 includes a drain piping 61 and an opening/closing valve 62. The drain piping 61 is a tubular member and allows the processing liquid to flow therethrough.

The drain piping 61 drains the processing liquid in the cup 450. Specifically, the upstream end of the drain piping 61 is connected to the bottom wall 451 of the cup 450. The drain piping 61 communicates with the inner space 450a of the cup 450. The processing liquid of the cup 450 flows into the drain piping 61. For example, the drain piping 61 allows the processing liquid to flow through a drain tank (not illustrated). The opening/closing valve 62 is provided in the drain piping 61 and opens and closes a flow path in the drain piping 61. The opening/closing valve 62 includes a valve body (not illustrated) inside which a valve seat is provided, a valve element that opens and closes the valve seat, and an actuator (not illustrated) that moves the valve element between an open position and a closed position.

Next, the substrate holding portion 200 and the moving mechanism 300 will be further described with reference to FIG. 5.

As illustrated in FIG. 5, the substrate holding portion 200 includes the spin base 201, a chuck pin 202, a shaft 203, the electric motor 204, and the housing 205. Note that the spin base 201 is an example of a “base” of the present invention.

A chuck pin 202 is provided on the spin base 201 disposed above the substrate W. The chuck pin 202 chucks the substrate W. Typically, the spin base 201 is provided with a plurality of chuck pins 202. The chuck pin 202 protrudes downward from a lower surface of the spin base 201. The chuck pin 202 has a pin-shaped portion extending in the up-down direction and a contact portion provided at the lower end of the pin-shaped portion and in contact with the circumferential edge of the substrate W. Each chuck pin 202 is rotatable about a rotational axis AX2 (a central axis of each pin-shaped portion) extending in the up-down direction. The chuck pin 202 rotates about the rotational axis AX2 between a holding position where the substrate W is held and a non-holding position where the substrate W is not held.

The shaft 203 is a hollow shaft. The shaft 203 extends in the vertical direction along the rotational axis AX1. The spin base 201 is coupled to the lower end of the shaft 203. The substrate W is located below the spin base 201.

The spin base 201 has a disk shape and horizontally supports the substrate W. The shaft 203 extends upward from the central portion of the spin base 201. The electric motor 204 applies a rotational force to the shaft 203. The electric motor 204 rotates the shaft 203 in the rotation direction to rotate the substrate W and the spin base 201 around the rotational axis AX1. The housing 205 has a substantially box shape and accommodates a portion of the shaft 203 and the electric motor 204. The electric motor 204 is attached to a predetermined position of the housing 205.

In addition, the substrate holding portion 200 includes a chuck driving mechanism 210 that rotates the plurality of chuck pins 202. The chuck driving mechanism 210 is configured by using a known technique (for example, Japanese Patent Application Publication No. 2016-25186), and will thus be briefly described.

The chuck driving mechanism 210 includes a driving magnet 211, a driven magnet 212, and a lifting/lowering plate 213. The driving magnet 211 is disposed in the housing 205. The driving magnet 211 is disposed over one turn to surround the rotational axis AX1. The driving magnet 211 is moved in the up-down direction with respect to the housing 205 by a lifting/lowering mechanism (not illustrated). The driven magnet 212 and the lifting/lowering plate 213 are disposed in the spin base 201. The driven magnet 212 is fixed to the lifting/lowering plate 213. The lifting/lowering plate 213 is biased upward by a biasing member (not illustrated). The driven magnet 212 and the lifting/lowering plate 213 are disposed over one turn to surround the rotational axis AX1. The driven magnet 212 is disposed at a position directly below the driving magnet 211. The driven magnet 212 is disposed to repel the driving magnet 211. Specifically, the driven magnet 212 and the driving magnet 211 are disposed such that the surfaces thereof facing each other have the same polarity. The lifting/lowering plate 213 is provided with a cam or a link mechanism that rotates the chuck pin 202 between the holding position and the non-holding position. When the driving magnet 211 is lifted and lowered, the driven magnet 212 and the lifting/lowering plate 213 are lifted and lowered. As a result, the chuck pin 202 is rotated between the holding position and the non-holding position, whereby the substrate W is held by the chuck pin 202 or released from the holding.

The moving mechanism 300 includes a lifting/lowering mechanism 310 that moves the substrate holding portion 200 in the vertical direction, and a turning mechanism 320 that turns the substrate holding portion 200. The lifting/lowering mechanism 310 includes, for example, the screw shaft 311, a nut 312, an electric motor 313, and a driving belt 314.

The screw shaft 311 and the nut 312 configure a ball screw mechanism. The screw shaft 311 extends in the vertical direction. An upper end of the screw shaft 311 is fixed to the housing 205 of the substrate holding portion 200. A screw groove is formed on the outer peripheral surface of the screw shaft 311.

The nut 312 has a ball that contacts the screw groove of the screw shaft 311. Since the nut 312 rotates about a central axis AX3 of the screw shaft 311, the screw shaft 311 moves in the vertical direction. In the present preferred embodiment, the central axis AX3 coincides with the turning axis L200.

The electric motor 313 includes, for example, a motor body 313a, a motor shaft 313b, and a motor pulley 313c. The motor body 313a is fixed to a motor supporting member 321 that will be described later of the turning mechanism 320. The motor pulley 313c is fixed to the tip of the motor shaft 313b.

The driving belt 314 is stretched around outer peripheral surfaces of the motor pulley 313c and the nut 312. The driving belt 314 transmits the rotational force of the motor pulley 313c to the nut 312. As a result, when the motor pulley 313c is rotated, the nut 312 is rotated. The screw shaft 311 is arranged not to move in the horizontal direction.

In the moving mechanism 300, when the electric motor 313 of the lifting/lowering mechanism 310 is driven, the driving force of the electric motor 313 is transmitted to the nut 312 through the driving belt 314. The nut 312 is then rotated, whereby the screw shaft 311 is lifted and lowered in the vertical direction.

The turning mechanism 320 includes, for example, the motor supporting member 321, an electric motor 322, and a driving belt 323.

The motor supporting member 321 supports the electric motor 313 of the lifting/lowering mechanism 310. The motor supporting member 321 includes a support plate 321a and a pulley 321b fixed to the support plate 321a. The screw shaft 311 is inserted through the central portion of the pulley 321b. The motor supporting member 321 is rotated (turned) about the central axis AX3 of the screw shaft 311 together with the electric motor 313.

The electric motor 322 includes, for example, a motor body 322a, a motor shaft 322b, and a motor pulley 322c. The motor body 322a is fixed to the support plate 502. The motor pulley 322c is fixed to the tip of the motor shaft 322b.

The driving belt 323 is stretched between the motor pulley 322c and the pulley: 321b of the motor supporting member 321. The driving belt 323 transmits the rotational force of the motor pulley 322c to the motor supporting member 321. As a result, when the motor pulley 322c is rotated, the motor supporting member 321 is turned about the central axis AX3 (turning axis L200).

In the moving mechanism 300, when the electric motor 322 is driven, the driving force of the electric motor 322 is transmitted to the motor supporting member 321 through the driving belt 323. As the motor supporting member 321 turns, the lifting/lowering mechanism 310 and the substrate holding portion 200 turn about the central axis AX3 (turning axis L200).

The moving mechanism 300 includes a shaft cover 330. The shaft cover 330 includes a bellows portion 330a that can expand and contract in the vertical direction, an upper plate 330b that attaches an upper end of the bellows portion 330a to the housing 205 of the substrate holding portion 200, and a lower plate 330c that attaches a lower end of the bellows portion 330a to the support plate 502.

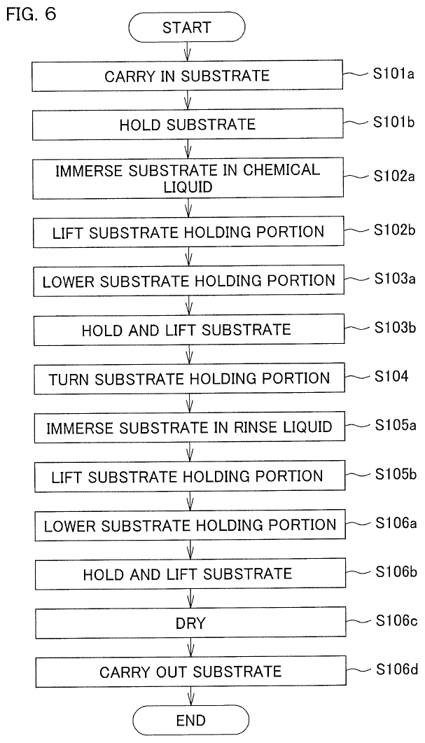

Next, the substrate processing method of the first preferred embodiment will be further described with reference to FIGS. 6 to 9. FIG. 6 is a detailed flowchart illustrating the substrate processing method according to the first preferred embodiment. FIGS. 7 to 9 are schematic views for describing the substrate processing method according to the first preferred embodiment. The substrate processing method of the substrate processing apparatus 100 of the first preferred embodiment includes steps S101a, S101b, S102a, S102b, S103a, S103b, S104, S105a, S105b, S106a, S106b, S106c, and S106d. These steps S101a to S106d are executed by the controlling portion 102. Steps S101a and S101b correspond to step S101 described above. Steps S102a and S102b correspond to step S102 described above. Steps S103a and S103b correspond to step S103 described above. Steps S105a and S105b correspond to step S105 described above. Steps S106a to S106d correspond to step S106 described above.

As illustrated in FIG. 6, in step S101a, the substrate W is carried into the chamber 11. Specifically, as illustrated in FIG. 7, the controlling portion 102 controls the center robot CR to carry the substrate W supported by the arm of the center robot CR into the chamber 11. At that time, the substrate holding portion 200 is retracted further upward than the height position at the time of delivering the substrate W. The opening/closing valves 35 to 37, 45 to 47, 54, and 55 are in a closed state, and the opening/closing valve 62 is in an open state.

Next, in step S101b, the substrate W is held. Specifically, the controlling portion 102 controls the moving mechanism 300 to move the substrate holding portion 200. Specifically, the controlling portion 102 controls the moving mechanism 300 to move (lower) the substrate holding portion 200 to a height position where the substrate W is delivered between the substrate holding portion 200 and the center robot CR.

The controlling portion 102 controls the substrate holding portion 200 such that the substrate W is held by the chuck pin 202. As a result, the substrate holding portion 200 rotatably holds the substrate W. At that time, the substrate W is located at the first height position P1. That is, the substrate W is in a non-immersion state of being located outside the immersion bath 400.

Next, in step S102a, the substrate W is immersed in the chemical liquid. Specifically, the controlling portion 102 controls the center robot CR to move the arm of the center robot CR to the outside of the chamber 11.

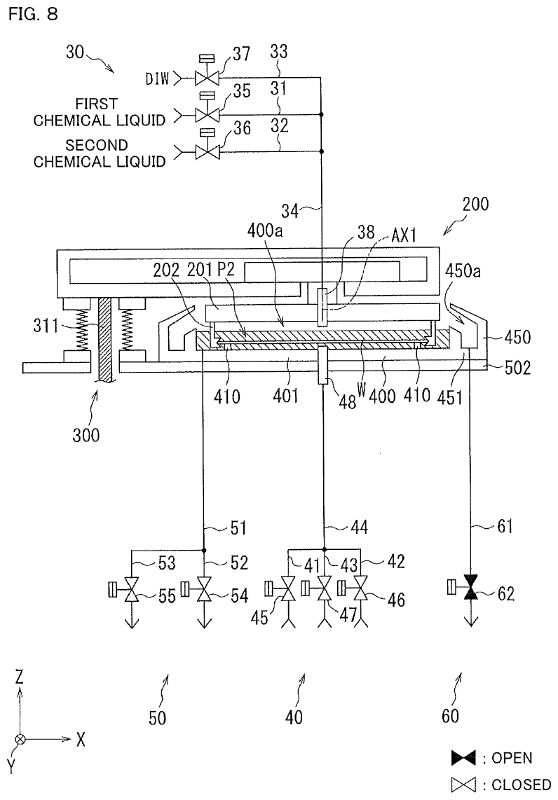

As illustrated in FIG. 8, the controlling portion 102 controls the moving mechanism 300 to move (lower) the substrate holding portion 200, thereby moving (lowering) the substrate W from the first height position P1 to the second height position P2. As a result, the substrate W is disposed in the inner space 400a of the immersion bath 400. In the present preferred embodiment, a predetermined amount of the chemical liquid is stored in the immersion bath 400 before executing step S102a.

At that time, in the present preferred embodiment, in a state in which the substrate holding portion 200 rotates the substrate W, the moving mechanism 300 immerses the substrate W in the chemical liquid stored in advance in the immersion bath 400.

At that time, in a state in which at least one of the first supplying portion 30 and the second supplying portion 40 is supplying the chemical liquid toward the substrate W, the moving mechanism 300 immerses the substrate W in the chemical liquid stored in advance in the immersion bath 400. In the present preferred embodiment, in a state in which both the first supplying portion 30 and the second supplying portion 40 are supplying the chemical liquid toward the substrate W, the moving mechanism 300 immerses the substrate W in the chemical liquid stored in advance in the immersion bath 400. In step S102a, at least the second supplying portion 40 preferably supplies the chemical liquid toward the substrate W.

Thereafter, the controlling portion 102 controls the substrate holding portion 200 to release the holding of the substrate W by the chuck pin 202. As a result, the substrate W is supported by the plurality of support tables 410 of the immersion bath 400.

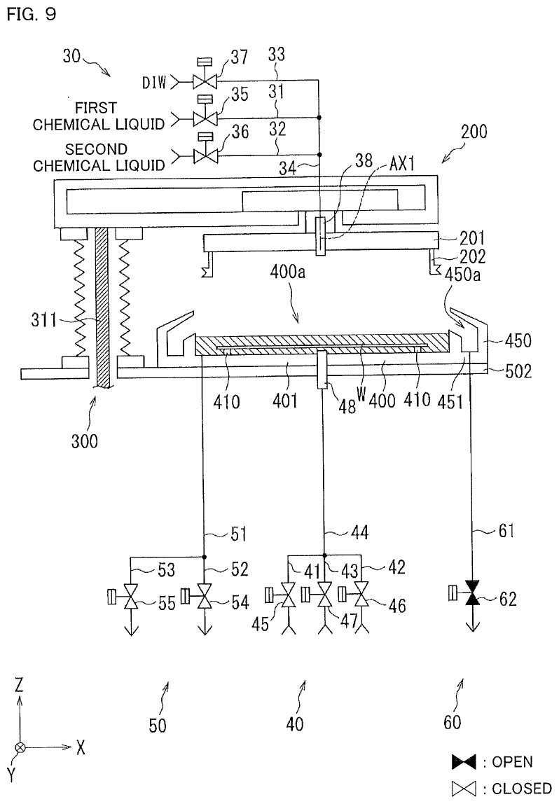

Next, in step S102b, the substrate holding portion 200 is lifted. Specifically, as illustrated in FIG. 9, the controlling portion 102 controls the moving mechanism 300 to move (lift) the substrate holding portion 200. As a result, the substrate holding portion 200 can be turned.

Next, in step S103a, the substrate holding portion 200 is lowered. Specifically, the controlling portion 102 controls the moving mechanism 300 to move (lower) the substrate holding portion 200.

Next, in step S103b, the substrate W is held and lifted. Specifically, illustrated in FIG. 8, the controlling portion 102 controls the substrate holding portion 200 such that the substrate W is held by the chuck pin 202. The controlling portion 102 controls the moving mechanism 300 to move (lift) the substrate holding portion 200. As a result, the substrate W is brought into a non-immersion state. In addition, the substrate holding portion 200 can be turned.

Next, in step S104, the substrate holding portion 200 is turned as described above. As a result, the substrate holding portion 200 and the substrate W are moved to the processing position Q2.

Next, in step S105a, the substrate W is immersed in the rinse liquid. Specifically, similarly to step S102a, the controlling portion 102 controls the moving mechanism 300 to move (lower) the substrate holding portion 200, thereby moving (lowering) the substrate W from the first height position P1 to the second height position P2. As a result, the substrate W is disposed in the inner space 400a of the immersion bath 400 at the processing position Q2. In the present preferred embodiment, a predetermined amount of the rinse liquid is stored in the immersion bath 400 before executing step S105a.

At that time, in the present preferred embodiment, in a state in which the substrate holding portion 200 rotates the substrate W, the moving mechanism 300 immerses the substrate W in the rinse liquid stored in advance in the immersion bath 400.

At that time, in a state in which at least one of the first supplying portion 30 and the second supplying portion s supplying the rinse liquid toward the substrate W, the moving mechanism 300 immerses the substrate W in the rinse liquid stored in advance in the immersion bath 400. In the present preferred embodiment, in a state in which both the first supplying portion 30 and the second supplying portion 40 are supplying the rinse liquid toward the substrate W, the moving mechanism 300 immerses the substrate W in the rinse liquid stored in advance in the immersion bath 400. In step S105a, at least the second supplying portion 40 preferably supplies the rinse liquid toward the substrate W.

Thereafter, the controlling portion 102 controls the substrate holding portion 200 to release the holding of the substrate W by the chuck pin 202. As a result, the substrate W is supported by the plurality of support tables 410 of the immersion bath 400.

Next, in step S105b, the substrate holding portion 200 is lifted. Specifically, similarly to step S102b, the controlling portion 102 controls the moving mechanism 300 to move (lift) the substrate holding portion 200. As a result, the substrate holding portion 200 can be turned.

Next, in step S106a, the substrate holding portion 200 is lowered. Specifically, similarly to step S103a, the controlling portion 102 controls the moving mechanism 300 to move (lower) the substrate holding portion 200.

Next, in step S106b, the substrate W is held and lifted. Specifically, similarly to step S103b, the controlling portion 102 controls the substrate holding portion 200 such that the substrate W is held by the chuck pin 202. The controlling portion 102 controls the moving mechanism 300 to move (lift) the substrate holding portion 200. As a result, the substrate W is brought into a non-immersion state.

Next, in step S106c, the substrate W is dried as necessary. Specifically, the controlling portion 102 controls the substrate holding portion 200 to rotate the substrate W about the rotational axis AX1. As a result, the substrate W is dried. Note that a rotational speed of the substrate W is not particularly limited, but is, for example, 1500 rpm to 2000 rpm or more.

Next, in step S106d, the substrate W is carried out of the chamber 11. Specifically, the controlling portion 102 controls the substrate holding portion 200 and the center robot CR to release the holding of the substrate W by the substrate holding portion 200 and to place the substrate W on the arm of the center robot CR. The controlling portion 102 controls the center robot CR to carry the substrate W supported by the arm of the center robot CR out of the chamber 11.

As described above, the processing on the substrate W ends. In the present preferred embodiment, an example in which the substrate W is dried in step S106c has been described, but the substrate W need not be dried.

In the present preferred embodiment, as described above, the immersion bath 400 is provided with the support table 410 that supports the substrate W. Therefore, by placing the substrate W on the support table 410, the substrate holding portion 200 does not have to keep holding the substrate W at the time of processing. Therefore, for example, the substrate holding portion 200 can be moved to another processing position Q to hold or transfer another substrate W.

As described above, the substrate holding portion 200 includes the spin base 201 disposed above the substrate W and the plurality of chuck pins 202 protruding downward from the spin base 201 and holding the circumferential edge of the substrate W. Therefore, since the substrate W can be held from above, the substrate W can be easily immersed in the processing liquid in the immersion bath 400.

In addition, as described above, in a state in which the second supplying portion 40 supplies the processing liquid toward the substrate W, the lifting/lowering mechanism 310 (moving mechanism 300) immerses the substrate W in the processing liquid stored in advance in the immersion bath 400. Therefore, the air existing between the lower surface Wb of the substrate W and the liquid level of the processing liquid is easily discharged radially outward of the substrate W by the processing liquid supplied from the second supplying portion 40. Therefore, the substrate W can be more easily immersed in the processing liquid.

In a state in which the first supplying portion supplies the processing liquid toward the substrate W, the lifting/lowering mechanism 310 (moving mechanism 300) immerses the substrate W in the processing liquid stored in advance in the immersion bath 400. Therefore, since the upper surface Wa of the substrate W is wetted by the processing liquid supplied from the first supplying portion 30, the processing liquid stored in the immersion bath 400 easily flows into the upper surface Wa of the substrate W. In addition, since the timing at which the processing liquid comes into contact with the upper surface Wa of the substrate W (the timing at which the processing starts) is advanced, the cycle time can be shortened.

The first supplying portion 30 includes the nozzle 38 that ejects the processing liquid toward the upper surface Wa of the substrate W, and the nozzle 38 is provided in the spin base 201. Therefore, in the configuration in which the spin base 201 is provided above the substrate W, the processing liquid can be easily ejected to the upper surface Wa of the substrate W.

Further, since the spin base 201 is rotated, the substrate holding portion 200 rotates the substrate W, and the nozzle 38 is disposed at the central portion of the spin base 201. Therefore, even in a case where the spin base 201 is rotated, for example, the nozzle 38 can be suppressed from being moved (rotated) around the rotational axis AX1.

In the first preferred embodiment, for example, an example in which the substrate W is placed on the support table 410 when the substrate W is subjected to the immersion processing with the processing liquid in steps S102 and S105 has been described, but the present invention is not limited thereto. For example, when the substrate W is immersed in the processing liquid stored in the immersion bath 400, the substrate W may be immersed for a predetermined time in a state in which the substrate W is held by the substrate holding portion 200. In this case, the support table 410 need not be provided in the immersion bath 400. In this case, the substrate W may also be immersed while the substrate W is rotated by the substrate holding portion 200. With this configuration, since the substrate W can be immersed in a state in which the processing liquid is convected, the substrate W can be processed more uniformly.

### First Modification Example

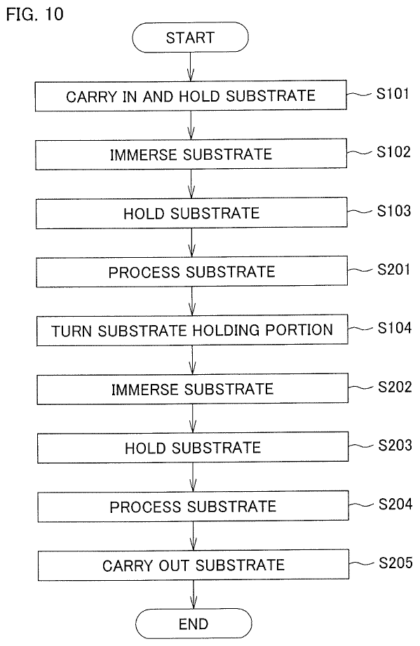

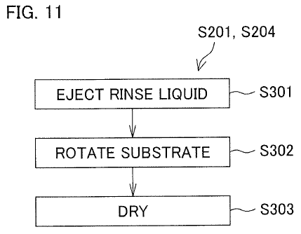

Next, a substrate processing apparatus 100 according to a first modification example of the first preferred embodiment of the present invention will be described with reference to FIGS. 10 and 11. FIG. 10 is a flowchart illustrating a substrate processing method of the substrate processing apparatus 100 according to the first modification example. In the first modification example, unlike the first preferred embodiment, an example in which a plurality of types of processing are performed on the substrate W at one processing position Q will be described. Note that a structure of the substrate processing apparatus 100 of the first modification example is the same as that of the first preferred embodiment.

The substrate processing method according to the first modification example will be described with reference to FIG. 10. The substrate processing method performed by the substrate processing apparatus 100 of the first modification example includes steps S101 to S103, S201, S104, and S202 to S205. Steps S101 to S103, S201, S104, and S202 to S205 are executed by the controlling portion 102.

As illustrated in FIG. 10, steps S101 to S103 are executed in the same manner as in the first preferred embodiment. In the first modification example, in step S102, the substrate W is immersed in the first chemical liquid.

Next, in step S201, the substrate W is processed with the processing liquid (here, the rinse liquid). Specifically, the controlling portion 102 controls the first supplying portion 30 and the second supplying portion 40 to supply the rinse liquid to the substrate W. Thus, the first substrate W1 is rinsed. A detailed flow of step S201 will be described later.

Next, step S104 is executed in the same manner as in the first preferred embodiment.

Next, in step S202, the substrate W is processed with the second chemical liquid. Specifically, the controlling portion 102 controls the moving mechanism 300 to lower the substrate holding portion 200. As a result, the substrate W is immersed in the second chemical liquid stored in advance in the immersion bath 400. That is, the moving mechanism 300 immerses the substrate W in the second chemical liquid by moving (lowering) the substrate holding portion 200 in a state in which the second chemical liquid is stored in the immersion bath 400. In the present preferred embodiment, a predetermined amount of the second chemical liquid is stored in the immersion bath 400 before executing step S202.

At that time, in the present preferred embodiment, in a state in which the substrate holding portion 200 rotates the substrate W, the moving mechanism 300 immerses the substrate W in the second chemical liquid stored in advance in the immersion bath 400.

The controlling portion 102 then controls the substrate holding portion 200 to release the holding of the substrate W by the substrate holding portion 200. Thereafter, the controlling portion 102 controls the moving mechanism 300 to lift the substrate holding portion 200. At that time, the substrate W is immersed in the second chemical liquid.

Next, in step S203, the substrate W is held by the substrate holding portion 200. Specifically, when a predetermined time has elapsed from the start of the processing of the substrate W with the second chemical liquid in step S202, the controlling portion 102 controls the moving mechanism 300 to lower the substrate holding portion 200. The controlling portion 102 then controls the substrate holding portion 200 to hold the substrate W by the substrate holding portion 200.

Next, in step S204, the substrate W is processed with the processing liquid (here, the rinse liquid). Specifically, the controlling portion 102 controls the first supplying portion 30 and the second supplying portion 40 to supply the rinse liquid to the substrate W. Thus, the substrate W is rinsed. Note that a detailed flow of step S204 will be described later.

Next, in step S205, the substrate W is carried out of the chamber 11. Specifically, the controlling portion 102 controls the moving mechanism 300 to lift the substrate holding portion 200.

Similarly to step S106, the controlling portion 102 controls the center robot CR and the substrate holding portion 200 to deliver the substrate W from the substrate holding portion 200 to the center robot CR, and then to carry the substrate W out of the chamber 11.

Other substrate processing methods of the first modification example are the same as those of the first preferred embodiment.

Next, the substrate processing method according to the first modification example will be further described with reference to FIG. 11. FIG. 11 is a detailed flowchart illustrating the substrate processing method according to the first modification example. Here, steps S201 and S204 in FIG. 10 will be described in detail.

As illustrated in FIG. 11, each of steps S201 and S204 includes, for example, steps S301 to S303.

In step S301, the substrate W is rinsed. Specifically, the controlling portion 102 controls the first supplying portion 30 and the second supplying portion 40 to eject the rinse liquid toward the substrate W. At that time, the controlling portion 102 preferably separates the substrate W from the support table 410 by controlling the moving mechanism 300 to move (lift) the substrate holding portion 200. Note that, in step S301, the controlling portion 102 may switch the opening/closing valve 54 of the first discharge portion 50 from the closed state to the open state to drain the chemical liquid in the immersion bath 400. In addition, the chemical liquid in the immersion bath 400 may be replaced with the rinse liquid by ejecting the rinse liquid while maintaining the opening/closing valve 54 of the first discharge portion 50 in the closed state.

Next, in step S302, the controlling portion 102 controls the substrate holding portion 200 to start rotation of the substrate W. At that time, the controlling portion 102 rotates the substrate W in a state in which the substrate W is not immersed in the rinse liquid. For example, the controlling portion 102 may control the moving mechanism 300 to lift the substrate W and then rotate the substrate W. For example, the controlling portion 102 may rotate the substrate W after draining the rinse liquid in the immersion bath 400.

Next, in step S303, the substrate W is dried. Specifically, the controlling portion 102 controls the first supplying portion 30 and the second supplying portion 40 to stop the ejection of the rinse liquid. As a result, since the substrate W is rotated in a state in which the rinse liquid is not ejected, the rinse liquid is discharged from the substrate W, and the substrate W is dried. Note that a rotational speed of the substrate W is not particularly limited, but is, for example, 1500 rpm to 2000 rpm or more.

Here, an example in which the substrate W is dried after the ejection of the rinse liquid is stopped has been described, but the present invention is not limited thereto. The substrate W may or need not be dried. Further, for example, step S201 need not include step S303 (drying step), and step S204 may include step S303.

In the first modification example, as described above, a plurality of types of processing are performed on the substrate W at one processing position Q. Therefore, since a plurality of types of processing can be performed in a small space, it is possible to suppress an increase in size of the substrate processing apparatus 100.

### Second Modification Example

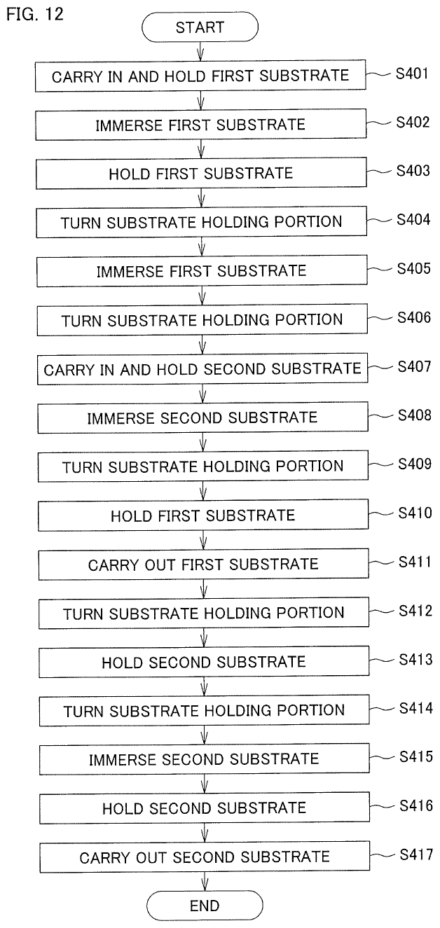

Next, a substrate processing apparatus 100 according to a second modification example of the first preferred embodiment of the present invention will be described with reference to FIG. 12. FIG. 12 is a flowchart illustrating a substrate processing method of the substrate processing apparatus 100 according to the second modification example.

In the second modification example, unlike the first preferred embodiment, etc., an example in which a plurality of substrates W are processed in parallel will be described. Note that, in the present specification, the preferred embodiments, etc., indicate preferred embodiments and modification examples. A structure of the substrate processing apparatus 100 of the second modification example is the same as that of the first preferred embodiment.

The substrate processing method according to the second modification example will be described with reference to FIG. 12. The substrate processing method performed by the substrate processing apparatus 100 of the second modification example includes steps S401 to S417. Steps S401 to S417 are executed by the controlling portion 102. As illustrated in FIG. 12, in step S401, the first substrate W1 is carried into the chamber 11 and held by the substrate holding portion 200 in the same manner as in step S101 described above.

Next, in step S402, the first substrate W1 is processed with the processing liquid (here, the chemical liquid) in the same manner as in step S102 described above. As a result, the holding of the first substrate W1 by the substrate holding portion 200 is released, and the first substrate W1 is immersed in the chemical liquid.

Next, in step S403, the first substrate W1 is held by the substrate holding portion 200 in the same manner as in step S103 described above.

Next, in step S404, the substrate holding portion 200 is turned in the same manner as in step S104 described above. As a result, the substrate holding portion 200 is moved to the processing position Q2.

Next, in step S405, the first substrate W1 is processed with the processing liquid (here, the rinse liquid) in the same manner as in step S105. As a result, the holding of the first substrate W1 by the substrate holding portion 200 is released, and the first substrate W1 is immersed in the rinse liquid.

Next, in step S406, the substrate holding portion 200 is turned. Specifically, the controlling portion 102 controls the moving mechanism 300 to turn the substrate holding portion 200 by a predetermined angle in a direction opposite to that in step S404. As a result, the substrate holding portion 200 is moved to the processing position Q1.

Next, in step S407, the second substrate W2 is carried into the chamber 11 and held by the substrate holding portion 200 in the same manner as in step S401.

Next, in step S408, the second substrate W2 is processed with the processing liquid (here, the chemical liquid) in the same manner as in step S402. As a result, the holding of the second substrate W2 by the substrate holding portion 200 is released, and the second substrate W2 is immersed in the chemical liquid.

Next, in step S409, the substrate holding portion 200 is turned. Specifically, the controlling portion 102 controls the moving mechanism 300 to turn the substrate holding portion 200 by a predetermined angle in the same direction as that in step S404. As a result, the substrate holding portion 200 is moved to the processing position Q2.

Next, in step S410, the first substrate W1 is held by the substrate holding portion 200 in the same manner as in step S403.

Next, in step S411, the first substrate W1 is carried d out of the chamber 11. Specifically, the controlling portion 102 controls the moving mechanism 300 to lift the substrate holding portion 200.

The controlling portion 102 controls the center robot CR and the substrate holding portion 200 to deliver the first substrate W1 from the substrate holding portion 200 to the center robot CR, and then to carry the first substrate W1 out of the chamber 11.

Next, in step S412, the substrate holding portion 200 is turned in the same manner as in step S406. As a result, the substrate holding portion 200 is moved to the processing position Q1.

Next, in step S413, the second substrate W2 is held by the substrate holding portion 200 in the same manner as in step S403.

Next, in step S414, the substrate holding portion 200 is turned in the same manner as in step S404. As a result, the substrate holding portion 200 is moved to the processing position Q2.

Next, in step S415, the second substrate W2 is processed with the processing liquid (here, the rinse liquid) in the same manner as in step S405. As a result, the holding of the second substrate W2 by the substrate holding portion 200 is released, and the second substrate W2 is immersed in the rinse liquid.

Next, in step S416, the second substrate W2 is held by the substrate holding portion 200 in the same manner as in step S410.

Next, in step S417, the second substrate W2 is carried out of the chamber 11 in the same manner as in step S411.

Other substrate processing methods of the second modification example are similar to those of the first

In the second modification example, an example in which the substrate W is processed with the chemical liquid at the processing position Q1 and the substrate W is processed with the rinse liquid at the processing position Q2 has been described, but the present invention is not limited thereto. For example, as in the first modification example, in the configuration in which the substrate W is processed with the first chemical liquid and the rinse liquid at the processing position Q1 and the substrate W is processed with the second chemical liquid and the rinse liquid at the processing position Q2, the plurality of substrates W may be processed in parallel.

In the second modification example, the cycle time of the plurality of substrates W can be shortened by processing the plurality of substrates W in parallel.

Other effects of the second modification example are similar to those of the first preferred embodiment, etc.

### Second Preferred Embodiment

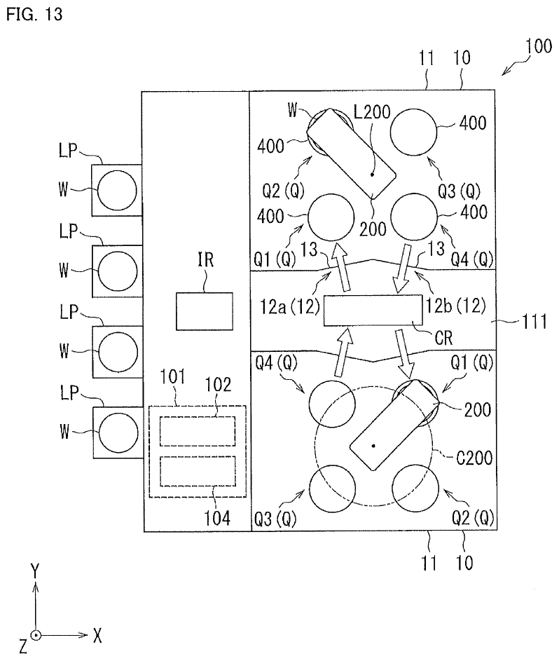

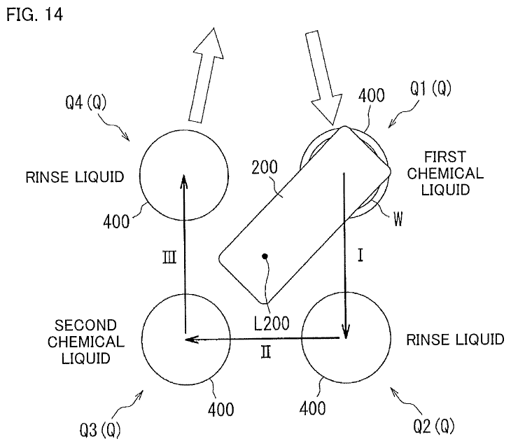

Next, a substrate processing apparatus 100 according to a second preferred embodiment of the present invention will be described with reference to FIGS. 13 to 15. FIG. 13 is a schematic plan view of the substrate processing apparatus 100 according to the second preferred embodiment. FIG. 14 is a schematic plan view illustrating the inside of one chamber 11 of the substrate processing apparatus 100 of the second preferred embodiment. In the second preferred embodiment, unlike the first preferred embodiment, etc., an example in which the substrate holding portion 200 can perform one rotation about the turning axis L200 will be described.

As illustrated in FIG. 13, the substrate processing unit 10 includes a plurality of processing positions Q. In the present preferred embodiment, a plurality of (here, four) processing positions Q are provided in each chamber 11.

The plurality of processing positions Q are located on the circle C200. Thus, the substrate holding portion 200 turns about the turning axis L200, so that the substrate W can be easily delivered to, for example, a member (here, the immersion bath 400) at any processing position Q. Hereinafter, in order to facilitate understanding, the four processing positions Q may be referred to as a processing position Q1, a processing position Q2, a processing position Q3, and a processing position Q4. In the present preferred embodiment, the processing position Q1, the processing position Q2, the processing position Q3, and the processing position Q4 are disposed in order in the clockwise direction. In addition, the processing position Q1 is disposed at a position closer to the first opening 12a than the other three processing positions Q. That is, the processing position Q1 is disposed to face the first opening 12a. The processing position Q1 is a position where the substrate W is carried in.

In the present preferred embodiment, the substrate holding portion 200 can perform one rotation (one turn) or more around the turning axis L200.

In the present preferred embodiment, the plurality of processing positions Q are disposed around the turning axis L200 over about one turn. For example, the plurality of processing positions Q disposed at intervals of 90°.

In the present preferred embodiment, the substrate W is processed by using different types of chemical liquids. Specifically, the substrate W is processed by using the first chemical liquid and the second chemical liquid. For example, at the processing position Q1, the substrate W is processed by using the first chemical liquid. For example, at the processing position Q2, the substrate W is processed by using the rinse liquid. For example, at the processing position Q3, the substrate W is processed by using the second chemical liquid. For example, at the processing position Q4, the substrate W is processed by using the rinse liquid. The third processing position includes a third processing position (for example, the processing position Q2) at which the substrate W processed at the first processing position (for example, the processing position Q1) is rinsed and a third processing position (for example, the processing position Q4) at which the substrate W processed at the second processing position (for example, the processing position Q3) is rinsed.

That is, as illustrated in FIG. 14, the plurality of processing positions Q include a first processing position (for example, the processing position Q1) at which the substrate W is processed with the first chemical liquid, a second processing position (for example, the processing position Q3) at which the substrate W is processed with the second chemical liquid different from the first chemical liquid, and a third processing position (for example, the processing position Q2 and the processing position Q4) at which the substrate W is processed with the rinse liquid.

In the present preferred embodiment, the substrate holding portion 200 sequentially transfers the substrate W to the plurality of processing positions Q in a predetermined turning direction (for example, in the clockwise direction) about the turning axis L200.

Specifically, the substrate holding portion 200 transfers the substrate W from the processing position Q1 to the processing position Q2, the processing position Q3, and the processing position Q4 in this order (see arrows I to III in FIG. 14).

Other structures of the second preferred embodiment are the same as those of the first preferred embodiment, etc.

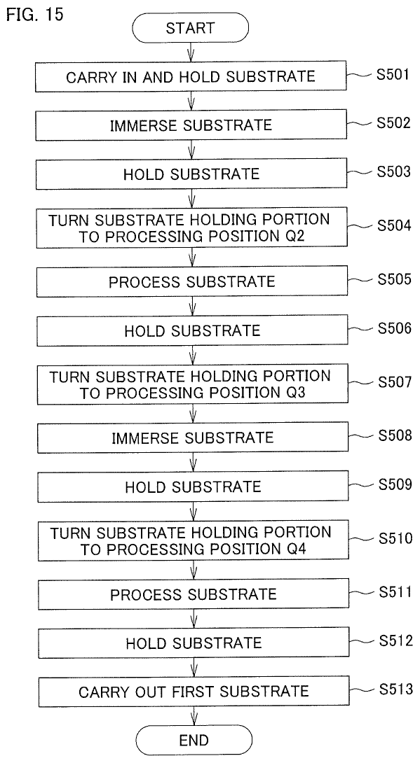

Next, a substrate processing method according to the second preferred embodiment will be described with reference to FIG. 15. FIG. 15 is a flowchart illustrating the substrate processing method according to the second preferred embodiment. The substrate processing method performed by the substrate processing apparatus 100 according to the second preferred embodiment includes steps S501 to S513.

As illustrated in FIG. 15, in step S501, the substrate W is carried into the chamber 11 and held by the substrate holding portion 200 in the same manner as in step S101 described above. At that time, the substrate W is carried into the chamber 11 through the first opening 12a.

Next, in step S502, the substrate W is processed with the first chemical liquid in the same manner as in step S102 described above. As a result, the holding of the substrate W by the substrate holding portion 200 is released, and the substrate W is immersed in the first chemical liquid.

Next, in step S503, the substrate W is held by the substrate holding portion 200 in the same manner as in step S103.

Next, in step S504, the substrate holding portion 200 is turned to the processing position Q2 in the same manner as in step S104.

Next, in step S505, the substrate W is processed with the rinse liquid. At that time, for example, as will be described later, the substrate W need not be immersed in the rinse liquid. In addition, for example, the substrate W may be immersed in the rinse liquid in the same manner as in step S502 described above.

Next, in step S506, for example, the substrate W is held by the substrate holding portion 200 in the same manner as in step S503. In a case where the holding of the substrate W by the substrate holding portion 200 is not released in step S505, the holding of the substrate W by the substrate holding portion 200 is maintained in step S506.

Next, in step S507, the substrate holding portion 200 is turned to the processing position Q3 in the same manner as in step S504.

Next, in step S508, the substrate W is processed with the second chemical liquid in the same manner as in step S502 described above. As a result, the holding of the substrate W by the substrate holding portion 200 is released, and the substrate W is immersed in the second chemical liquid.

Next, in step S509, the substrate W is held by the substrate holding portion 200 in the same manner as in step S503.

Next, in step S510, the substrate holding portion 200 is turned to the processing position Q4 in the same manner as in step S504.

Next, in step S511, the substrate W is processed with the rinse liquid in the same manner as in step S505 described above.

Next, in step S512, the substrate W is held by the substrate holding portion 200 in the same manner as in step S506.

Next, in step S513, the substrate W is carried out of the chamber 11. Specifically, the controlling portion 102 controls the moving mechanism 300, the substrate holding portion 200, and the center robot CR to hold the substrate W by the center robot CR and then to carry the substrate W out of the chamber 11. At that time, the substrate W is carried out of the chamber 11 through the second opening 12b.

As described above, the processing on the substrate W ends.

Other substrate processing methods of the second preferred embodiment are the same as those of the first preferred embodiment, etc. In the second preferred embodiment, an example in which one substrate W is processed has been described, but the present invention is not limited thereto. A plurality of substrates W can be processed in parallel.

In the present preferred embodiment, as described above, the substrate holding portion 200 can perform one rotation (one turn) or more about the turning axis L200. Therefore, it is possible to suppress the occurrence of waste in the movement of the substrate holding portion 200. Specifically, the substrate holding portion 200 can reach the plurality of processing positions Q without waste, for example, by appropriately turning in the clockwise direction or the counterclockwise direction.

As described above, the substrate holding portion 200 sequentially transfers the substrate W to the plurality of processing positions Q in a predetermined turning direction (here, in the clockwise direction) about the turning axis L200. Therefore, it is possible to suppress the occurrence of waste in the movement of the substrate holding portion 200.

As described above, the substrate W is processed with the first chemical liquid at the first processing position (for example, the processing position Q1), the substrate W is processed with the second chemical liquid at the second processing position (for example, the processing position Q3), and the substrate W is processed with the rinse liquid at the third processing position (for example, the processing positions Q2 and Q4). Therefore, in one chamber 11, the substrate W can be processed with at least three processing liquids.

As described above, the plurality of third processing positions (for example, the processing positions Q2 and Q4) include the third processing position (for example, the processing position Q2) at which the substrate W processed at the first processing position (for example, the processing position Q1) is rinsed and the third processing position (for example, the processing position Q4) at which the substrate W processed at the second processing position (for example, the processing position Q3) is rinsed. Therefore, for example, even in a case where the substrate W is subjected to the immersion processing with the rinse liquid, it is possible to prevent mixing of a plurality of chemical liquids with the rinse liquid. In addition, unlike the case where only one third processing position at which the substrate W is processed with the rinse liquid is provided, it is possible to suppress the occurrence of, for example, the standby time of the rinse processing at the third processing position.

Other effects of the second preferred embodiment are similar to those of the first preferred embodiment, etc.

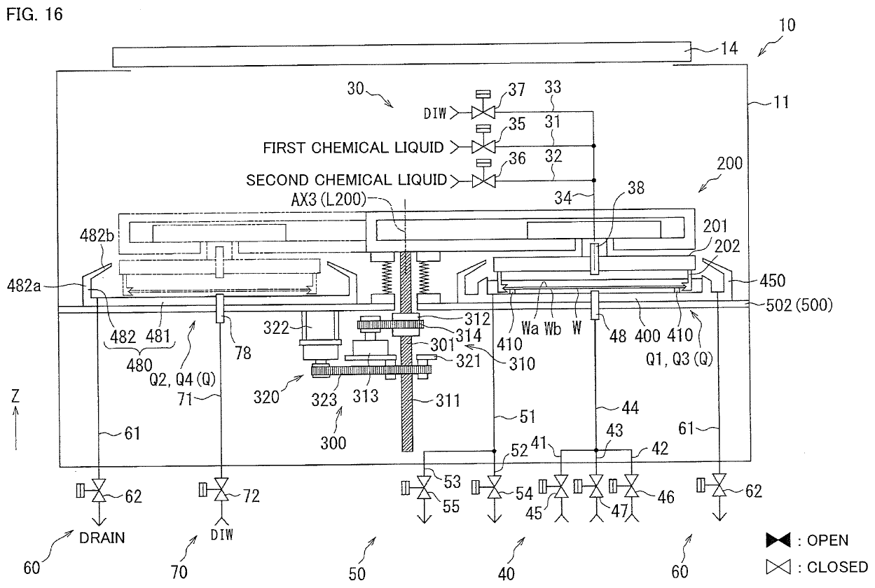

Next, the substrate processing unit 10 in the substrate processing apparatus 100 according to the second preferred embodiment will be further described with reference to FIG. 16. FIG. 16 is a schematic view of the substrate processing unit 10 in the substrate processing apparatus 100 according to the second preferred embodiment.

As illustrated in FIG. 16, the substrate processing unit 10 according to the second preferred embodiment includes the four processing positions Q as described above. The processing position Q1 and the processing position Q3 are configured similarly to the processing position Q of the first preferred embodiment, etc. On the other hand, the processing position Q2 and the processing position Q4 have a configuration suitable for a case where only the rinse processing is performed without performing the processing using the chemical liquid. Note that it is also possible to perform processing using the chemical liquid at the processing position Q2 and the processing position Q4.

The substrate processing unit 10 includes the cup 480. The cup 480 is disposed at the processing position Q2 and the processing position Q4.

The cup 480 has a container shape with an open upper surface and accommodates the substrate W. The substrate W is rinsed in a state of being disposed in the cup 480.

The cup 480 has, for example, a substantially circular shape in plan view. The cup 480 has a bottom wall 481 and a side wall 482. The bottom wall 481 may have a circular shape in plan view. The side wall 482 is connected to the bottom wall 481. The side wall 482 may be connected to an end portion (peripheral edge portion) of the bottom wall 481. The side wall 482 extends upward from the bottom wall 481.

The side wall 482 has a structure similar to that of the side wall 402 of the cup 450. Specifically, the side wall 482 has a lower wall portion 482a and an upper wall portion 482b. The lower wall portion 482a extends upward from the bottom wall 481. The upper wall portion 482b is inclined inward and upward from the upper end of the lower wall portion 482a.

The cup 480 collects, for example, a processing liquid (here, the rinse liquid) scattered d around the periphery of the substrate W due to the rotation of the substrate W. An exhaust device (not illustrated) may be connected to the cup 480, and the gas in the inner space of the cup 480 may be exhausted out of the chamber 11.

The substrate processing apparatus 100 includes a third supplying portion 70. The third supplying portion 70 is controlled by the controlling portion 102.

The third supplying portion 70 supplies the rinse liquid to the cup 480. The third supplying portion 70 supplies the rinse liquid from below the cup 480. In the present preferred embodiment, the third supplying portion 70 can eject the processing liquid toward the lower surface Wb of the substrate W held by the substrate holding portion 200.

Specifically, the third supplying portion 70 includes a rinse liquid piping 71, an opening/closing valve 72, and a nozzle 78.

The rinse liquid piping 71 is an annular member and allows the rinse liquid to flow therethrough.

The rinse liquid is supplied from a supply source to the rinse liquid piping 71. The downstream end of the rinse liquid piping 71 is connected to the nozzle 78.

The nozzle 78 ejects the rinse liquid. In the present preferred embodiment, the nozzle 78 ejects the processing liquid toward the lower surface Wb of the substrate W held by the substrate holding portion 200. The nozzle 78 is disposed at the central portion of the cup 480.

In the present preferred embodiment, the tip (upper end) of the nozzle 78 protrudes upward from the upper surface of the bottom wall 481 of the cup 480. The nozzle 78 may be formed separately from the cup 480, or may be formed by a portion of the cup 480.

The second discharge portion 60 is connected to the bottom wall 481 of the cup 480. The second discharge portion 60 discharges the processing liquid (here, the rinse liquid) in the cup 480 out of the cup 480.

The opening/closing valve 72 is provided in the rinse liquid piping 71, and opens and closes a flow path in the rinse liquid piping 71. The opening/closing valve 72 adjusts the opening degree of the rinse liquid piping 71 to adjust a flow rate of the rinse liquid supplied to the rinse liquid piping 71. The opening/closing valve 72 includes a valve body (not illustrated) inside which a valve seat is provided, a valve element that opens and closes the valve seat, and an actuator (not illustrated) that moves the valve element between an open position and a closed position.

In the present preferred embodiment, by configuring the processing position Q2 and the processing position Q4 (hereinafter, referred to as rinse processing positions in some cases in the second preferred embodiment) as described above, the configurations of the processing position Q2 and the processing position Q4 at which the rinse processing is performed can be simplified.

Other configurations of the second preferred embodiment are similar to those of the first preferred embodiment, etc.

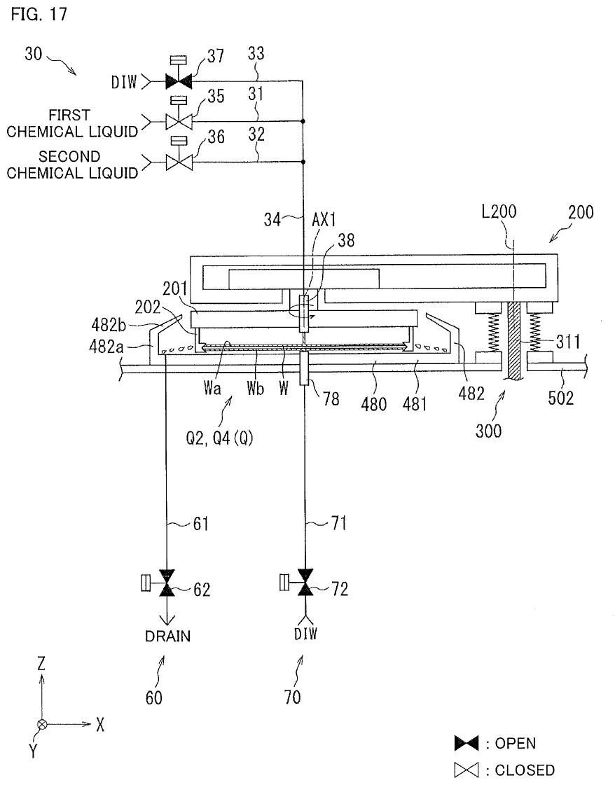

Next, the rinse processing at the processing position Q2 and the processing position Q4 (rinse processing positions) of the second preferred embodiment will be described with reference to FIG. 17. That is, steps S505 and S511 in FIG. 15 will be described. FIG. 17 is a schematic view for describing rinse processing at the processing position Q2 and the processing position Q4 according to the second preferred embodiment.

As illustrated in FIG. 17, the substrate W is disposed in the cup 480. Specifically, the controlling portion 102 controls the moving mechanism 300 to lower the substrate holding portion 200. As a result, the substrate W is located in the cup 480.

The controlling portion 102 controls the substrate holding portion 200 to start rotation of the substrate W. Thereafter, the controlling portion 102 switches the opening/closing valve 37 of the first supplying portion 30 and the opening/closing valve 72 of the third supplying portion 70 from the closed state to the open state. As a result, the rinse liquid is ejected from the nozzles 38 and 78 toward the substrate W. The rinse liquid ejected to the upper surface Wa and the lower surface Wb of the substrate W flows from the central portion to the peripheral edge portion of the substrate W and then is discharged radially outward. The rinse liquid discharged from the substrate W is received by the cup 480 and discharged from the second discharge portion 60 to the outside of the chamber 11.

The controlling portion 102 switches the opening/closing valve 37 and the opening/closing valve 72 from the open state to the closed state. As a result, the supply of the rinse liquid to the substrate W is stopped.

Thereafter, after the rinse liquid is discharged from the substrate W, the controlling portion 102 controls the substrate holding portion 200 to stop the rotation of the substrate W.

The controlling portion 102 controls the moving mechanism 300 to lift the substrate holding portion 200.

As described above, the rinse processing is performed at the processing position Q2 and the processing position Q4 (rinse processing positions).

Note that the immersion bath 400 may be provided instead of the cup 480 at the processing position Q2 and the processing position Q4, and the substrate W may be immersed in the rinse liquid to perform the rinse processing. In this case, the four substrates W can be processed in parallel by advancing the processing position Q of the subsequent substrate W by one every time the processing position Q of the leading substrate W is advanced by one. As described above, the same number of substrates W as the number of processing positions Q (here, four) at which the immersion processing is performed can be processed in parallel.

### Third Modification Example

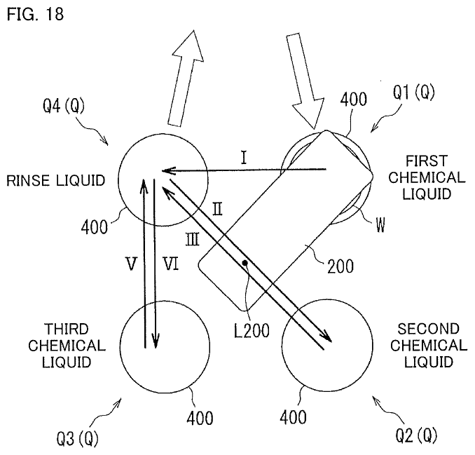

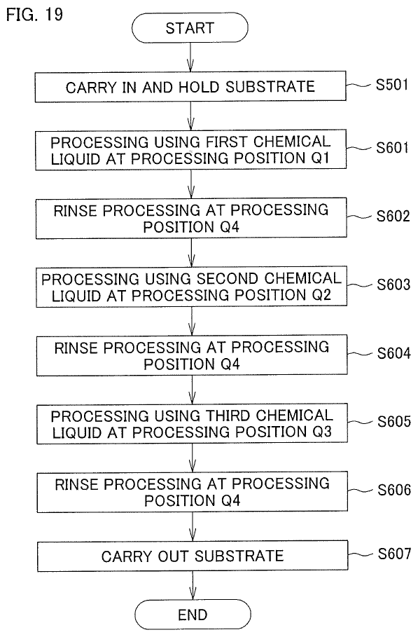

Next, a substrate processing apparatus 100 according to a third modification example of the second preferred embodiment of the present invention will be described with reference to FIGS. 18 and 19. FIG. 18 is a schematic plan view illustrating the inside of one chamber 11 of the substrate processing apparatus 100 of the third modification example. In the third modification example, unlike the second preferred embodiment, an example in which substrates W processed by using different types of chemical liquids are rinsed at one processing position Q will be described.

As illustrated in FIG. 18, in the third modification example, a plurality of processing positions Q include a first chemical liquid processing position (for example, the processing position Q1) at which the substrate W is processed with a first chemical liquid, a second chemical liquid processing position (for example, the processing position Q2) at which the substrate W is processed with a second chemical liquid, a third chemical liquid processing position (for example, the processing position Q3) at which the substrate W is processed with a third chemical liquid different from the first chemical liquid and the second chemical liquid, and a rinse liquid processing position (for example, the processing position Q4) at which the substrate W is processed with a rinse liquid. In the third modification example, the first chemical liquid processing position (processing position Q1) is an example of a “first processing position” of the present invention. The second chemical liquid processing position (processing position Q2) is an example of a “second processing position” of the present invention. The rinse liquid processing position (processing position Q4) is an example of a “third processing position” of the present invention.

In the third modification example, the substrates W are processed by using three different types of chemical liquids. Specifically, the substrates W are processed by using the first chemical liquid, the second chemical liquid, and the third chemical liquid. For example, at the processing position Q1, the substrate W is processed by using the first chemical liquid. For example, at the processing position Q2, the substrate W is processed by using the second chemical liquid. For example, at the processing position Q3, the substrate W is processed by using the third chemical liquid. At the processing position Q4, the substrate W is processed by using the rinse liquid.

At the rinse liquid processing position (for example, the processing position Q4), the substrate W processed at the first chemical liquid processing position (for example, the processing position Q1) is rinsed, the substrate W processed at the second chemical liquid processing position (for example, the processing position Q2) is rinsed, and the substrate W processed at the third chemical liquid processing position (for example, the processing position Q3) is rinsed.

In the third modification example, the substrate holding portion 200 is turned about the turning axis L200 to transfer the substrates W in the order of the processing position Q1, the processing position Q4, the processing position Q2, the processing position Q4, the processing position Q3, and the processing position Q4 (see I to V in FIG. 18).

In the third modification example, although not illustrated, the first supplying portion 30 and the second supplying portion 40 are arranged to be able to supply the third chemical liquid to the immersion bath 400 similarly to the first chemical liquid and the second chemical liquid.

Other structures of the third modification example are similar to those of the second preferred embodiment.

In the third modification example, as described above, at one third processing position (for example, the processing position Q4), the substrate W processed at the first processing position (for example, the processing position Q1) is rinsed, and the substrate W processed at the second processing position (for example, the processing position Q2) is rinsed. Further, in the third modification example, the substrate W processed at the processing position Q3 is also rinsed at one third processing position (for example, the processing position Q4). That is, the rinse processing position (third processing position) is shared. Therefore, it is possible to suppress an increase in the number of rinse processing positions (third processing positions). Therefore, it is possible to suppress an increase in size of the chamber 11 and an increase in the number of components.

Other effects of the third modification example are similar to those of the second preferred embodiment.

Next, a substrate processing method according to the third modification example will be described with reference to FIG. 19. FIG. 19 is a flowchart illustrating the substrate processing method according to the third modification example. The substrate processing method performed by the substrate processing apparatus 100 of the third modification example includes steps S501 and S601 to S607. Note that a method of turning the substrate holding portion 200, a method of holding and releasing the substrate W, etc., are similar to those in the above preferred embodiments, etc., and thus description thereof will be omitted.

As illustrated in FIG. 19, step S501 is executed in the same manner as in the second preferred embodiment.

Next, in step S601, the controlling portion 102 controls the moving mechanism 300 and the substrate holding portion 200, etc., to immerse the substrate W in the first chemical liquid at the processing position Q1.

Next, in step S602, the controlling portion 102 controls the moving mechanism 300 and the substrate holding portion 200, etc., to rinse the substrate W with the rinse liquid at the processing position Q4.

Next, in step S603, the controlling portion 102 controls the moving mechanism 300 and the substrate holding portion 200, etc., to immerse the substrate W in the second chemical liquid at the processing position Q2.

Next, in step S604, the controlling portion 102 controls the moving mechanism 300 and the substrate holding portion 200, etc., to rinse the substrate W with the rinse liquid at the processing position Q4.

Next, in step S605, the controlling portion 102 controls the moving mechanism 300 and the substrate holding portion 200, etc., to immerse the substrate W in the third chemical liquid at the processing position Q3.

Next, in step S606, the controlling portion 102 controls the moving mechanism 300 and the substrate holding portion 200, etc., to rinse the substrate W with the rinse liquid at the processing position Q4.

Next, in step S607, the controlling portion 102 controls the moving mechanism 300, the substrate holding portion 200, and the center robot CR, etc., to carry the substrate W out of the chamber 11.

As described above, the processing on the substrate W ends.

Other substrate processing methods of the third modification example are similar to those of the second preferred embodiment.

Although not described herein, a plurality of substrates W can be processed in parallel. For example, when the first substrate W1 is subjected to the immersion processing at the processing position Q2 or the processing position Q4, the second substrate W2 may be subjected to the immersion processing at the processing position Q1. Further, for example, when the first substrate W1 is subjected to the immersion processing at the processing position Q3 or the processing position Q4, the second substrate W2 may be subjected to the immersion processing at the processing position Q2, and the third substrate W3 may be subjected to the immersion processing at the processing position Q1.

### Fourth Modification Example

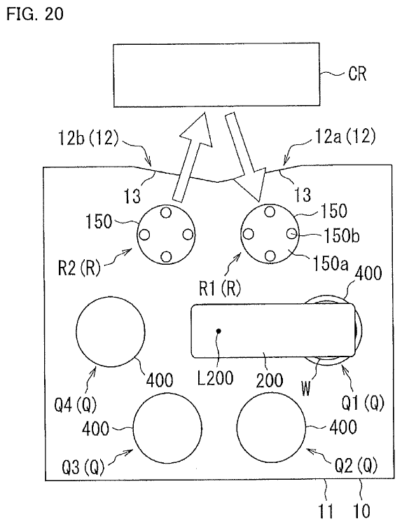

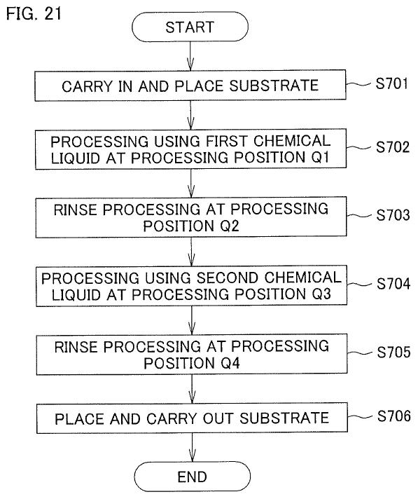

Next, a substrate processing apparatus 100 according to a fourth modification example of the second preferred embodiment of the present invention will be described with reference to FIGS. 20 and 21. FIG. 20 is a schematic plan view of the substrate processing apparatus 100 according to the fourth modification example. In the fourth modification example, unlike the first preferred embodiment and the second preferred embodiment, etc., an example in which a delivery table 150 is provided in the chamber 11 will be described.

As illustrated in FIG. 20, the substrate processing unit 10 includes the delivery table 150. The delivery table 150 is a table for delivering the substrate W between the center robot CR and the substrate holding portion 200. The delivery table 150 supports the substrate W. The delivery table 150 is an example of a “supporting member” of the present invention.

Specifically, the delivery table 150 includes a circular plate 150a and a plurality of (here, four) projection portions 150b protruding upward from the plate 150a. The plurality of projection portions 150b support the lower surface Wb of the substrate W. The plurality of projection portions 150b are disposed, for example, at equal angular intervals (here,) 90° around the center of the plate 150a at the peripheral edge portion of the plate 150a.

The substrate processing unit 10 includes a plurality of processing positions Q and a delivery position R. The delivery position R is provided in the chamber 11. In the present preferred embodiment, a plurality of (here, four) processing positions Q and a plurality of (here, two) delivery positions R are provided in each chamber 11. The delivery table 150 is disposed at the delivery position R. Note that the delivery position R is an example of a “support position” of the present invention.

The plurality of processing positions Q and the plurality of delivery positions R are located on the circle C200. Thus, the substrate holding portion 200 is turned about the turning axis L200 and can thus easily deliver the substrate W to, for example, a member (here, the immersion bath 400) at any processing position Q and the delivery table 150 at the delivery position R.

In the present preferred embodiment, the opening 12 of the chamber 11 is provided for each delivery position R. That is, one opening 12 is provided for one delivery position R. Specifically, the chamber 11 has two openings 12. Two shutters 13 are provided. Two delivery positions R are provided for one chamber 11. The delivery positions R include a first delivery position R1 at which the substrate W is received from the center robot CR and a second delivery position R2 at which the substrate W is passed to the center robot CR. The first opening 12a is located between the center robot CR and the first delivery position R1 in a state in which the center robot CR is disposed at a predetermined position (for example, the position illustrated in FIG. 20). On the other hand, the second opening 12b is located between the center robot CR and the second delivery position R2 in a state in which the center robot CR is disposed at a predetermined position (for example, the position illustrated in FIG. 20).

In the present preferred embodiment, the first delivery position R1, the processing position Q1, the processing position Q2, the processing position Q3, the processing position Q4, and the second delivery position R2 are sequentially disposed in the clockwise direction.

In the present preferred embodiment, the plurality of processing positions Q and the plurality of delivery positions R are disposed around the turning axis L200 over about one turn. The plurality of processing positions Q and the plurality of delivery positions R are disposed, for example, at equal angular intervals (here,) 60° around the turning axis L200.

In the present preferred embodiment, all the substrates W to be processed in the chamber 11 are carried into the chamber 11 through the first opening 12a. All the substrates W processed in the chamber 11 are carried out of the chamber 11 through the same second opening 12b.

Other structures of the fourth modification example are similar to those of the second preferred embodiment.

Next, a substrate processing method according to the fourth modification example will be described with reference to FIG. 21. FIG. 21 is a flowchart illustrating the substrate processing method according to the fourth modification example. The substrate processing method performed by the substrate processing apparatus 100 of the fourth modification example includes steps S701 to S706. Note that a method of turning the substrate holding portion 200, a method of holding and releasing the substrate W, etc., are similar to those in the above preferred embodiments, etc., and thus description thereof will be omitted.

As illustrated in FIG. 21, in step S701, the substrate W is carried into the chamber 11. Specifically, the controlling portion 102 controls the center robot CR to carry the substrate W into the chamber 11 and place the substrate W on the delivery table 150, and then to retract the arm from the first delivery position R1. At that time, the substrate holding portion 200 is located at a position other than the first delivery position R1. At that time, the substrate W is carried into the chamber 11 through the first opening 12a.

Next, in step S702, the controlling portion 102 controls the moving mechanism 300 and the substrate holding portion 200, etc., to immerse the substrate W in the first chemical liquid at the processing position Q1.

Next, in step S703, the controlling portion 102 controls the moving mechanism 300 and the substrate holding portion 200, etc., to rinse the substrate W with the rinse liquid at the processing position Q2.

Next, in step S704, the controlling portion 102 controls the moving mechanism 300 and the substrate holding portion 200, etc., to immerse the substrate W in the second chemical liquid at the processing position Q3.

Next, in step S705, the controlling portion 102 controls the moving mechanism 300 and the substrate holding portion 200, etc., to rinse the substrate W with the rinse liquid at the processing position Q4.

Next, in step S706, the controlling portion 102 controls the moving mechanism 300 and the substrate holding portion 200 to place the substrate W on the delivery table 150. Thereafter, the controlling portion 102 controls the center robot CR to receive the substrate W from the delivery table 150 and carry the substrate W out of the chamber 11. At that time, the substrate W is carried out of the chamber 11 through the second opening 12b.

As described above, the processing on the substrate W ends.

Other substrate processing methods of the fourth modification example are similar to those of the second preferred embodiment, etc. In the fourth modification example, an example in which one substrate W is processed has been described, but the present invention is not limited thereto. The same number of substrates W as the number of processing positions Q (here, four) can be processed in parallel.

In the present preferred embodiment, as described above, the delivery position R is provided inside the chamber 11 where the delivery table 150 that supports the substrate W is disposed. Therefore, the substrate holding portion 200 does not need to directly receive the substrate W from the center robot CR. Therefore, even during the operation of the substrate holding portion 200, the center robot CR can deliver and receive the substrate W to and from the delivery table 150. Further, even during the operation of the center robot CR, the substrate holding portion 200 can deliver and receive the substrate W to and from the delivery table 150. Therefore, when the substrate W is delivered between the center robot CR and the substrate holding portion 200, it is possible to suppress the occurrence of a standby time in the center robot CR or the substrate holding portion 200.

Other effects of the fourth modification example are similar to those of the second preferred embodiment, etc.

### Fifth Modification Example

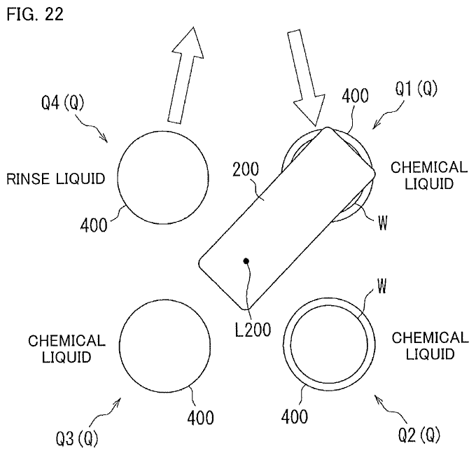

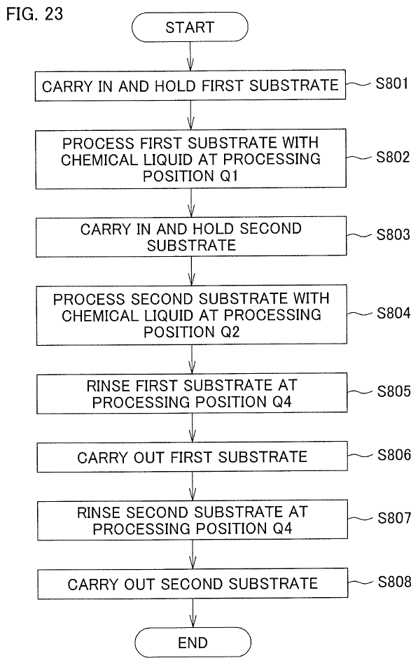

Next, a substrate processing apparatus 100 according to a fifth modification example of the second preferred embodiment of the present invention will be described with reference to FIGS. 22 and 23. FIG. 22 is a schematic plan view illustrating the inside of one chamber 11 of the substrate processing apparatus 100 according to the fifth modification example. In the fifth modification example, unlike the first preferred embodiment and the second preferred embodiment, etc., an example in which the substrate W is processed with the same chemical liquid at a plurality of processing positions Q will be described.

As illustrated in FIG. 22, in the fifth modification example, as in the second preferred embodiment, there are a plurality of (here, four) processing positions Q in the chamber 11. In the fifth modification example, the substrate W is processed with the same chemical liquid at three processing positions (for example, the processing position Q1, the processing position Q2, and the processing position Q3) among the four processing positions Q. The substrate W is processed with a rinse liquid at the remaining one processing position Q (for example, the processing position Q4). In the fifth modification example, the chemical liquid is an example of a “first processing liquid” of the present invention, and the rinse liquid is an example of a “second processing liquid” of the present invention.

Other structures of the fifth modification example are similar to those of the second preferred embodiment.

Next, a substrate processing method according to the fifth modification example will be described with reference to FIG. 23. FIG. 23 is a flowchart illustrating the substrate processing method according to the fifth modification example. The substrate processing method performed by the substrate processing apparatus 100 of the fifth modification example includes steps S801 to S808. Note that a method of turning the substrate holding portion 200, a method of holding and releasing the substrate W, etc., are similar to those in the above preferred embodiments, etc., and thus description thereof will be omitted.

As illustrated in FIG. 23, in step S801, the first substrate W1 is carried into the chamber 11 and held by the substrate holding portion 200 in the same manner as in step S501 described above.

Next, in step S802, the controlling portion 102 controls the moving mechanism 300 and the substrate holding portion 200, etc., to immerse the first substrate W1 in the chemical liquid at the processing position Q1.

Next, in step S803, the second substrate W2 is carried into the chamber 11 and held by the substrate holding portion 200 in the same manner as in step S801.

Next, in step S804, the controlling portion 102 controls the moving mechanism 300 and the substrate holding portion 200, etc., to immerse the second substrate W2 in the chemical liquid at the processing position Q2.

Next, in step S805, the controlling portion 102 controls the moving mechanism 300 and the substrate holding portion 200, etc., to rinse the first substrate W1 with the rinse liquid at the processing position Q4 (rinse processing position).

Next, in step S806, the first substrate W1 is carried out of the chamber 11 in the same manner as in step S513 described above.

Next, in step S807, the controlling portion 102 controls the moving mechanism 300 and the substrate holding portion 200, etc., to rinse the second substrate W2 with the rinse liquid at the processing position Q4 (rinse processing position).

Next, in step S808, the second substrate W2 is carried out of the chamber 11 in the same manner as in step

S806.

As described above, the processing on the first substrate W1 and the second substrate W2 ends.

Other substrate processing methods of the fifth modification example are similar to those of the second preferred embodiment. In the fifth modification example, an example in which two substrates W, the first substrate W1 and the second substrate W2, are processed in parallel has been described, but the present invention is not limited thereto. The same number of substrates W as the number of processing positions Q (here, three) can be processed in parallel.

In the fifth modification example, as described above, the plurality of processing positions Q include at least two (here, two) processing positions Q at which the substrates W are processed with the same chemical liquid. Therefore, for example, the same processing can be performed on at least two substrates W in parallel.

Other effects of the fifth modification example are similar to those of the first preferred embodiment and the second preferred embodiment, etc.

### Third Preferred Embodiment

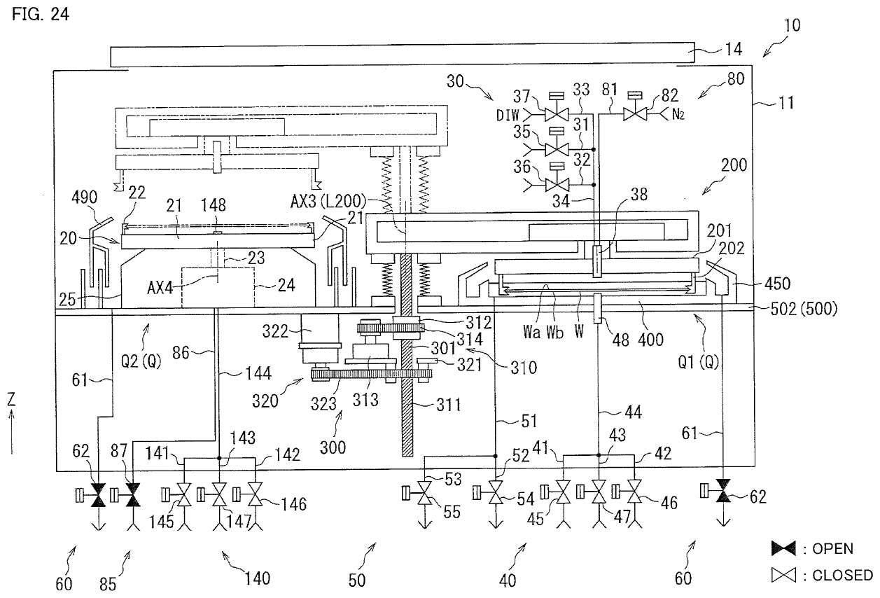

Next, a substrate processing apparatus 100 according to a third preferred embodiment of the present invention will be described with reference to FIGS. 24 to 36. FIG. 24 is a schematic view of a substrate processing unit 10 in the substrate processing apparatus 100 according to the third preferred embodiment. In the third preferred embodiment, unlike the above preferred embodiments, etc., an example in which a lower substrate holding portion 20 is provided at a processing position Q will be described.

As illustrated in FIG. 24, in the third preferred embodiment, the substrate processing unit 10 includes the lower substrate holding portion 20. Note that the lower substrate holding portion 20 is controlled by the controlling portion 102. The lower substrate holding portion 20 is disposed at least at one processing position Q.

The lower substrate holding portion 20 horizontally holds the substrate W. The lower substrate holding portion 20 horizontally holds the substrate W such that the upper surface Wa of the substrate W faces upward and the lower surface Wb of the substrate W faces vertically downward. In addition, the lower substrate holding portion rotates the substrate W while holding the substrate W.

For example, the lower substrate holding portion may be of a holding type that holds the end portion of the substrate W. Alternatively, the lower substrate holding portion 20 may have any mechanism holding the substrate W from the lower surface Wb. For example, the lower substrate holding portion 20 may be of a vacuum type. In this case, the lower substrate holding portion 20 holds the substrate W horizontally by attracting the central portion of the lower surface Wb of the substrate W, which is the non-device forming surface, to the upper surface. Alternatively, the lower substrate holding portion 20 may be of a type of combining a holding type in which a plurality of chuck pins are brought into contact with the circumferential end surface of the substrate W and a vacuum type.

For example, the lower substrate holding portion includes a spin base 21, a chuck member 22, a shaft 23, an electric motor 24, and a housing 25. The chuck member 22 is provided on the spin base 21. The chuck member 22 chucks the substrate W. Typically, the spin base 21 is provided with a plurality of chuck members 22.

The shaft 23 is a hollow shaft. The shaft 23 extends in the vertical direction along a rotational axis AX4. The spin base 21 is coupled to an upper end of the shaft 23. The substrate W is placed above the spin base 21.

The spin base 21 has a disk shape and horizontally supports the substrate W. The shaft 23 extends downward from a central portion of the spin base 21. The electric motor 24 applies a rotational force to the shaft 23. The electric motor 24 rotates the shaft 23 in the rotation direction to rotate the substrate W and the spin base 21 around the rotational axis AX4. The housing 25 surrounds the shaft 23 and the electric motor 24.

The substrate processing unit 10 includes a cup 490. The cup 490 is disposed to surround the periphery of the lower substrate holding portion 20. The cup 490 collects a processing liquid scattered from the substrate W. The cup 490 is lifted and lowered. For example, the cup 490 is lifted vertically upward to the side of the substrate W over a period during which the processing liquid is supplied to the substrate W. In this case, the cup 490 collects the processing liquid that is scattered from the substrate W due to the rotation of the substrate W. When the period during which the processing liquid is supplied to the substrate W ends, the cup 490 is lowered vertically downward from the side of the substrate W. The cup 490 is controlled by the controlling portion 102.

In addition, the second discharge portion 60 and a fourth supplying portion 140 are provided at the processing position Q where the lower substrate holding portion 20 and the cup 490 are disposed. The second discharge portion 60 is connected to a lower portion of the cup 490. The second discharge portion 60 discharges the processing liquid in the cup 490 out of the cup 490.

The fourth supplying portion 140 has the same structure as that of the second supplying portion 40. Specifically, the fourth supplying portion 140 includes a first chemical liquid piping 141, a second chemical liquid piping 142, a rinse liquid piping 143, a common piping 144, an opening/closing valve 145, an opening/closing valve 146, an opening/closing valve 147, and a nozzle 148.

The nozzle 148 of the fourth supplying portion 140 protrudes upward from the central portion of the spin base 21 and ejects the processing liquid toward the substrate W. Other configurations of the first chemical liquid piping 141, the second chemical liquid piping 142, the rinse liquid piping 143, the common piping 144, the opening/closing valve 145, the opening/closing valve 146, the opening/closing valve 147, and the nozzle 148 are similar to the configurations of the first chemical liquid piping 41, the second chemical liquid piping 42, the rinse liquid piping 43, the common piping 44, the opening/closing valve 45, the opening/closing valve 46, the opening/closing valve 47, and the nozzle 48 of the second supplying portion 40.

The substrate processing apparatus 100 includes a fifth supplying portion 80 and a sixth supplying portion 85. The fifth supplying portion 80 and the sixth supplying portion 85 are controlled by the controlling portion 102.

The fifth supplying portion 80 supplies a gas to the substrate W. In the present preferred embodiment, the fifth supplying portion 80 supplies the gas toward the upper surface Wa of the substrate W held by the substrate holding portion 200 or the lower substrate holding portion 20. The gas supplied by the fifth supplying portion 80 is not particularly limited, but is preferably an inert gas such as a nitrogen gas (N₂ gas), a helium gas (He gas), or an argon gas (Ar gas). In the present preferred embodiment, the gas supplied by the fifth supplying portion 80 is a nitrogen gas.

The fifth supplying portion 80 includes a gas piping 81 and an opening/closing valve 82. The gas piping 81 is a tubular member through which an inert gas flows. An inert gas is supplied from a supply source to the gas piping 81. The downstream end of the gas piping 81 is connected to the nozzle 38. The gas piping 81 allows the inert gas to flow through the nozzle 38.

The opening/closing valve 82 is provided in the gas piping 81 and opens and closes a flow path in the gas piping 81. The opening/closing valve 82 adjusts the opening degree of the gas piping 81 to adjust a flow rate of the inert gas supplied to the gas piping 81.

In the present preferred embodiment, the nozzle 38 is provided with a flow path through which the inert gas passes in addition to a flow path through which the liquid from the first supplying portion 30 passes. The nozzle 38 ejects an inert gas toward the upper surface Wa of the substrate W held by the substrate holding portion 200 or the lower substrate holding portion 20.

The sixth supplying portion 85 supplies a gas to the substrate W. In the present preferred embodiment, the sixth supplying portion 85 supplies the gas toward the lower surface Wb of the substrate W held by the substrate holding portion 200 or the lower substrate holding portion 20. The gas supplied by the sixth supplying portion 85 is the same as the gas supplied by the fifth supplying portion 80.

The sixth supplying portion 85 includes a gas piping 86 and an opening/closing valve 87. The gas piping 86 is a tubular member through which an inert gas flows. The inert gas is supplied from a supply source to the gas piping 86. The downstream end of the gas piping 86 is connected to the nozzle 148. The gas piping 86 allows the inert gas to flow through the nozzle 148.

The opening/closing valve 87 is provided in the gas piping 86 and opens and closes a flow path in the gas piping 86. The opening/closing valve 87 adjusts the opening degree of the gas piping 86 to adjust a flow rate of the inert gas supplied to the gas piping 86.

In the present preferred embodiment, the nozzle 148 is provided with a flow path through which the inert gas passes in addition to a flow path through which the liquid from the fourth supplying portion 140 passes. The nozzle 148 ejects the inert gas toward the lower surface Wb of the substrate W held by the substrate holding portion 200 or the lower substrate holding portion 20. Note that the downstream end of the gas piping 86 may cause the inert gas to flow through a gap (not illustrated) around the periphery of the nozzle 148, and the inert gas may be ejected from the periphery of the nozzle 148 to the lower surface Wb of the substrate W.

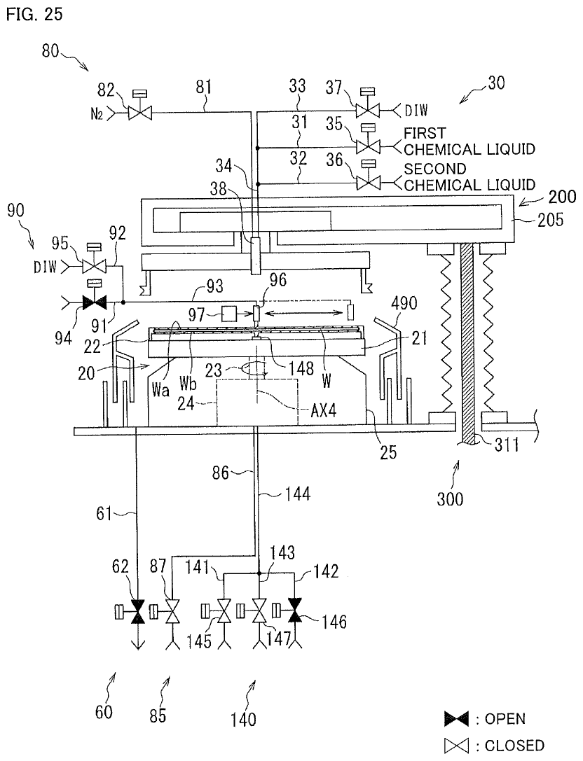

FIG. 25 is a schematic view of the substrate processing unit 10 in the substrate processing apparatus 100 according to the third preferred embodiment. As illustrated in FIG. 25, the substrate processing apparatus 100 includes a seventh supplying portion 90. The seventh supplying portion 90 is controlled by the controlling portion 102.

The seventh supplying portion 90 supplies a processing liquid to the substrate W. In the present preferred embodiment, the seventh supplying portion 90 supplies the processing liquid toward the upper surface Wa of the substrate W held by the substrate holding portion 200.

Specifically, the seventh supplying portion 90 includes a second chemical liquid piping 91, a rinse liquid piping 92, a common piping 93, an opening/closing valve 94, an opening/closing valve 95, a nozzle 96, and a nozzle moving mechanism 97.

The second chemical liquid piping 91, the rinse liquid piping 92, and the common piping 93 are tubular members, and allow the processing liquid to flow therethrough.

A second chemical liquid is supplied from a supply source to the second chemical liquid piping 91. The downstream end of the second chemical liquid piping 91 is connected to the common piping 93. The opening/closing valve 94 is provided in the second chemical liquid piping 91 and opens and closes a flow path in the second chemical liquid piping 91. The opening/closing valve 94 adjusts the opening degree of the second chemical liquid piping 91 to adjust a flow rate of the second chemical liquid supplied to the second chemical liquid piping 91.

A rinse liquid is supplied from a supply source to the rinse liquid piping 92. The downstream end of the rinse liquid piping 92 is connected to the common piping 93. The opening/closing valve 95 is provided in the rinse liquid piping 92, and opens and closes a flow path in the rinse liquid piping 92. The opening/closing valve 95 adjusts the opening degree of the rinse liquid piping 92 to adjust a flow rate of the rinse liquid supplied to the rinse liquid piping 92.

Each of the opening/closing valve 94 and the opening/closing valve 95 includes a valve body (not illustrated) inside which a valve seat is provided, a valve element that opens and closes the valve seat, and an actuator (not illustrated) that moves the valve element between an open position and a closed position.

The downstream end of the common piping 93 is connected to the nozzle 96. The common piping 93 allows the processing liquid to flow through the nozzle 96. The nozzle 96 ejects the processing liquid. In

the present preferred embodiment, the nozzle 96 ejects the processing liquid toward the upper surface Wa of the substrate W held by the lower substrate holding portion 20.

The nozzle moving mechanism 97, for example, lifts and lowers the nozzle 96. For example, the nozzle moving mechanism 97 includes a ball screw mechanism and an electric motor that applies a driving force to the ball screw mechanism. For example, the nozzle moving mechanism 97 horizontally rotates the nozzle 96 about an axis (not illustrated) extending in the vertical direction. For example, the nozzle moving mechanism 97 includes an electric motor.

The seventh supplying portion 90 may include a first chemical liquid piping through which a first chemical liquid is supplied and an opening/closing valve that opens and closes a flow path in the first chemical liquid piping.

In the present preferred embodiment, as illustrated in FIG. 24, the support table 410 is not provided in the immersion bath 400. Note that the support table 410 may be provided in the immersion bath 400.

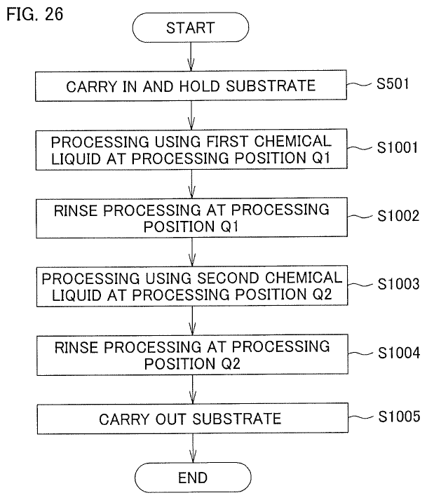

Next, a substrate processing method according to the third preferred embodiment will be described with reference to FIG. 26. FIG. 26 is a flowchart illustrating the substrate processing method according to the third preferred embodiment. The substrate processing method performed by the substrate processing apparatus 100 according to the third preferred embodiment includes steps S501 and S1001 to S1005. Here, an example in which the structure of the present preferred embodiment described with reference to FIG. 24 is applied to the chamber structure described with reference to FIG. 1 in the first preferred embodiment will be described. However, the structure of the present preferred embodiment may be applied to the chamber structure of another preferred embodiment, etc. Note that a method of turning the substrate holding portion 200, a method of holding and releasing the substrate W, etc., are the same as those in the above preferred embodiments, and thus the description thereof will be omitted.

As illustrated in FIG. 26, step S501 is executed in the same manner as in the second preferred embodiment.

Next, in step S1001, the controlling portion 102 controls the moving mechanism 300 and the substrate holding portion 200, etc., to immerse the substrate W in the first chemical liquid at the processing position Q1.

Next, in step S1002, the controlling portion 102 controls the moving mechanism 300 and the substrate holding portion 200, etc., to rinse the substrate W with the rinse liquid at the processing position Q1.

Next, in step S1003, the controlling portion 102 controls the moving mechanism 300, the substrate holding portion 200, and the lower substrate holding portion 20, etc., to process the substrate W held by the lower substrate holding portion 20 with the second chemical liquid at the processing position Q2. At the processing position Q2, the substrate W is not immersed in the chemical liquid.

Next, in step S1004, the controlling portion 102 controls the moving mechanism 300, the substrate holding portion 200, and the lower substrate holding portion 20, etc., to rinse the substrate W with the rinse liquid at the processing position Q2. Note that at the processing position Q2, the substrate W is not immersed in the rinse liquid.

Next, in step S1005, the controlling portion 102 controls the moving mechanism 300, the substrate holding portion 200, and the center robot CR, etc., to carry the substrate W out of the chamber 11.

As described above, the processing on the substrate W ends.

Other substrate processing methods of the third preferred embodiment are the same as those of the first preferred embodiment, etc.

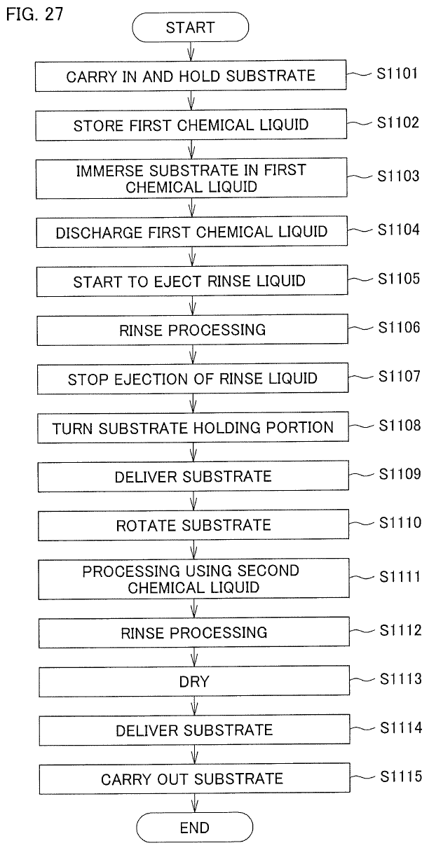

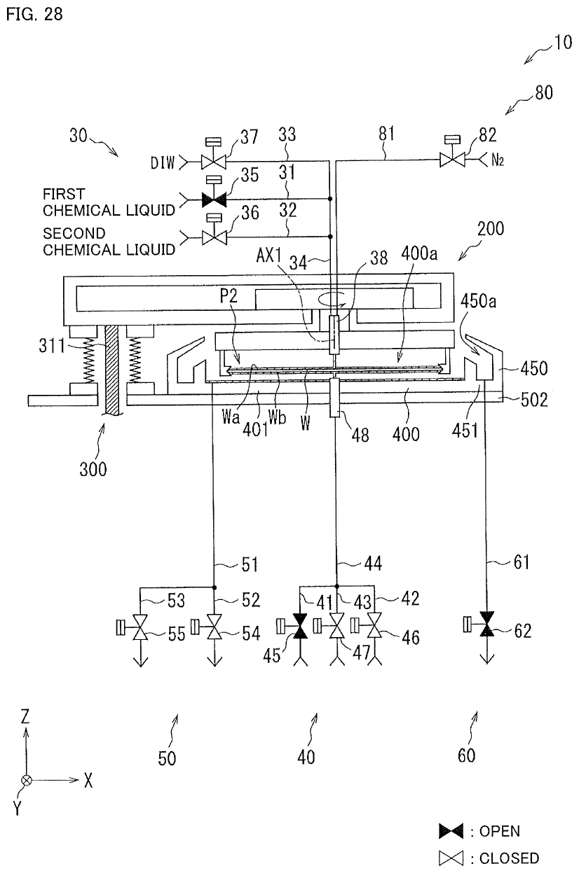

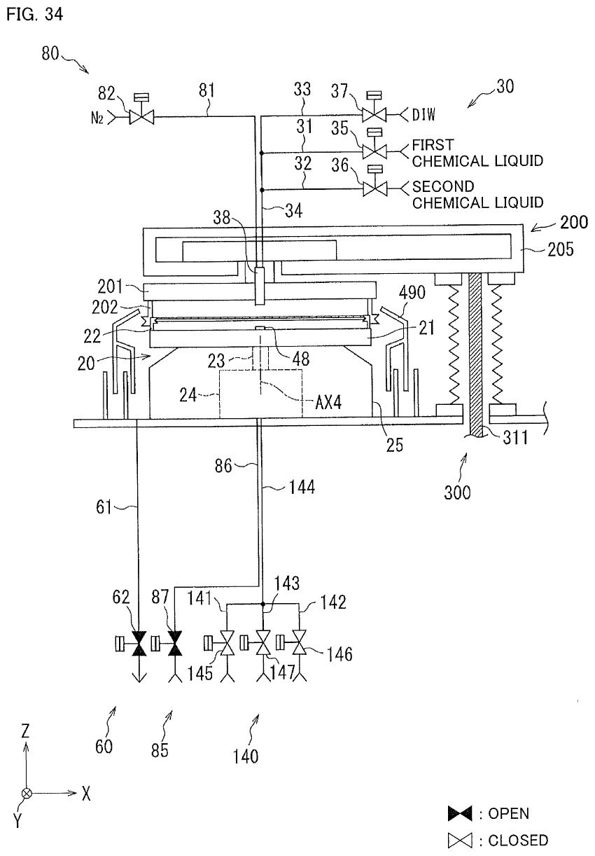

Next, the substrate processing method at the processing position Q1 and the processing position Q2 of the third preferred embodiment will be further described with reference to FIGS. 25 and 27 to 36. FIG. 27 is a detailed flowchart illustrating the substrate processing method according to the third preferred embodiment. FIGS. 28 to 33 are schematic views for describing the substrate processing method at the processing position Q1 of the third preferred embodiment. FIGS. 34 to 36 are schematic views for describing the substrate processing method at the processing position Q2 of the third preferred embodiment. The substrate processing method at the processing position Q1 and the processing position Q2 of the substrate processing apparatus 100 of the third preferred embodiment includes steps S1101 to S1115. For example, step S1101 corresponds to step S501 described above. For example, steps S1102 to S1104 correspond to step S1001 described above. For example, steps S1105 to S1107 correspond to step

S1002 described above. For example, steps S1111 corresponds to step S1003 described above. For example, step S1112 corresponds to step S1004 described above. For example, step S1115 corresponds to step S1005 described above.

As illustrated in FIG. 27, in step S1101, the substrate W is carried into the chamber 11 and the substrate W is held in the same manner as in step S501. At that time, the substrate W is carried into the chamber 11 through the first opening 12a. The opening/closing valves 35 to 37, 45 to 47, 55, 82, 87, 94, 95, and 145 to 147 are in a closed state, and the opening/closing valves 54 and 62 are in an open state.

Next, in step S1102, the first chemical liquid is stored in the immersion bath 400. Specifically, as illustrated in FIG. 28, the controlling portion 102 controls the moving mechanism 300 to lower the substrate holding portion 200 and move the substrate W to the inner space 400a of the immersion bath 400.

The controlling portion 102 then switches the opening/closing valve 54 from the open state to the closed state. In addition, the controlling portion 102 switches the opening/closing valve 35 and the opening/closing valve from the closed state to the open state. As a result, the first chemical liquid is ejected from the nozzle 38 toward the upper surface Wa of the substrate W, and the first chemical liquid is ejected from the nozzle 48 toward the lower surface Wb of the substrate W.

At that time, the controlling portion 102 controls the substrate holding portion 200 to rotate the substrate W. Note that the rotational speed of the substrate W is not particularly limited, but is, for example, 100 rpm or more and 500 rpm or less.

The first chemical liquid flows down from the upper surface Wa and the lower surface Wb of the substrate W and is stored in the immersion bath 400.

In step S1102, since the first chemical liquid is ejected to the substrate W while rotating the substrate W, the first chemical liquid wets and spreads immediately over the entire surface of the upper surface Wa and the lower surface Wb of the substrate W. Therefore, for example, it is possible to suppress a difference in processing time using the first chemical liquid between the central portion and the outer circumferential portion of the substrate W.

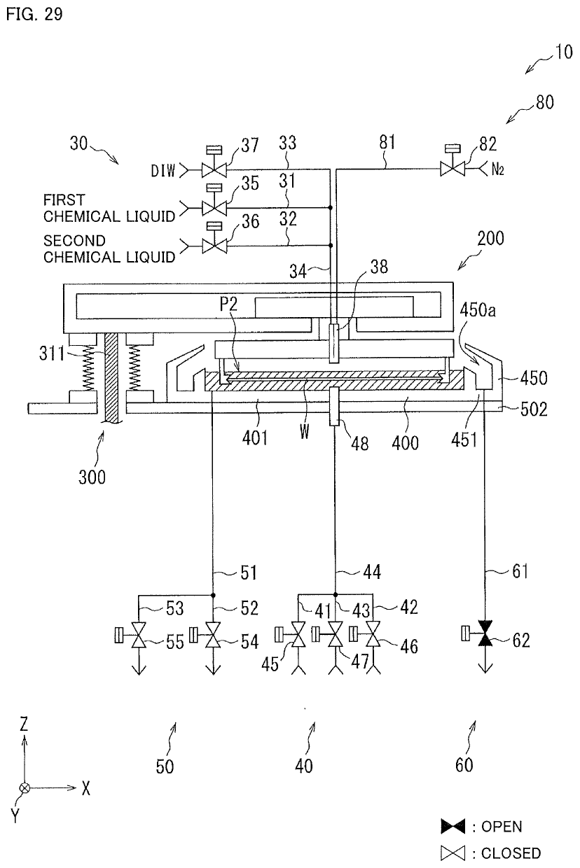

Next, in step S1103, the substrate W is immersed in the first chemical liquid. Specifically, as illustrated in FIG. 29, the controlling portion 102 switches the opening/closing valve 35 and the opening/closing valve 45 from the open state to the closed state when a predetermined time has elapsed from the start of supply of the first chemical liquid. At that time, the liquid level of the first chemical liquid is higher than the upper surface Wa of the substrate W, and the substrate W is immersed in the first chemical liquid. That is, the substrate W is located inside the immersion bath 400 and is in a state of being immersed in the processing liquid.

In addition, the controlling portion 102 controls the substrate holding portion 200 to stop the rotation of the substrate W. Note that the controlling portion 102 need not stop the rotation of the substrate W. That is, the controlling portion 102 may continue the rotation of the substrate W. In this case, a rotational speed of the substrate W is not particularly limited, but may be lower than the rotational speed in step S1102. The rotational speed of the substrate W may be, for example, several tens rpm or more and several hundreds rpm or less.

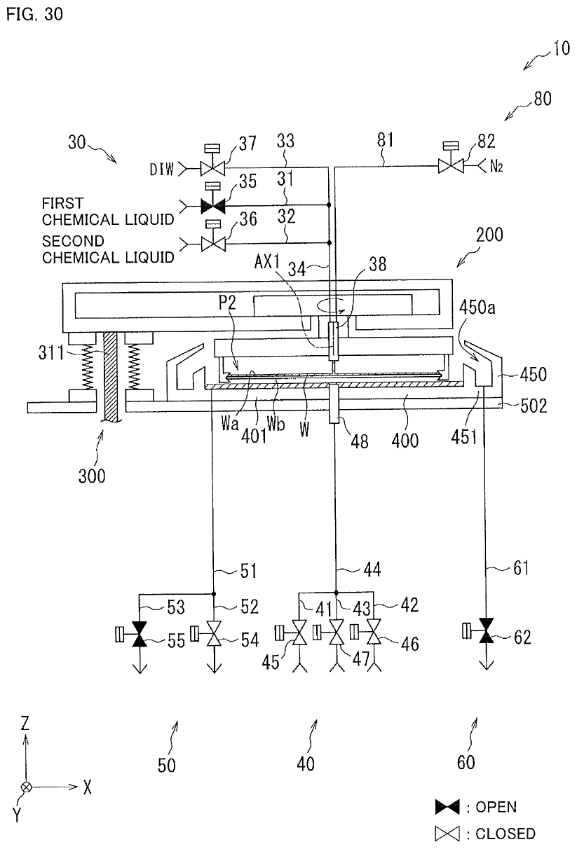

Next, in step S1104, the first chemical liquid is discharged from the immersion bath 400. Specifically, as illustrated in FIG. 30, when a predetermined time has elapsed after switching the opening/closing valve 35 and the opening/closing valve 45 from the open state to the closed state, the controlling portion 102 switches the opening/closing valve 55 from the closed state to the open state. As a result, the first chemical liquid in the immersion bath 400 returns to the processing liquid cabinet. Note that in step S1104, the controlling portion 102 may switch the opening/closing valve 54 from the closed state to the open state and discharge the first chemical liquid.

In addition, when the first chemical liquid is discharged from the immersion bath 400, the controlling portion 102 switches the opening/closing valve 35 from the closed state to the open state. As a result, the first chemical liquid is ejected from the nozzle 38 to the upper surface Wa of the substrate W. Therefore, since the upper surface Wa of the substrate W can be suppressed from drying, it is possible to suppress collapse of the pattern and generation of particles. Note that the amount of the first chemical liquid ejected from the nozzle 38 is smaller than the amount of the first chemical liquid discharged from the first discharge portion 50.

At that time, the controlling portion 102 controls the substrate holding portion 200 to rotate the substrate W. Note that the rotational speed of the substrate W is not particularly limited, but is, for example, 100 rpm or more and 500 rpm or less.

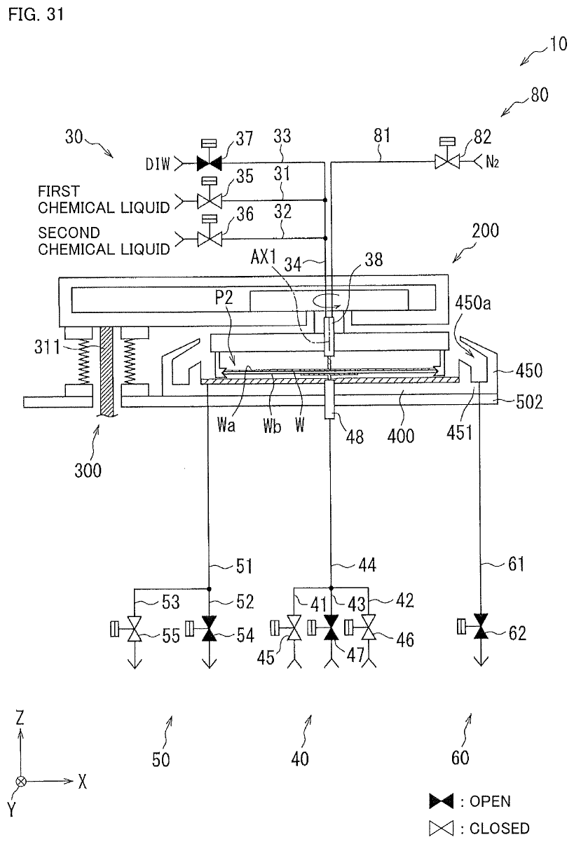

Next, in step S1105, the ejection of the rinse liquid is started. Specifically, as illustrated in FIG. 31, the controlling portion 102 switches the opening/closing valve 54 from the closed state to the open state and switches the opening/closing valve 55 from the open state to the closed state when a predetermined time has elapsed from the start of discharge of the first chemical liquid. At that time, the controlling portion 102 switches the opening/closing valve 35 from the open state to the closed state, and switches the opening/closing valve 37 from the closed state to the open state. As a result, the processing liquid ejected onto the upper surface Wa of the substrate W is switched from the first chemical liquid to the rinse liquid. At that time, the controlling portion 102 also switches the opening/closing valve 47 from the closed state to the open state. As a result, the rinse liquid is ejected from the nozzle 48 to the lower surface Wb of the substrate W.

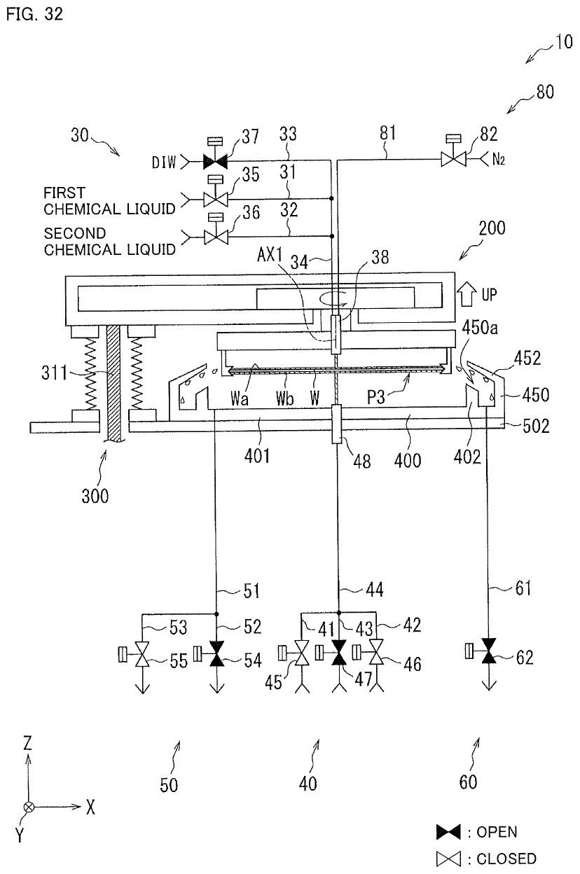

Next, in step S1106, the substrate W is rinsed. Specifically, as illustrated in FIG. 32, the controlling portion 102 maintains the opening/closing valve 37, the opening/closing valve 47, and the opening/closing valve 54 in the open state. As a result, the upper surface Wa and the lower surface Wb of the substrate W are rinsed.

At that time, it is preferable to lift the substrate W. Specifically, the controlling portion 102 moves the substrate holding portion 200 to a third height position P3 at which the substrate W faces the side wall 452 of the cup 450 in the horizontal direction.

Furthermore, for example, the controlling portion 102 may increase the rotational speed of the substrate W after lifting the substrate W to the third height position P3. The rotational speed of the substrate W is not particularly limited, but is, for example, 1500 rpm to 2000 rpm or more.

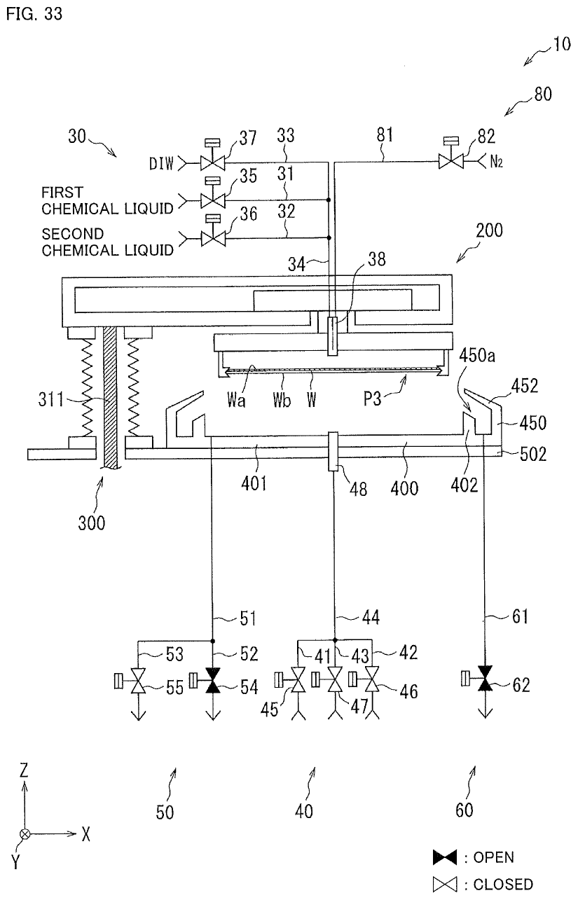

Next, in step S1107, when a predetermined time has elapsed from the start of the ejection of the rinse liquid in step S1105, the controlling portion 102 controls the substrate holding portion 200 to stop the rotation of the substrate W. Thereafter, the controlling portion 102 stops the ejection of the rinse liquid by switching the opening/closing valve 37 and the opening/closing valve 47 from the open state to the closed state. As a result, the upper surface Wa of the substrate W is covered with the rinse liquid (see FIG. 33). Therefore, since the upper surface Wa of the substrate W can be suppressed from being dried, generation of particles, etc., can be suppressed.

As illustrated in FIG. 33, the controlling portion 102 controls the moving mechanism 300 to lift the substrate holding portion 200.

Next, in step S1108, the controlling portion 102 controls the moving mechanism 300 to turn the substrate holding portion 200. As a result, the substrate holding portion 200 is located at the processing position Q2. The substrate W is turned in a state in which the upper surface Wa is covered with the rinse liquid.

Next, in step S1109, as illustrated in FIG. 34, the controlling portion 102 controls the moving mechanism 300, the substrate holding portion 200, and the lower substrate holding portion 20 to deliver the substrate W between the substrate holding portion 200 and the lower substrate holding portion 20. As a result, the substrate W is passed from the substrate holding portion 200 to the lower substrate holding portion 20.

Next, in step S1110, the controlling portion 102 controls the lower substrate holding portion 20 to start rotation of the substrate W.

Next, in step S1111, as illustrated in FIG. 25, the controlling portion 102 controls the seventh supplying portion 90 to move the nozzle 96 above the substrate W. Then, the controlling portion 102 switches the opening/closing valve 94 and the opening/closing valve 146 from the closed state to the open state, so that the second chemical liquid is ejected from the nozzle 96 toward the upper surface Wa of the substrate W and the second chemical liquid is ejected from the nozzle 148 toward the lower surface Wb of the substrate W. At that time, the controlling portion 102 controls the seventh supplying portion 90 to reciprocate the nozzle 96 in the horizontal direction between the position above the central portion of the substrate W and the position above the peripheral edge portion of the substrate W.

Thereafter, when a predetermined time has elapsed from the start of the supply of the second chemical liquid to the substrate W, the controlling portion 102 switches the opening/closing valve 94 and the opening/closing valve 146 from the open state to the closed state to stop the supply of the second chemical liquid.

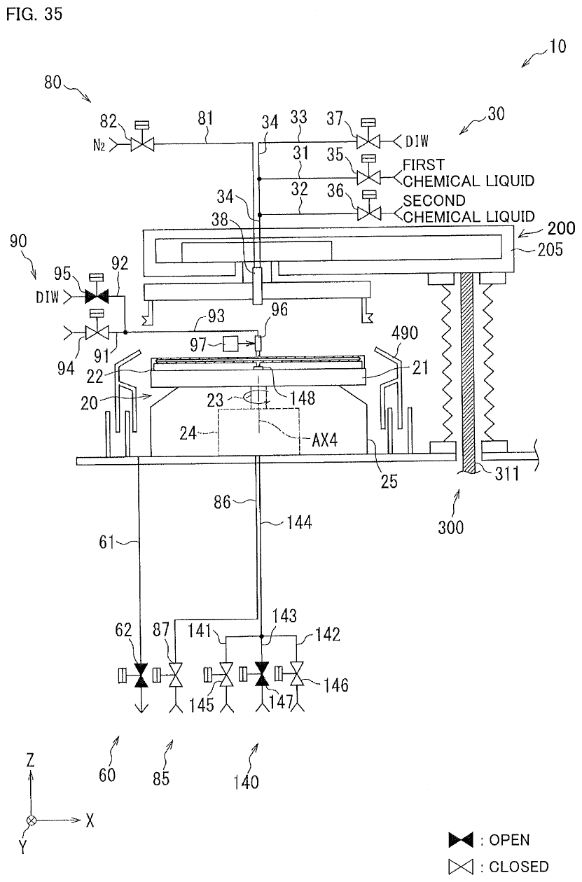

Next, in step S1112, as illustrated in FIG. 35, the controlling portion 102 switches the opening/closing valve 95 and the opening/closing valve 147 from the closed state to the open state. As a result, the rinse liquid is ejected from the nozzle 96 toward the upper surface Wa of the substrate W, and the rinse liquid is ejected from the nozzle 148 toward the lower surface Wb of the substrate W. Note that in step S1112, the nozzle 96 is located at the position above the central portion of the substrate W.

Thereafter, when a predetermined time has elapsed from the start of the supply of the rinse liquid to the substrate W, the controlling portion 102 stops the supply of the rinse liquid by switching the opening/closing valve 95 and the opening/closing valve 147 from the open state to the closed state.

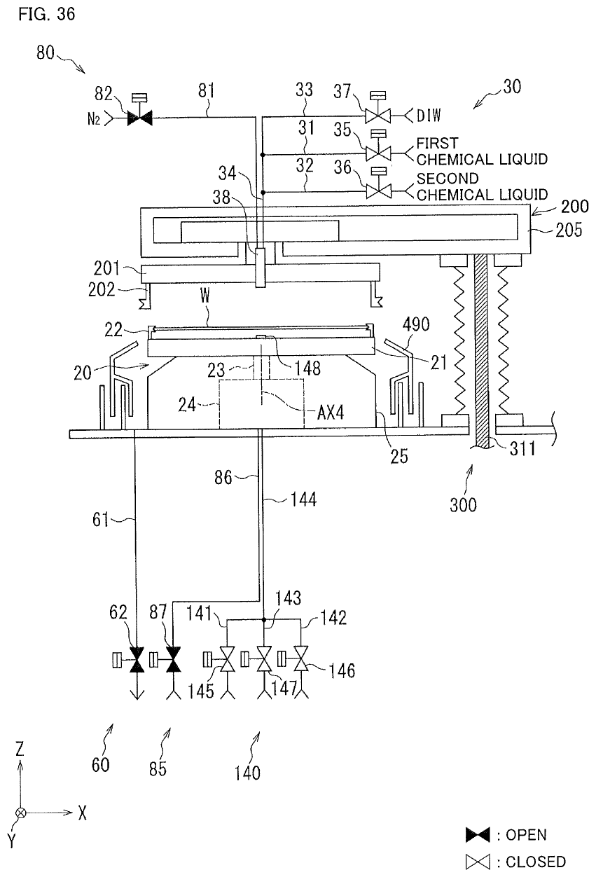

Next, in step S1113, the substrate W is dried. Specifically, as illustrated in FIG. 36, the controlling portion 102 switches the opening/closing valve 82 and the opening/closing valve 87 from the closed state to the open state. As a result, the inert gas is ejected from the nozzle 38 toward the upper surface Wa of the substrate W, and the inert gas is ejected from the nozzle 148 toward the lower surface Wb of the substrate W. In addition, the controlling portion 102 causes the lower substrate holding portion 20 to maintain the rotation of the substrate W. As a result, the rinse liquid on the substrate W is blown off by the inert gas and the centrifugal force, and the substrate W is dried. Thereafter, the controlling portion 102 controls the lower substrate holding portion 20 to stop the rotation of the substrate W.

Next, in step S1114, the controlling portion 102 controls the moving mechanism 300, the substrate holding portion 200, and the lower substrate holding portion 20 to deliver the substrate W between the substrate holding portion 200 and the lower substrate holding portion 20. As a result, the substrate W is passed from the lower substrate holding portion 20 to the substrate holding portion 200.

Next, in step S1115, similarly to step S1005, the controlling portion 102 carries the substrate W out of the chamber 11. At that time, the substrate W is carried out of the chamber 11 through the second opening 12b.

As described above, the processing on the substrate W ends.

In the third preferred embodiment, by configuring the processing position Q2 as described above, it is possible to perform immersion processing and processing (non-immersion processing) using a general single substrate processing apparatus on the substrate W in one chamber 11.

In addition, by ejecting the processing liquid from the first supplying portion 30 and the second supplying portion 40 toward the upper surface Wa and the lower surface Wb of the substrate W, the processing liquid is stored in the immersion bath 400. Therefore, it is possible to perform the processing on the upper surface Wa and the lower surface Wb of the substrate W while storing the processing liquid. In addition, it is possible to suppress an increase in time for storing the processing liquid in the immersion bath 400.

In addition, in a state in which the substrate holding portion 200 rotates the substrate W, the first supplying portion 30 and the second supplying portion 40 eject the processing liquid toward the substrate W, and store the processing liquid in the immersion bath 400. Therefore, the processing liquid ejected onto the substrate W uniformly spreads on the substrate W due to the rotation of the substrate W. Therefore, the occurrence of processing unevenness can be suppressed.

When the first discharge portion 50 discharges the processing liquid in the immersion bath 400, the first supplying portion 30 ejects the processing liquid toward the substrate W. Therefore, it is possible to suppress the substrate W from being dried when the processing liquid in the immersion bath 400 is discharged. In addition, in a case where the substrate W is being rotated, it is possible to suppress the processing liquid bounced back on the side wall 402 of the immersion bath 400 from adhering to the substrate W. Thus, generation of particles can be suppressed.

Other flows and other effects of the third preferred embodiment are similar to those of the above preferred embodiments, etc.

In the third preferred embodiment, an example in which step S1111 is executed after the rotation of the substrate W is started in step S1110 has been described, but for example, step S1110 may be executed in the middle of step S1111.

Further, in the third preferred embodiment, an example in which the rinse processing and the drying processing are performed on the substrate W in a state in which the substrate W is held by the lower substrate holding portion 20 has been described, but the present invention is not limited thereto. For example, the substrate W may be subjected to rinse processing and/or drying processing in a state in which the substrate W is held by the substrate holding portion 200.

In addition, in the third preferred embodiment, an example in which the rinse liquid is supplied from the seventh supplying portion 90 to the upper surface Wa of the substrate W has been described, but the present invention is not limited thereto. For example, the rinse liquid may be supplied from the first supplying portion 30 to the upper surface Wa of the substrate W.

Further, when the substrate W is rinsed in step S1106 after the ejection of the rinse liquid is started in step S1105, the rinse liquid may be stored in the immersion bath 400 in a state in which the opening/closing valve 54 is closed. In this case, the rinse liquid may overflow from the immersion bath 400. As described above, by causing the rinse liquid to overflow from the immersion bath 400, the cup 450 provided around the periphery of the immersion bath 400 can be cleaned by the overflowing rinse liquid.

### Sixth Modification Example

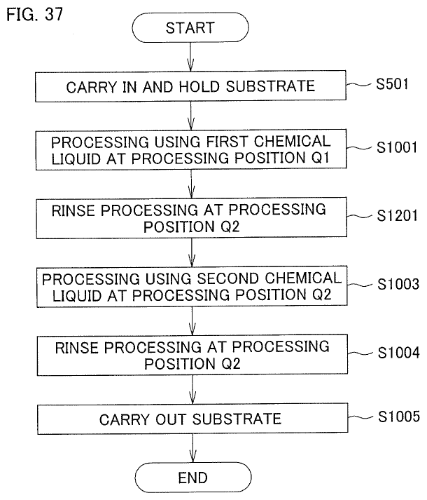

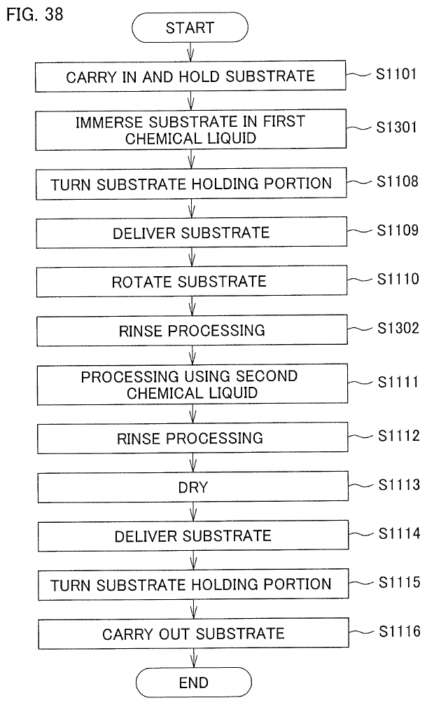

Next, a substrate processing apparatus 100 according to a sixth modification example of the third preferred embodiment of the present invention will be described with reference to FIGS. 37 and 38. FIG. 37 is a flowchart illustrating a substrate processing method according to the sixth modification example. In the sixth modification example, unlike the third preferred embodiment, an example in which the rinse processing is not executed at the processing position Q1 will be described. The substrate processing method performed by the substrate processing apparatus 100 of the sixth modification example includes steps S501, S1001, S1201, and S1003 to S1005. The structure of the sixth modification example is the same as that of the third preferred embodiment.

As illustrated in FIG. 37, step S501 is executed in the same manner as in the third preferred embodiment.

Next, in step S1001, the controlling portion 102 controls the moving mechanism 300 and the substrate holding portion 200, etc., to immerse the substrate W in the first chemical liquid at the processing position Q1.

Next, in step S1201, the controlling portion 102 controls the moving mechanism 300, the substrate holding portion 200, and the lower substrate holding portion 20, etc., to rinse the substrate W with the rinse liquid at the processing position Q2.

Next, steps S1003 to S1005 are executed in the same manner as in the third preferred embodiment.

As described above, the processing on the substrate W ends.

Other substrate processing methods of the sixth modification example are similar to those of the third

Next, the substrate processing method at the processing position Q1 and the processing position Q2 of the sixth modification example will be further described with reference to FIG. 38. FIG. 38 is a detailed flowchart illustrating the substrate processing method according to the sixth modification example. For example, steps S1101, S1301, S1302, S1111, S1112, and S1116 respectively correspond to steps S501, S1001, S1201, S1003, S1004, and S1005 described above.

As illustrated in FIG. 38, step S1101 is executed in the same manner as in the third preferred embodiment.

Next, in step S1301, the substrate W is immersed in the first chemical liquid. At that time, for example, the substrate W is immersed in the first chemical liquid in the same manner as in step S102 of the first preferred embodiment or steps S1102 and S1103 of the third preferred embodiment. In the sixth modification example, similarly to step S102 of the first preferred embodiment, the substrate W is immersed in the first chemical liquid stored in advance in the immersion bath 400.

When a predetermined time has elapsed from the start of the immersion of the substrate W in the first chemical liquid, the controlling portion 102 controls the moving mechanism 300 to lift the substrate holding portion 200 and move the substrate W above the immersion bath 400. At that time, the upper surface Wa of the substrate W is covered with the first chemical liquid.

Next, step S1108 is executed in the same manner as in the third preferred embodiment. Note that the substrate W is turned in a state in which the upper surface Wa is covered with the first chemical liquid. Therefore, since the upper surface Wa of the substrate W can be suppressed from being dried, generation of particles, etc., can be suppressed.

Next, steps S1109 and S1110 are executed in the same manner as in the third preferred embodiment. As a result, the substrate W is rotated in a state of being held by the lower substrate holding portion 20.

Next, in step S1302, the substrate W is rinsed in the same manner as in step S1112 of the third preferred embodiment.

Next, steps S1111 to S1116 are executed in the same manner as in the third preferred embodiment.

In the sixth modification example, as described above, the rinse processing is not performed at the processing position Q1. Therefore, as in step S102 of the first preferred embodiment, the substrate W can be immersed in the first chemical liquid stored in advance in the immersion bath 400. Therefore, it is not necessary to replace the processing liquid in the immersion bath 400 every time the substrate W is immersed. Therefore, the consumption amount of the processing liquid can be further reduced.

Other flows and other effects of the sixth modification example are similar to those of the third preferred embodiment.

### Fourth Preferred Embodiment

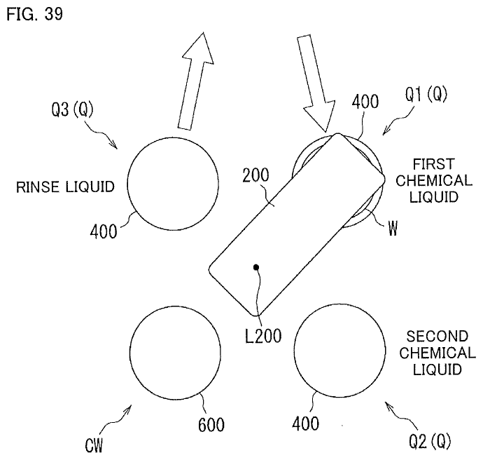

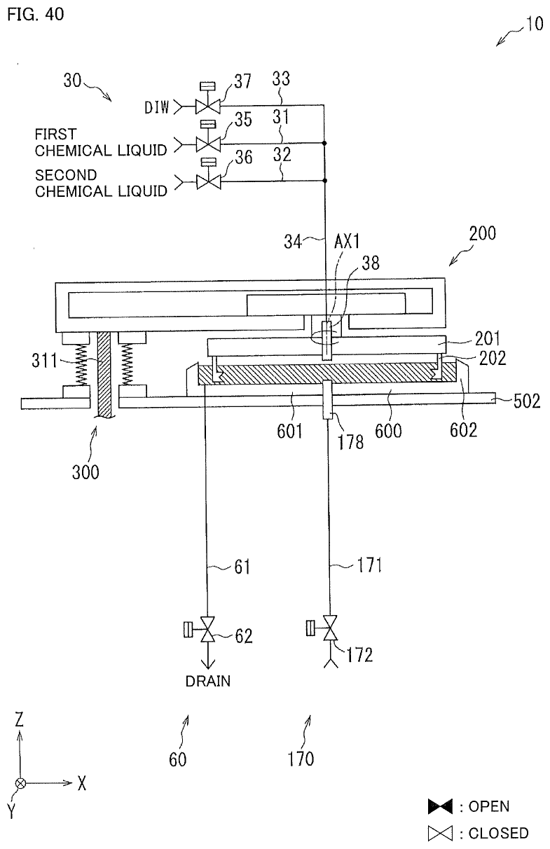

Next, a substrate processing apparatus 100 according to a fourth preferred embodiment of the present invention will be described with reference to FIGS. 39 and 40. FIG. 39 is a schematic plan view of a substrate processing unit in the substrate processing apparatus 100 according to the fourth preferred embodiment. FIG. 40 is a schematic view illustrating a structure around a cleaning bath 600 in the substrate processing apparatus 100 according to the fourth preferred embodiment. In the fourth preferred embodiment, unlike the above preferred embodiments, etc., an example in which the cleaning bath 600 is provided in the substrate processing unit 10 will be described.

As illustrated in FIGS. 39 and 40, the substrate processing unit 10 includes the cleaning bath 600. The cleaning bath 600 is a bath to clean the chuck pin 202 of the substrate holding portion 200. A rinse liquid (here, DIW) is stored in the cleaning bath 600.

The cleaning bath 600 stores the rinse liquid. The cleaning bath 600 has a container shape with an open upper surface and accommodates a portion of the chuck pin 202. The chuck pin 202 of the substrate holding portion 200 is immersed in the rinse liquid stored in the cleaning bath 600 in a state of not holding the substrate W. As a result, the chuck pin 202 is cleaned by the rinse liquid. In the present preferred embodiment, the substrate holding portion 200 rotates the spin base 201 about the rotational axis AX1 in a state in which the chuck pin 202 is immersed in the rinse liquid. Therefore, the cleaning effect on the chuck pin 202 can be improved.

The cleaning bath 600 has the same structure as that of the immersion bath 400. Specifically, the cleaning bath 600 has a bottom wall 601 and a side wall 602. Note that configurations of the bottom wall 601 and the side wall 602 are similar to the configurations of the bottom wall 401 and the side wall 402 of the immersion bath 400.

The substrate processing apparatus 100 includes an eighth supplying portion 170. The eighth supplying portion 170 is controlled by the controlling portion 102.

The eighth supplying portion 170 supplies the rinse liquid to the cleaning bath 600. The eighth supplying portion 170 supplies the rinse liquid from below the cleaning bath 600.

The eighth supplying portion 170 has the same structure as that of the third supplying portion 70. Specifically, the eighth supplying portion 170 includes a rinse liquid piping 171, an opening/closing valve 172, and a nozzle 178. The nozzle 178 is connected to the bottom wall 601 of the cleaning bath 600, and ejects the rinse liquid to the inside of the cleaning bath 600. Note that other configurations of the rinse liquid piping 171, the opening/closing valve 172, and the nozzle 178 are similar to the configurations of the rinse liquid piping 71, the opening/closing valve 72, and the nozzle 78 of the third supplying portion 70.

The substrate processing apparatus 100 also includes the second discharge portion 60. The second discharge portion 60 is connected to a lower portion of the cleaning bath 600. The second discharge portion 60 discharges the rinse liquid in the cleaning bath 600 out of the cleaning bath 600.

The substrate processing unit 10 has a cleaning position CW. The cleaning position CW is provided in the chamber 11. In the present preferred embodiment, a plurality of (here, three) processing positions Q and one cleaning position CW are provided in each chamber 11. The cleaning bath 600 is disposed at the cleaning position CW. The plurality of processing positions Q and the cleaning position CW are located on the circle C200 (not illustrated in FIG. 39). Therefore, the substrate holding portion 200 is turned about the turning axis L200 to be able to deliver the substrate W to a member (here, the immersion bath 400) at the processing position Q and accommodate a portion of the chuck pin 202 in the cleaning bath 600 at the cleaning position CW.

In the present preferred embodiment, the processing position Q1, the processing position Q2, the cleaning position CW, and the processing position Q3 are disposed in this order in the clockwise direction. The processing position Q1 is disposed to face the first opening 12a. The processing position Q3 is disposed to face the second opening 12b. That is, the processing position Q1 is disposed at a position closest to the first opening 12a.

The processing position Q3 is disposed at a position closest to the second opening 12b. In addition, the cleaning position CW and the cleaning bath 600 are disposed at a position farthest from a position (here, the processing position Q1 and the processing position Q3) at which the substrate W is delivered to and from the center robot CR. In the present preferred embodiment, the distance from the processing position Q3 to the cleaning position CW and the distance from the processing position Q2 to the processing position Q1 are the same.

In the present preferred embodiment, the substrate W is processed with the first chemical liquid at the processing position Q1. At the processing position Q2, the substrate W is processed with the second chemical liquid. At the processing position Q3, the substrate W is processed with the rinse liquid.

Next, a substrate processing method of the present preferred embodiment will be briefly described.

When the substrate W is carried into the processing position Q1, the substrate holding portion 200 holds the substrate W.

Then, the substrate holding portion 200 immerses the substrate W in the first chemical liquid at the processing position Q1 and releases the holding of the substrate W.

Thereafter, the substrate holding portion 200 immerses the chuck pin 202 in the rinse liquid at the cleaning position CW to clean the chuck pin 202.

After holding the substrate W at the processing position Q1, the substrate holding portion 200 then immerses the substrate W in the rinse liquid at the processing position Q3 and releases the holding of the substrate W.

Thereafter, the substrate holding portion 200 immerses the chuck pin 202 in the rinse liquid at the cleaning position CW to clean the chuck pin 202.

After holding the substrate W at the processing position Q3, the substrate holding portion 200 then immerses the substrate W in the second chemical liquid at the processing position Q2 and releases the holding of the substrate W.

Thereafter, the substrate holding portion 200 immerses the chuck pin 202 in the rinse liquid at the cleaning position CW to clean the chuck pin 202.

After holding the substrate W at the processing position Q2, the substrate holding portion 200 then immerses the substrate W in the rinse liquid at the processing position Q3 and releases the holding of the substrate W.

Thereafter, the substrate holding portion 200 immerses the chuck pin 202 in the rinse liquid at the cleaning position CW to clean the chuck pin 202.

After holding the substrate W at the processing position Q3, the substrate holding portion 200 then passes the substrate W to the center robot CR.

Thereafter, the substrate holding portion 200 immerses the chuck pin 202 in the rinse liquid at the cleaning position CW to clean the chuck pin 202.

As described above, the processing on the substrate W and the cleaning of the chuck pin 202 are performed.

Other substrate processing methods of the fourth preferred embodiment are similar to those of the above preferred embodiments, etc.

In the present preferred embodiment, as described above, the cleaning bath 600 for cleaning the chuck pin 202 holding the substrate w is provided. Therefore, the chemical liquid, etc., adhering to the chuck pin 202 can be removed. Therefore, for example, it is possible to suppress mixing of a plurality of chemical liquids in the immersion bath 400.

Other effects of the fourth preferred embodiment are similar to those of the above preferred embodiments, etc.

In the fourth preferred embodiment, an example in which one substrate W is processed has been described, but the present invention is not limited thereto. For example, the same number of substrates W as the number of processing positions Q (here, two) can be processed in parallel.

In the fourth preferred embodiment, an example in which the chuck pin 202 is cleaned every time the substrate W is immersed in chemical liquids (the first chemical liquid and the second chemical liquid) and a rinse liquid has been described, but the present invention is not limited thereto. For example, the chuck pin 202 may be cleaned only after the substrate W is immersed in a chemical liquid. For example, the chuck pin 202 may be cleaned only after the substrate W is immersed in a rinse liquid. In addition, for example, the chuck pin 202 may be cleaned every time the processing on one substrate W is completed.

### Fifth Preferred Embodiment

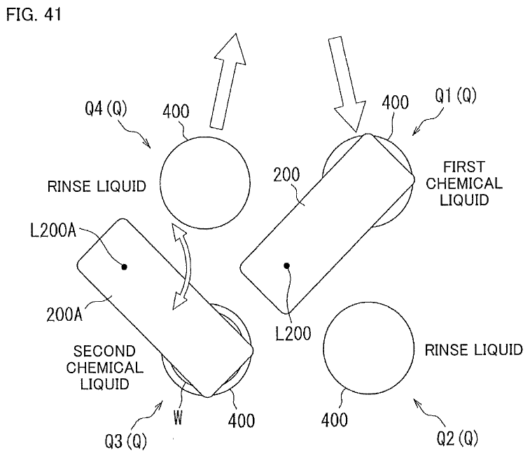

Next, a substrate processing apparatus 100 according to a fifth preferred embodiment of the present invention will be described with reference to FIG. 41. FIG. 41 is a schematic plan view of a substrate processing unit 10 in the substrate processing apparatus 100 according to the fifth preferred embodiment. In the fifth preferred embodiment, unlike the above preferred embodiments, etc., an example in which the substrate processing unit 10 is provided with a substrate holding portion 200A separately from the substrate holding portion 200 will be described. Note that in the following description, a portion of the second preferred embodiment will be modified, but the fifth preferred embodiment is also applicable to other preferred embodiments, etc.

As illustrated in FIG. 41, in the present preferred embodiment, there are a plurality of (here, four) processing positions Q in the chamber 11. The plurality of processing positions Q include a processing position Q1 to a processing position Q4. Disposition of the processing positions Q1 to 04 is similar to that in the second preferred embodiment.

In the present preferred embodiment, as in the second preferred embodiment, for example, the substrate W is processed by using the first chemical liquid at the processing position Q1. For example, at the processing position Q2, the substrate W is processed by using the rinse liquid. For example, at the processing position Q3, the substrate W is processed by using the second chemical liquid. At the processing position Q4, the substrate W is processed by using the rinse liquid.

Here, in the present preferred embodiment, the substrate processing unit 10 is provided with the substrate holding portion 200A separately from the substrate holding portion 200.

The substrate holding portion 200A can be turned about a turning axis L200A. The substrate holding portion 200A is turned about the turning axis L200A to be able to deliver, for example, the substrate W at the processing position Q3 and the processing position Q4. The turning axis L200A is located on the opposite side to the turning axis L200 with respect to a straight line (not illustrated) connecting the processing position Q3 and the processing position Q4. The processing position Q3 and the processing position Q4 are located on a circle centered on the turning axis L200A.

Note that a structure of the substrate holding portion 200A is similar to that of the substrate holding portion 200, and thus description thereof will be omitted. In addition, the substrate processing unit 10 is provided with a moving mechanism (not illustrated) that moves the substrate holding portion 200A. Since a structure of the moving mechanism that moves the substrate holding portion 200A is similar to that of the moving mechanism 300 that moves the substrate holding portion 200, the description thereof will be omitted.

Next, a substrate processing method of the present preferred embodiment will be briefly described. Note that the substrate holding portion 200 and the substrate holding portion 200A are retracted as appropriate to positions not interfering (contacting) with each other.

The substrate holding portion 200 receives the substrate W from the center robot CR at the processing position Q1 and holds the substrate W.

Then, the substrate holding portion 200 immerses the substrate W in the first chemical liquid at the processing position Q1.

Thereafter, the substrate holding portion 200 rinses the substrate W at the processing position Q2.

The substrate holding portion 200 then immerses the substrate W in the second chemical liquid at the processing position Q3 and releases the holding of the substrate W. The substrate holding portion 200 is retracted to, for example, the processing position Q1.

Thereafter, the substrate holding portion 200A holds the substrate W at the processing position Q3, and then rinses the substrate W at the processing position Q4.

The substrate holding portion 200A then passes the substrate W to the center robot CR at the processing position Q4.

As described above, the processing on the substrates W is thus completed.

Other substrate processing methods of the fifth preferred embodiment are similar to those of the second preferred embodiment, etc.

In the present preferred embodiment, as described above, the substrate W is passed to the center robot CR by the substrate holding portion 200A that is not immersed in the first chemical liquid. Therefore, the substrate W can be carried out in a state in which contamination of the substrate W is further suppressed.

Other effects of the fifth preferred embodiment are similar to those of the second preferred embodiment, etc.

In the fifth preferred embodiment, an example in which one substrate W is processed has been described, but the present invention is not limited thereto. A plurality of (for example, four) substrates W can be processed in parallel.

### Seventh Modification Example

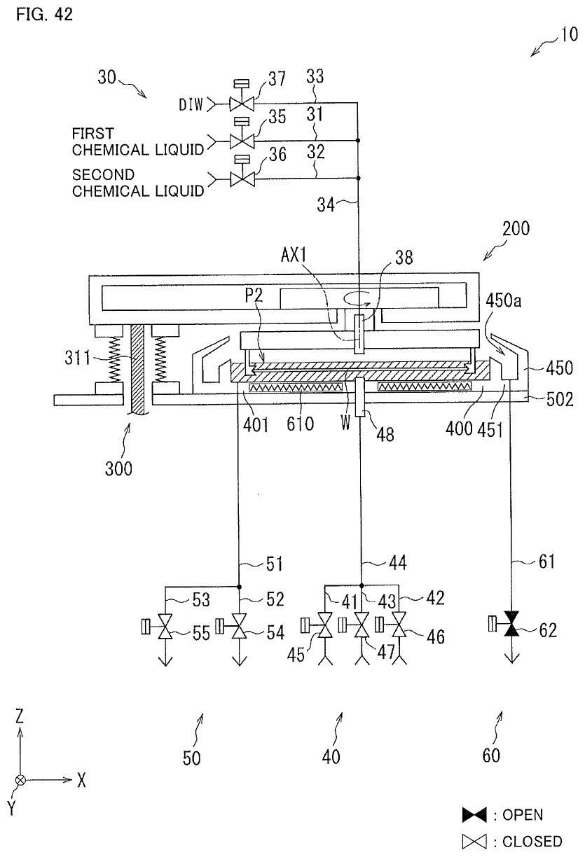

Next, a substrate processing apparatus 100 according to a seventh modification example of the present invention will be described with reference to FIG. 42. FIG. 42 is a schematic view illustrating the substrate processing apparatus 100 according to the seventh modification example. In the seventh modification example, unlike the above preferred embodiments, etc., an example of heating a processing liquid in the immersion bath 400 will be described. Note that in the following description, a portion of the first preferred embodiment will be modified, but the seventh modification example is also applicable to other preferred embodiments, etc.

As illustrated in FIG. 42, the substrate processing apparatus 100 includes a heater 610 that heats the processing liquid. The heater 610 heats the processing liquid in the immersion bath 400. Specifically, the heater 610 is disposed, for example, inside the bottom wall 401 of the immersion bath 400. For example, the heater 610 may be disposed to be in contact with the bottom surface of the bottom wall 401 of the immersion bath 400. For example, the heater 610 is disposed over one turn to surround the periphery of the nozzle 48. The heater 610 heats the processing liquid stored in the immersion bath 400 by heating the immersion bath 400.

The controlling portion 102 controls the heater 610. The controlling portion 102 controls the heater 610 to heat the processing liquid in the immersion bath 400 to a predetermined temperature. Specifically, the controlling portion 102 performs ON/OFF control of the heater 610 to maintain the processing liquid in the immersion bath 400 at a predetermined temperature. In this case, the substrate processing apparatus 100 includes, for example, a temperature sensor (not illustrated) that measures the temperature of the immersion bath 400 or the temperature of the processing liquid. Note that in the seventh modification example, the first supplying portion 30 and the second supplying portion 40 are preferably provided with a heater (not illustrated) that heats the processing liquid to a predetermined temperature.

In the seventh modification example, as described above, by providing the heater 610 that heats the processing liquid in the immersion bath 400, it is possible to suppress a decrease in the temperature of the processing liquid in the immersion bath 400. Therefore, for example, even in a case where the immersion processing is performed for a long time, it is possible to suppress a decrease in the temperature of the processing liquid. In addition, by heating the processing liquid in the immersion bath 400 to a predetermined temperature, for example, the substrate W can be processed with a processing liquid at a constant temperature.

Other configurations and other effects of the seventh modification example are similar to those of the above preferred embodiments, etc.

### Eighth Modification Example

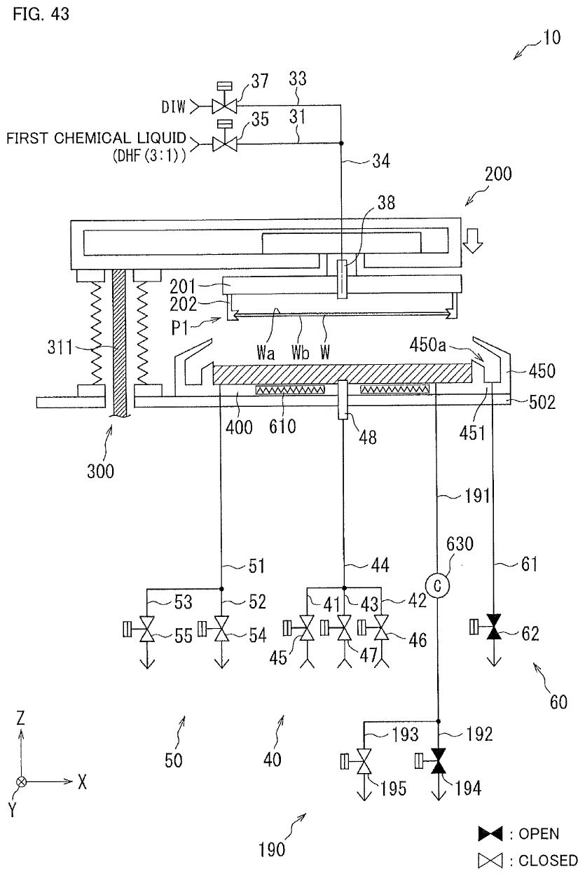

Next, a substrate processing apparatus 100 according to an eighth modification example of the present invention will be described with reference to FIG. 43. FIG. 43 is a schematic view illustrating the substrate processing apparatus 100 according to the eighth modification example. In the eighth modification example, unlike the above preferred embodiments, etc., an example in which a concentration sensor 630 that detects a concentration of a processing liquid stored in the immersion bath 400 is provided will be described.

In the eighth modification example, for example, the substrate W is immersed in a processing liquid stored in advance in the immersion bath 400. In the eighth modification example, the first supplying portion 30 includes the first chemical liquid piping 31, the rinse liquid piping 33, the common piping 34, the opening/closing valve 35, the opening/closing valve 37, and the nozzle 38. In the eighth modification example, the second chemical liquid piping 32 and the opening/closing valve 36 may be provided or need not be provided.

In the eighth modification example, the first chemical liquid is, for example, a dilute hydrofluoric acid (DHF). The dilute hydrofluoric acid is a mixed solution of a hydrofluoric acid and DIW at a mixing ratio of, for example, 3:1. The dilute hydrofluoric acid is stored in the immersion bath 400. In addition, the second chemical liquid is, for example, a hydrofluoric acid (HF). The concentration of the hydrofluoric acid is, for example, 49%.

In the eighth modification example, the substrate processing apparatus 100 includes the concentration sensor 630 and a fourth discharge portion 190. The fourth discharge portion 190 discharges the first chemical liquid stored in the immersion bath 400 out of the immersion bath 400. Note that the fourth discharge portion 190 allows the first chemical liquid to flow when the concentration of the first chemical liquid stored in the immersion bath 400 is detected.

The fourth discharge portion 190 includes a common piping 191, a drain piping 192, a return piping 193, an opening/closing valve 194, and an opening/closing valve 195. Since the common piping 191, the drain piping 192, the return piping 193, the opening/closing valve 194, and the opening/closing valve 195 are configured similarly to the common piping 51, the drain piping 52, the return piping 53, the opening/closing valve 54, and the opening/closing valve 55 of the first discharge portion 50, the description thereof will be omitted.

The concentration sensor 630 detects the concentration of the first chemical liquid stored in the immersion bath 400. Specifically, the concentration sensor 630 is provided in the common piping 191 of the fourth discharge portion 190. When the first chemical liquid in the immersion bath 400 passes through the common piping 191, the concentration sensor 630 detects the concentration of the first chemical liquid. The detection result from the concentration sensor 630 is transmitted to the controlling portion 102.

For example, the controlling portion 102 switches the opening/closing valve 194 from a closed state to an open state for a predetermined time when the substrate W is not processed. As a result, the first chemical liquid in the immersion bath 400 passes through the common piping 191, and the concentration sensor 630 detects the concentration of the first chemical liquid.

The controlling portion 102 determines whether the concentration of the first chemical liquid is within a predetermined range.

When the concentration of the first chemical liquid is lower than a predetermined range, the controlling portion 102 switches the opening/closing valve 46 from the closed state to the open state for a predetermined time. As a result, the second chemical liquid (hydrofluoric acid) is supplied into the immersion bath 400, and the concentration of the first chemical liquid in the immersion bath 400 increases. The time for bringing the opening/closing valve 46 into the open state is determined on the basis of the concentration of the first chemical liquid.

On the other hand, when the concentration of the first chemical liquid is higher than the predetermined range, the controlling portion 102 switches the opening/closing valve 47 from the closed state to the open state for a predetermined time. As a result, DIW is supplied into the immersion bath 400, and the concentration of the first chemical liquid in the immersion bath 400 decreases. Note that the time for bringing the opening/closing valve 47 into the open state is determined on the basis of the concentration of the first chemical liquid.

In the eighth modification example, in a case where the second chemical liquid or DIW is supplied into the immersion bath 400, the controlling portion 102 immerses the chuck pin 202 in the immersion bath 400 and rotates the chuck pin 202 about the rotational axis AX1. As a result, the processing liquid in the immersion bath 400 is stirred.

In the eighth modification example, it is possible to determine whether the concentration of the chemical liquid in the immersion bath 400 is lower or higher than a predetermined range by providing the concentration sensor 630 that detects the concentration of the chemical liquid in the immersion bath 400 as described above. Therefore, when the concentration of the chemical liquid in the immersion bath 400 decreases, the concentration of the chemical liquid can be increased. In addition, when the concentration of the chemical liquid in the immersion bath 400 increases, the concentration of the chemical liquid can be decreased. Therefore, the substrate W can be processed with a chemical liquid having a concentration in a predetermined range.

Other configurations and other effects of the eighth modification example are similar to those of the above preferred embodiments, etc.

### Ninth Modification Example

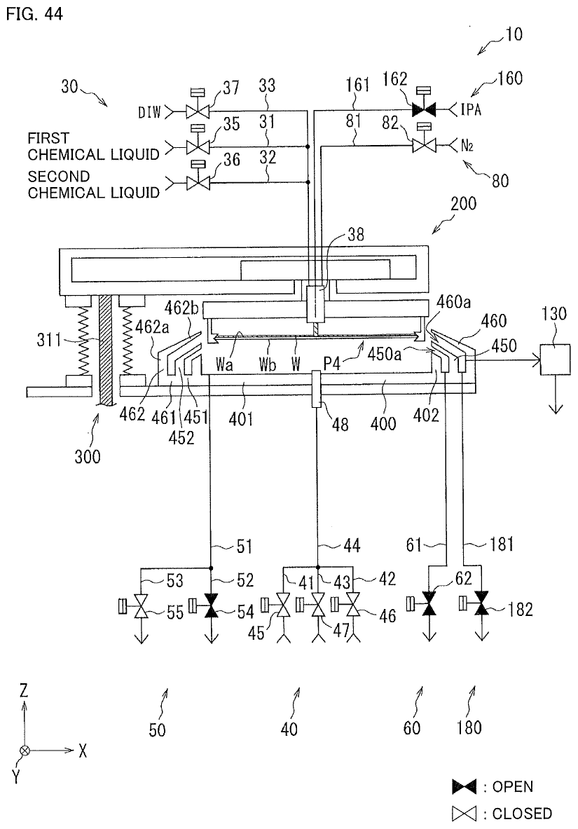

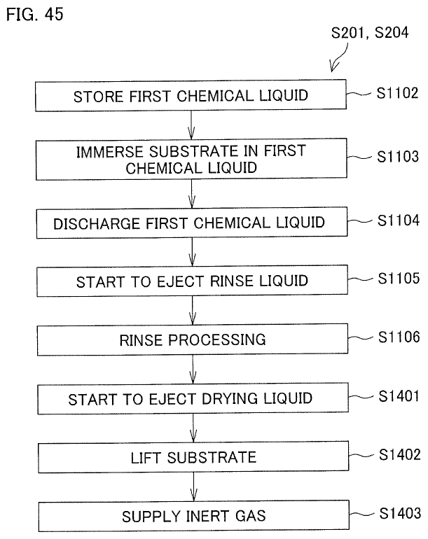

Next, a substrate processing apparatus 100 according to a ninth modification example of the present invention will be described with reference to FIGS. 44 and 45. FIG. 44 is a schematic view illustrating the substrate processing apparatus 100 according to the ninth modification example. In the ninth modification example, unlike the above preferred embodiments, etc., an example in which an outer cup 460 is provided will be described. Note that in the following description, a portion of the first modification example will be modified, but the ninth modification example is also applicable to other preferred embodiments, etc.

As illustrated in FIG. 44, the substrate processing apparatus 100 includes a ninth supplying portion 160 and the fifth supplying portion 80.

The ninth supplying portion 160 supplies a drying liquid to the substrate W. In the ninth modification example, the ninth supplying portion 160 supplies the drying liquid toward the upper surface Wa of the substrate W held by the substrate holding portion 200. The drying liquid is, for example, isopropyl alcohol (IPA).

The ninth supplying portion 160 includes a drying liquid piping 161 and an opening/closing valve 162. The drying liquid piping 161 is a tubular member through which the drying liquid flows. The drying liquid is supplied from a supply source to the drying liquid piping 161. The downstream end of the drying liquid piping 161 is connected to the nozzle 38. The drying liquid piping 161 allows the drying liquid to flow through the nozzle 38.

The opening/closing valve 162 is provided in the drying liquid piping 161 and opens and closes a flow path in the drying liquid piping 161. The opening/closing valve 162 adjusts the opening degree of the drying liquid piping 161 to adjust a flow rate of the drying liquid supplied to the drying liquid piping 161.

In the ninth modification example, a flow path through which the drying liquid passes is formed in the nozzle 38 in addition to a flow path through which the liquid from the first supplying portion 30 passes. The nozzle 38 ejects the drying liquid toward the upper surface Wa of the substrate W held by the substrate holding portion 200.

In the ninth modification example, the substrate processing apparatus 100 further includes the outer cup 460 outside the cup 450. The outer cup 460 is disposed around the periphery of the cup 450. In the ninth modification example, in the outer cup 460, the outer cup 460, the cup 450, and the immersion bath 400 are integrally formed. In other words, the outer cup 460, the cup 450, and the immersion bath 400 are a single member.

The outer cup 460 is disposed outside the side wall 452 of the cup 450 at a predetermined distance from the side wall 452. Specifically, the outer cup 460 has a bottom wall 461 and a side wall 462. The bottom wall 461 is connected to the bottom wall 451 or the side wall 452 of the cup 450. The side wall 462 is connected to a peripheral edge portion of the bottom wall 461. The side wall 462 has a lower wall portion 462a and an upper wall portion 462b. The lower wall portion 462a extends upward from the bottom wall 461. The upper wall portion 462b is inclined inward and upward from the upper end of the lower wall portion 462a. The bottom wall 461 and the side wall 462 of the outer cup 460 and the side wall 452 of the cup 450 define an inner space 460a of the outer cup 460.

For example, the outer cup 460 collects the drying liquid that is scattered around the periphery of the substrate W due to the rotation of the substrate W. A gas discharge portion 130 is connected to the outer cup 460, and a gas in the inner space 460a is discharged out of the chamber 11. The gas discharge portion 130 includes, for example, an exhaust piping and an exhaust fan disposed inside the exhaust piping.

The substrate processing apparatus 100 includes a third discharge portion 180. The third discharge portion 180 discharges the drying liquid in the outer cup 460 out of the outer cup 460. In the ninth modification example, the third discharge portion 180 discharges the drying liquid in the outer cup 460 out of the chamber 11. Specifically, the third discharge portion 180 includes a drain piping 181 and an opening/closing valve 182. Since the third discharge portion 180 is configured similarly to the second discharge portion 60, the description thereof will be omitted.

The controlling portion 102 controls the ninth supplying portion 160, the fifth supplying portion 80, and the third discharge portion 180.

In the ninth modification example, the support table 410 is not provided in the immersion bath 400. Note that the support table 410 may be provided in the immersion bath 400.

Other configurations of the ninth modification example are similar to those of the first preferred embodiment, etc.

Next, a substrate processing method at one processing position Q of the ninth modification example will be described with reference to FIGS. 44 and 45. FIG. 45 is a flowchart illustrating the substrate processing method at one processing position Q of the ninth modification example. Here, steps S202 to S204 in FIG. 10 will be described in detail. The substrate processing method at one processing position Q of the ninth modification example includes steps S1102 to S1106 and steps S1401 to S1403. Steps S1102 to S1104 correspond to step S202 described above. Steps S1105, S1106, and S1401 to S1403 correspond to step S204 described above. Note that since the substrate holding portion 200 does not release the holding of the substrate W in steps S1102 to S1104, step S203 is unnecessary between step S1104 and step S1105 in the ninth modification example.

As illustrated in FIG. 45, steps S1102 to S1106 are executed in the same manner as in the third preferred embodiment.

Next, in step S1401, the ejection of the rinse liquid is stopped, and the ejection of the drying liquid is started. Specifically, the controlling portion 102 switches the opening/closing valve 37 and the opening/closing valve 47 from the open state to the closed state, and switches the opening/closing valve 162 from the closed state to the open state. As a result, the rinse liquid is not supplied to the substrate W, and the drying liquid is supplied thereto.

Next, in step S1402, the substrate W is lifted. Specifically, as illustrated in FIG. 44, the controlling portion 102 moves the substrate holding portion 200 to a fourth height position P4 where the substrate W faces the side wall 462 of the outer cup 460 in the horizontal direction.

Next, in step S1403, a gas is supplied to the substrate W. Specifically, the controlling portion 102 switches the opening/closing valve 162 from the open state to the closed state, and switches the opening/closing valve 82 from the closed state to the open state. As a result, the drying liquid is not supplied to the substrate W, and the inert gas is supplied thereto. The substrate W is dried.

The controlling portion 102 switches the opening/closing valve 82 from the open state to the closed state when a predetermined time has elapsed from the start of the supply of the inert gas. Thereafter, the controlling portion 102 controls the substrate holding portion 200 to stop the rotation of the substrate W.

Other substrate processing methods of the ninth modification example are similar to those of the first modification example.

In the ninth modification example, as described above, the outer cup 460 is provided around the periphery of the cup 450, and when the substrate W is dried, the substrate W is disposed at the height position (fourth height position P4) of horizontally facing the side wall 462 of the outer cup 460. Therefore, the substrate W can be dried at the height position of the outer cup 460 where the first chemical liquid and/or the second chemical liquid do not flow. Therefore, for example, a mist of the first chemical liquid and/or the second chemical liquid can be prevented from adhering to the substrate W and adversely affecting the substrate W.

Other effects of the ninth modification example are similar to those of the above preferred embodiments, etc.

### Tenth Modification Example

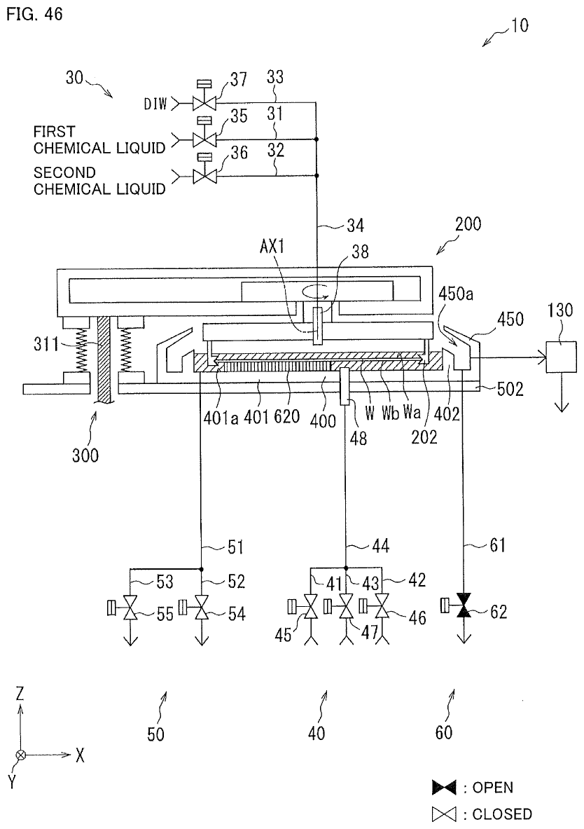

Next, a substrate processing apparatus 100 according to a tenth modification example of the present invention will be described with reference to FIG. 46. FIG. 46 is a the substrate processing schematic view illustrating apparatus 100 according to the tenth modification example. In the tenth modification example, unlike the above preferred embodiments, etc., an example in which a brush 620 is provided in the immersion bath 400 will be described. Note that in the following description, a portion of the first preferred embodiment will be modified, but the tenth modification example is also applicable to preferred embodiments, etc., other than the first preferred embodiment.

As illustrated in FIG. 46, the substrate processing apparatus 100 includes the brush 620. The brush 620 is disposed in the immersion bath 400. The brush 620 is provided to clean the lower surface Wb of the substrate W.

The brush 620 may include, for example, a porous material such as sponge. In addition, the brush 620 may contain, for example, a resin such as polyvinyl alcohol (PVA). In addition, the brush 620 may be configured by combining a plurality of members. In addition, the brush 620 may include a plurality of bristles.

The brush 620 is fixed to an upper surface 401a of the bottom wall 401 of the immersion bath 400. The brush 620 comes into contact with the lower surface Wb of the substrate W to clean the lower surface Wb of the substrate W in a state in which the substrate W is immersed in the processing liquid stored in the immersion bath 400.

The brush 620 comes into contact with the substrate W that is being rotated to clean the substrate W. The brush 620 is disposed, for example, on an extension line of the rotational axis AX1 of the substrate holding portion 200. In other words, the brush 620 is disposed in a region including the center of the upper surface of the bottom wall 401 of the immersion bath 400. The brush 620 is disposed radially outward from the central portion of the bottom wall 401. The brush 620 is formed in, for example, a substantially fan shape, a belt shape, or a linear shape in plan view. In the tenth modification example, the nozzle 48 is disposed at a position shifted from the center of the bottom wall 401 of the immersion bath 400. Note that the brush 620 may be, for example, formed in a circular shape in plan view.

In the tenth modification example, for example, in step S102, etc., of the processing flow, the lower surface Wb of the substrate W is cleaned by the brush 620. At that time, in the tenth modification example, in a state in which the substrate W is rotated by the substrate holding portion 200, the brush 620 comes into contact with the lower surface Wb of the substrate W to clean the lower surface Wb of the substrate W. Note that the cleaning of the substrate W by the brush 620 need not be performed during the processing using the chemical liquid, and may be performed during the rinse processing using the rinse liquid.

In the tenth modification example, as described above, the brush 620 is provided on the upper surface 401a of the bottom wall 401 of the immersion bath 400, and the brush 620 comes into contact with the lower surface Wb of the substrate W to clean the lower surface Wb of the substrate W in a state in which the substrate W is immersed in the processing liquid stored in the immersion bath 400. Therefore, since the brush 620 comes into contact with the substrate W in a state of being immersed in the processing liquid, the cleaning effect can be improved.

As described above, the substrate holding portion 200 rotates the substrate W while the lower surface Wb of the substrate W is in contact with the brush 620. Therefore, the cleaning effect can be further improved. In addition, by rotating the substrate W, substantially the entire lower surface Wb of the substrate W can be easily cleaned by the brush 620.

Other configurations, substrate processing methods, and effects of the tenth modification example are similar to those of the above preferred embodiments, etc.

### Eleventh Modification Example

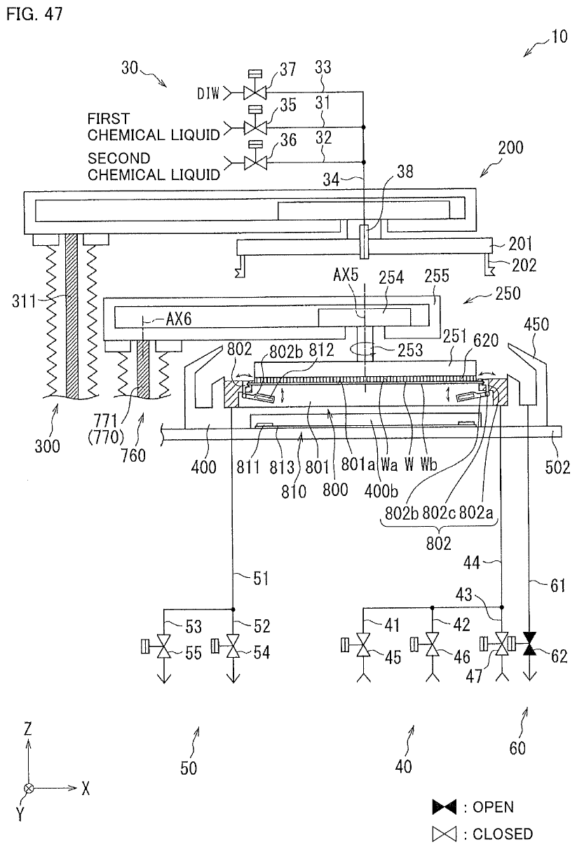

Next, a substrate processing apparatus 100 according to an eleventh modification example of the present invention will be described with reference to FIG. 47. FIG. 47 is a schematic view illustrating the substrate processing apparatus 100 according to the eleventh modification example. In the eleventh modification example, unlike the tenth modification example, an example in which the brush 620 is brought into contact with the upper surface Wa of the substrate W will be described.

As illustrated in FIG. 47, the substrate processing apparatus 100 includes the brush 620, a brush holding portion 250 that holds the brush 620, and a brush moving mechanism 760 that moves the brush holding portion 250. Note that the brush holding portion 250 and the brush moving mechanism 760 are controlled by the controlling portion 102.

In the eleventh modification example, the brush 620 is provided to clean the upper surface Wa of the substrate W. The brush 620 comes into contact with the substrate W while being rotated to clean the substrate W.

The brush holding portion 250 includes a spin base 251, a shaft 253, an electric motor 254, and a housing 255. The brush 620 is attached to a lower surface of the spin base 251. The brush 620 is disposed on an extension line of a rotational axis AX5 of the shaft 253. In other words, the brush 620 is disposed in a region including the center of the lower surface of the spin base 251. In the eleventh modification example, the brush 620 is attached to substantially the entire lower surface of the spin base 251.

Since the spin base 251, the shaft 253, the electric motor 254, and the housing 255 are configured similarly to the spin base 201, the shaft 203, the electric motor 204, and the housing 205 of the substrate holding portion 200, the description thereof will be omitted.

The brush moving mechanism 760 moves the brush holding portion 250 separately from the substrate holding portion 200. Specifically, the brush moving mechanism 760 moves the brush holding portion 250 in the vertical direction. That is, the brush moving mechanism 760 lifts and lowers the brush holding portion 250. In addition, the brush moving mechanism 760 rotates (turns) the brush holding portion 250 about a rotational axis AX6. The brush moving mechanism 760 includes, for example, a ball screw mechanism and an electric motor that applies a driving force to the ball screw mechanism.

Specifically, the brush moving mechanism 760 may be configured similarly to, for example, the moving mechanism 300. The brush moving mechanism 760 includes, for example, a lifting/lowering mechanism 770 that moves the brush holding portion 250 in the up-down direction, and a turning mechanism (not illustrated) that turns the brush holding portion 250. The lifting/lowering mechanism 770 includes, for example, a screw shaft 771, a nut, an electric motor, and a driving belt (none of which are illustrated). The screw shaft 771 and the nut (not illustrated) configure a ball screw mechanism. The screw shaft 771 extends in the vertical direction. An upper end of the screw shaft 771 is fixed to the housing 255 of the brush holding portion 250. Since the lifting/lowering mechanism 770 and the turning mechanism (not illustrated) of the brush moving mechanism 760 are configured similarly to the lifting/lowering mechanism 310 and the turning mechanism 320 of the moving mechanism 300, the description thereof will be omitted.

The substrate processing apparatus 100 includes a lower substrate holding portion 800. The lower substrate holding portion 800 is controlled by the controlling portion 102. The lower substrate holding portion 800 horizontally holds the substrate W. Specifically, the lower substrate holding portion 800 includes a base 801 and a chuck member 802.

The base 801 is disposed in the immersion bath 400. The base 801 has a substantially cylindrical shape. An upper surface 801a of the base 801 extends in the horizontal direction. The lower surface Wb of the substrate W comes into contact with the upper surface 801a of the base 801. The base 801 is formed at a height at which the upper surface Wa of the substrate W is lower than the liquid level of the processing liquid in a state in which the substrate W is disposed on the upper surface 801a.

The chuck member 802 is provided on the base 801. The chuck member 802 chucks the substrate W. For example, the chuck member 802 delivers the substrate W to and from the chuck pin 202 of the substrate holding portion 200. In the eleventh modification example, the lower surface Wb of the substrate W comes into contact with the upper surface 801a of the base 801 or is slightly separated from the upper surface 801a of the base 801 in a state in which the chuck member 802 chucks the substrate W.

The base 801 is provided with a plurality of chuck members 802. The chuck member 802 includes a chuck pin 802a protruding upward from the base 801, a driven portion 802b, and a coupling shaft 802c. The coupling shaft 802c couples the chuck pin 802a and the driven portion 802b. The coupling shaft 802c extends in the horizontal direction. The chuck pin 802a, the driven portion 802b, and the coupling shaft 802c may be configured with separate members, or may be configured with a single member.

The chuck pin 802a has a pin-shaped portion and a contact portion provided at the upper end of the pin-shaped portion and in contact with the circumferential edge of the substrate W. The driven portion 802b is moved up and down by a chuck driving mechanism 810 that will be described later. Specifically, the driven portion 802b swings about the coupling shaft 802c.

In addition, the driven portion 802b is fixed to the coupling shaft 802c, and the chuck pin 802a is fixed to the coupling shaft 802c. Therefore, the driven portion 802b and the chuck pin 802a swing integrally. Therefore, when the driven portion 802b swings about the coupling shaft 802c, the chuck pin 802a swings about the coupling shaft 802c. In the eleventh modification example, when the driven portion 802b swings up and down, the chuck pin 802a swings in the radial direction of the substrate W. When the chuck pin 802a swings radially inward of the substrate W, the chuck pin 802a comes into contact with the substrate W to hold the substrate W. On the other hand, when the chuck pin 802a swings radially outward of the substrate W, the chuck pin 802a is separated from the substrate W and releases the holding of the substrate W.

Although not illustrated, an internal space in which the driven portion 802b can swing is defined in the base 801.

The substrate processing apparatus 100 includes the chuck driving mechanism 810 that swings the plurality of chuck pins 802a. The chuck driving mechanism 810 is controlled by the controlling portion 102. The chuck driving mechanism 810 includes a driving magnet 811, a driven magnet 812, and a lifting/lowering plate 813.

The driving magnet 811 is disposed below the driven portion 802b of the chuck member 802. For example, the driving magnet 811 is disposed below the base 801 or between the base 801 and the support plate 502. In the eleventh modification example, an accommodation space 400b is defined in the lower portion of the immersion bath 400, and the driving magnet 811 is accommodated in the accommodation space 400b. The driving magnet 811 is disposed over one turn to surround a center line (not illustrated) of the base 801 in plan view.

The lifting/lowering plate 813 supports the driving magnet 811. Specifically, the lifting/lowering plate 813 is a plate having a circular shape. The driving magnet 811 is fixed onto the lifting/lowering plate 813 over one turn. The lifting/lowering plate 813 is accommodated in the accommodation space 400b. The lifting/lowering plate 813 is moved in the up-down direction with respect to the immersion bath 400 by a lifting/lowering mechanism (not illustrated).

The driven magnet 812 is fixed to the driven portion 802b. The driven magnet 812 is disposed at a position directly above the driving magnet 811. The driven magnet 812 is disposed to repel the driving magnet 811. Specifically, the driven magnet 812 and the driving magnet 811 are disposed such that the surfaces thereof facing each other have the same polarity.

When the lifting/lowering plate 813 and the driving magnet 811 are lifted, the driven magnet 812 swings upward. As a result, the chuck pins 802a swing radially outward of the substrate W. On the other hand, when the lifting/lowering plate 813 and the driving magnet 811 are lowered, the driven magnet 812 swings downward due to its own weight. As a result, the chuck pins 802a swing radially inward of the substrate W.

In the eleventh modification example, for example, the lower surface Wb of the substrate W is cleaned by the brush 620 in step S105, etc., of the processing flow. At that time, in the eleventh modification example, in a state in which the substrate W is held by the lower substrate holding portion 800, the brush 620 comes into contact with the upper surface Wa of the substrate W while being rotated to clean the upper surface Wa of the substrate W.

In the eleventh modification example, the upper surface Wa of the substrate W can be easily cleaned by providing the brush holding portion 250 and the lower substrate holding portion 800 as described above.

Other substrate processing methods and other effects of the eleventh modification example are similar to those of the tenth modification example.

### Twelfth Modification Example

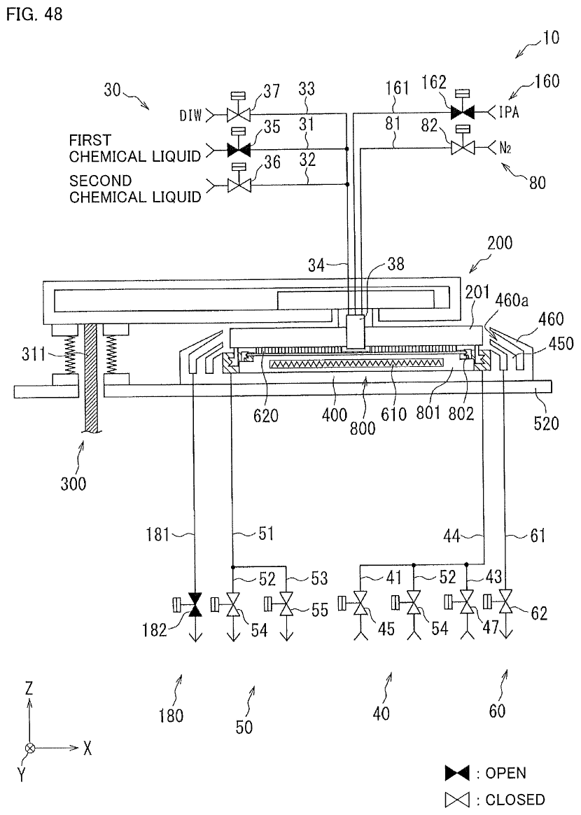

Next, a substrate processing apparatus 100 according to a twelfth modification example of the present invention will be described with reference to FIG. 48. FIG. 48 is a schematic view illustrating the substrate processing apparatus 100 according to the twelfth modification example. In the twelfth modification example, unlike the eleventh modification example, an example in which the brush 620 is attached to the substrate holding portion 200 will be described.

As illustrated in FIG. 48, the substrate processing apparatus 100 includes the brush 620. In the twelfth modification example, the brush 620 is fixed to the lower surface of the spin base 201 of the substrate holding portion 200. That is, the brush 620 is held by the substrate holding portion 200 and moved by the moving mechanism 300. Note that in the twelfth modification example, the brush holding portion 250 and the brush moving mechanism 760 are not provided.

The brush 620 is provided to clean the upper surface Wa of the substrate W as in the eleventh modification example. The brush 620 comes into contact with the substrate W while being rotated to clean the substrate W.

The brush 620 is attached to substantially the entire lower surface of the spin base 201. Note that in FIG. 48, the brush 620 is not provided at the central portion of the spin base 201 to avoid the nozzle 38, but for example, the brush 620 may be provided at the central portion of the spin base 201 by adjusting a shape or an inner diameter of the ejection port of the nozzle 38. Further, in a case where the brush 620 is not provided at the central portion of the spin base 201, the spin base 201 may be moved in the horizontal direction while rotating the brush 620.

In the twelfth modification example, similarly to the eleventh modification example, the lower substrate holding portion 800 and the heater 610 are provided. For example, the heater 610 is disposed inside the base 801 of the lower substrate holding portion 800.

In the twelfth modification example, similarly to the ninth modification example, the outer cup 460 and the third discharge portion 180 are provided.

In the twelfth modification example, as described above, the brush 620 is fixed to the spin base 201 of the substrate holding portion 200. Therefore, unlike the eleventh modification example, it is not necessary to provide the brush holding portion 250 that holds the brush 620 and the brush moving mechanism 760 that moves the brush holding portion 250. Therefore, the apparatus configuration can be simplified.

Other substrate processing methods and other effects of the twelfth modification example are similar to those of the above preferred embodiments, etc.

### Thirteenth Modification Example

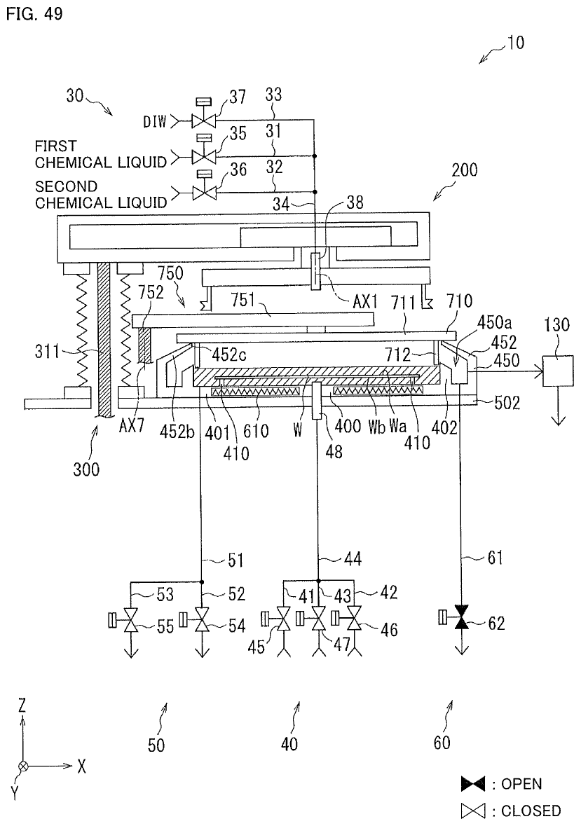

Next, a substrate processing apparatus 100 according to a thirteenth modification example of the present invention will be described with reference to FIG. 49. FIG. 49 is a schematic view illustrating the substrate processing apparatus 100 according to the thirteenth modification example. In the thirteenth modification example, unlike the above preferred embodiments, etc., an example in which the substrate processing apparatus 100 includes a lid 710 will be described. Note that in the following description, a portion of the seventh modification example will be modified, but the thirteenth modification example is also applicable to preferred embodiments, etc., other than the seventh modification example.

As illustrated in FIG. 49, the substrate processing apparatus 100 includes the lid 710 and a lid moving mechanism 750 that moves the lid 710. The lid 710 covers an inner circumferential edge 452c of the cup 450. Specifically, the cup 450 has the inner circumferential edge 452c defining an opening through which the substrate W can pass. The inner circumferential edge 452c is formed by the upper end of the upper wall portion 452b of the side wall 452.

The lid 710 includes, for example, a plate-shaped plate 711 and a circular cylindrical portion 712 having a circular cylindrical shape. The plate 711 has, for example, a circular shape. The circular cylindrical portion 712 protrudes downward from the lower surface of the plate 711.

The plate 711 has a diameter larger than the diameter of the inner circumferential edge 452c of the cup 450. The plate 711 covers the upper side of the inner circumferential edge 452c in a state of being disposed on the cup 450. In addition, the circular cylindrical portion 712 has a diameter (outer diameter) smaller than the diameter of the inner circumferential edge 452c of the cup 450. The circular cylindrical portion 712 covers the inside of the inner circumferential edge 452c in a state of being inserted into the inside (radially inside) of the cup 450. In the thirteenth modification example, the circular cylindrical portion 712 is formed from the upper end of the side wall 452 of the cup 450 to the upper end of the side wall 402 of the immersion bath 400 in the up-down direction.

The lid moving mechanism 750 moves the lid 710 separately from the substrate holding portion 200. Specifically, the lid moving mechanism 750 moves the lid 710 in the vertical direction. That is, the lid moving mechanism 750 lifts and lowers the lid 710. In addition, the lid moving mechanism 750 rotates (turns) the lid 710 about a rotational axis AX7. The lid moving mechanism 750 includes, for example, a ball screw mechanism and an electric motor that applies a driving force to the ball screw mechanism.

Specifically, the lid moving mechanism 750 may be, for example, configured similarly to the moving mechanism 300. The lid moving mechanism 750 includes, for example, a supporting portion 751 that supports the lid 710 and a screw shaft 752. In addition, the lid moving mechanism 750 includes a nut, an electric motor, a driving belt, and a shaft cover (none of which are illustrated). Since the screw shaft 752, the nut, the electric motor, the driving belt, and the shaft cover of the lid moving mechanism 750 are configured similarly to the moving mechanism 300, the description thereof will be omitted. In addition, the lid moving mechanism 750 includes a turning mechanism (not illustrated) that turns the screw shaft 752 and the driving motor about the rotational axis AX7 which is a central axis of the screw shaft 752. As a result, the lid 710 can be retracted from the position immediately above the substrate W.

The gas discharge portion 130 is connected to the cup 450, and the gas in the inner space 450a is discharged out of the chamber 11.

In the thirteenth modification example, for example, in step S102, etc., of the processing flow, the controlling portion 102 controls the substrate holding portion 200 to place the substrate W on the plurality of support tables 410. As a result, the substrate W is immersed in the processing liquid stored in the immersion bath 400. In addition, the controlling portion 102 controls the substrate holding portion 200 to retract the substrate holding portion 200 upward from the cup 450.

The controlling portion 102 then controls the lid moving mechanism 750 to place the lid 710 on the cup 450.

In the thirteenth modification example, as described above, the substrate processing apparatus 100 includes the lid 710 that covers the inner circumferential edge 452c of the cup 450. Therefore, it is possible to suppress the gas above the immersion bath 400 from being drawn into the inner space 450a of the cup 450. Therefore, it is possible to suppress a decrease in the temperature of the processing liquid in the immersion bath 400 due to the airflow drawn into the inner space 450a.

As described above, the lid moving mechanism 750 that moves the lid 710 separately from the substrate holding portion 200 is provided. Therefore, the lid 710 can be easily moved to cover the inner circumferential edge 452c of the immersion bath 400.

Other configurations, substrate processing methods, and effects of the thirteenth modification example are similar to those of the above preferred embodiments, etc.

### Fourteenth Modification Example

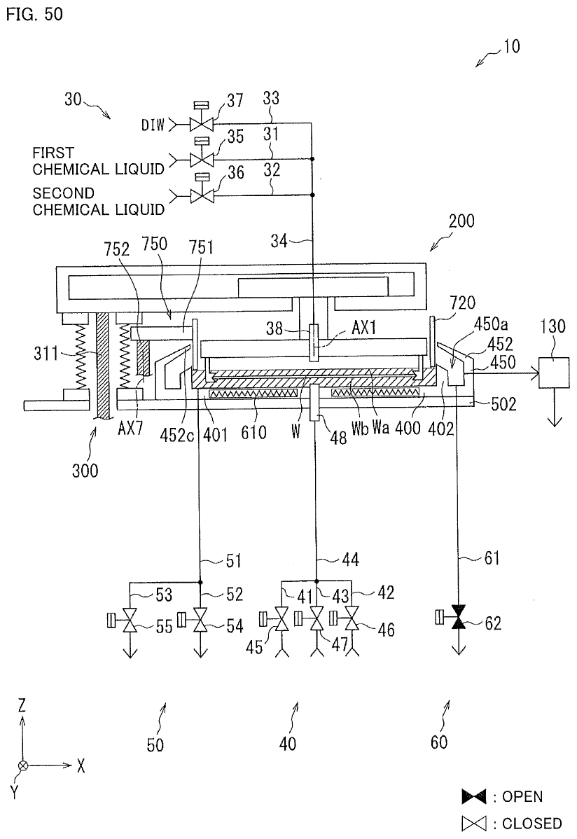

Next, a substrate processing apparatus 100 according to a fourteenth modification example of the present invention will be described with reference to FIG. 50. FIG. 50 is a schematic view illustrating the substrate processing apparatus 100 according to the fourteenth modification example. In the fourteenth modification example, unlike the thirteenth modification example, an example will be described in which the temperature decrease of the processing liquid is suppressed by a lid 720 in a state in which the substrate W is held by the substrate holding portion 200.

As illustrated in FIG. 50, the substrate processing apparatus 100 includes the lid 720 and the lid moving mechanism 750 that moves the lid 720. The lid 720 covers the inner circumferential edge 452c of the cup 450. Specifically, the lid 720 has a circular cylindrical shape. The lid 720 extends in the up-down direction.

The lid 720 has a diameter (outer diameter) smaller than the inner circumferential edge 452c of the cup 450. The lid 720 covers the inside of the inner circumferential edge 452c in a state of being inserted into the inside (radially inside) of the cup 450. The lid 720 is formed from the upper end of the side wall 452 of the cup 450 to the upper end of the side wall 402 of the immersion bath 400 in the up-down direction. That is, the lid 720 covers the inlet of the inner space 450a.

In addition, the lid 720 has an inner diameter larger than the diameter of the spin base 201. Thus, the spin base 201 can be disposed inside the lid 720. Note that other configurations of the lid 720 are similar to those of the circular cylindrical portion 712 of the lid 710.

The lid moving mechanism 750 moves the lid 720. Specifically, the lid moving mechanism 750 moves the lid 720 in the vertical direction. That is, the lid moving mechanism 750 lifts and lowers the lid 720. In addition, the lid moving mechanism 750 rotates (turns) the lid 720 about the rotational axis AX7. The supporting portion 751 of the lid moving mechanism 750 is fixed to, for example, the outer peripheral surface of the lid 720. Other configurations of the lid moving mechanism 750 are similar to those of the thirteenth modification example.

Note that in the fourteenth modification example, unlike the thirteenth modification example, the support table 410 is not provided in the immersion bath 400.

In the fourteenth modification example, for example, prior to step S102, etc., of the processing flow, the controlling portion 102 controls the lid moving mechanism 750 to insert the lid 720 into the cup 450. As a result, in step S102, etc., the lid 720 covers the inside of the inner circumferential edge 452c of the cup 450, and the substrate W is immersed in the processing liquid in a state of being held by the substrate holding portion 200.

Other configurations, substrate processing methods, and effects of the fourteenth modification example are similar to those of the thirteenth modification example. (Fifteenth Modification Example)

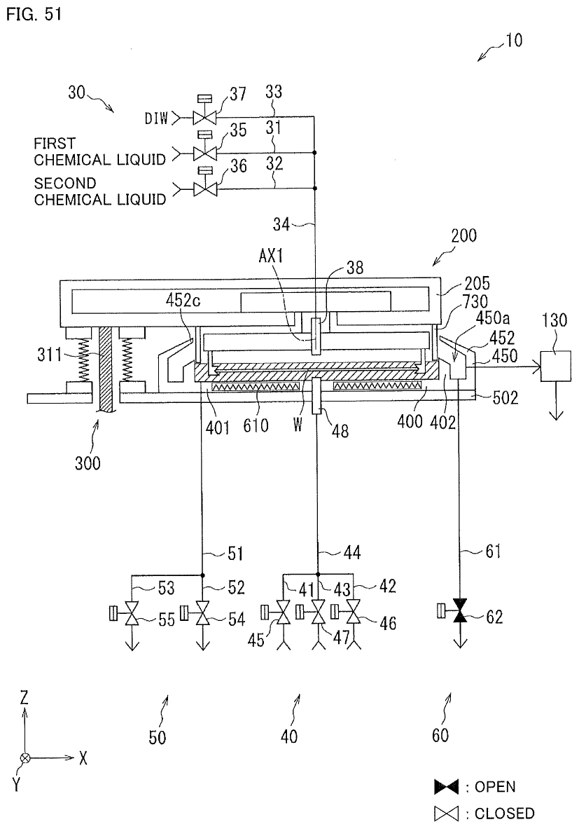

Next, a substrate processing apparatus 100 according to a fifteenth modification example of the present invention will be described with reference to FIG. 51. FIG. 51 is a schematic view illustrating the substrate processing apparatus 100 according to the fifteenth modification example. In the fifteenth modification example, unlike the thirteenth modification example and the fourteenth modification example, an example in which the lid moving mechanism 750 is not provided will be described.

As illustrated in FIG. 51, the substrate processing apparatus 100 includes a lid 730. In the fifteenth modification example, unlike the fourteenth modification example, the lid moving mechanism 750 is not provided. The lid 730 covers the inner circumferential edge 452c of the cup 450. The upper end of the lid 730 is fixed to the housing 205 of the substrate holding portion 200. In the fifteenth modification example, the lid 730 surrounds the periphery of the spin base 201. Other configurations of the lid 730 are similar to those of the lid 720 of the fourteenth modification example.

In the fifteenth modification example, for example, in step S102, etc., of the processing flow, the lid 730 covers the inside of the inner circumferential edge 452c of the cup 450, and the substrate W is immersed in the processing liquid in a state of being held by the substrate holding portion 200.

In the fifteenth modification example, as described above, the lid 730 is provided in the substrate holding portion 200. Therefore, it is not necessary to provide the lid moving mechanism 750 for moving the lid 730.

Other configurations, substrate processing methods, and effects of the fifteenth modification example are similar to those of the fourteenth modification example.

### Sixteenth Modification Example

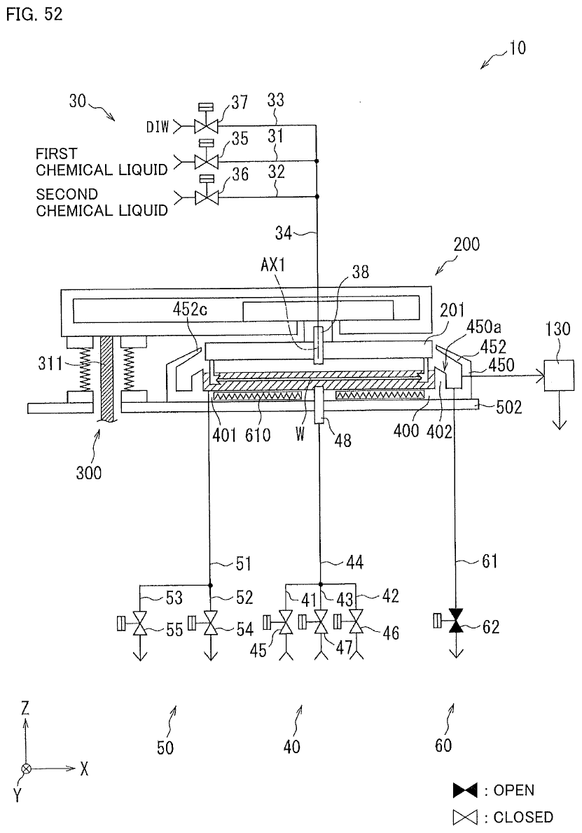

Next, a substrate processing apparatus 100 according to a sixteenth modification example of the present invention will be described with reference to FIG. 52. FIG. 52 is a schematic view illustrating the substrate processing apparatus 100 according to the sixteenth modification example. In the sixteenth modification example, unlike the thirteenth modification example to the fifteenth modification example, an example in which the spin base 201 also serves as a lid will be described. Note that in the following description, a portion of the fifteenth modification example will be modified, but the sixteenth modification example is also applicable to preferred embodiments, etc., other than the fifteenth modification example.

As illustrated in FIG. 52, the spin base 201 of the substrate holding portion 200 also serves as a lid. Note that in the sixteenth modification example, unlike the thirteenth modification example to the fifteenth modification example, the substrate processing apparatus 100 does not include the lids 710 to 730 and the lid moving mechanism 750. In the sixteenth modification example, the spin base 201 covers the inner circumferential edge 452c of the cup 450. In the sixteenth modification example, the spin base 201 has a diameter (outer diameter) slightly smaller than the inner diameter of the inner circumferential edge 452c of the cup 450. Therefore, the gap between the outer peripheral surface of the spin base 201 and the inner circumferential edge 452c of the cup 450 in the sixteenth modification example is smaller than the gap between the outer peripheral surface of the spin base 201 and the inner circumferential edge 452c of the cup 450 in the seventh modification example.

In the sixteenth modification example, since the spin base 201 also serves as a lid as described above, it is possible to suppress an increase in the number of components.

Other configurations, substrate processing methods, and effects of the sixteenth modification example are similar to those of the fifteenth modification example.

### Seventeenth Modification Example

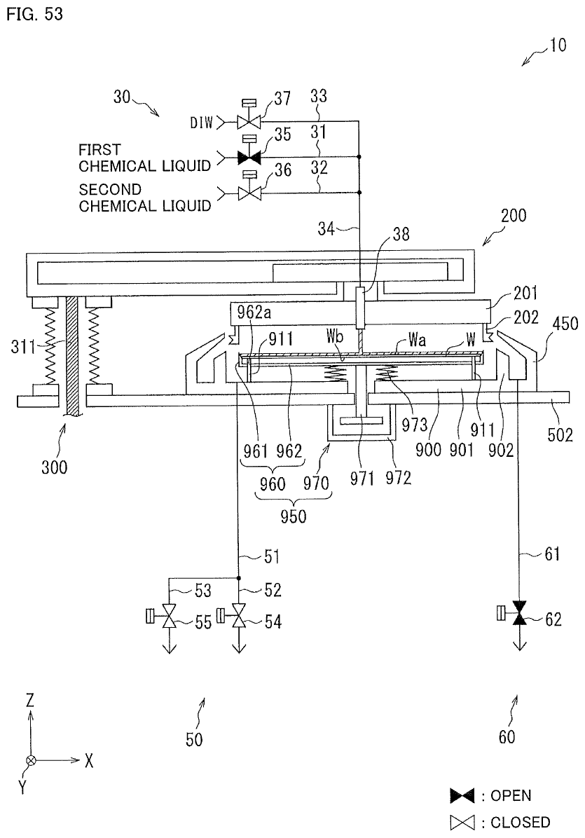

Next, a substrate processing apparatus 100 according to a seventeenth modification example of the present invention will be described with reference to FIG. 53. FIG. 53 is a schematic plan view of a substrate processing unit in the substrate processing apparatus 100 according to the seventeenth modification example. In the seventeenth modification example, unlike the above preferred embodiments, etc., an example in which a blocking member 960 that blocks a processing liquid on the upper surface Wa of the substrate W is provided will be described.

As illustrated in FIG. 53, the substrate processing unit 10 includes a processing bath 900. The processing bath 900 suppresses scattering of a processing liquid around the surroundings. Unlike the immersion bath 400, the processing bath 900 does not store a processing liquid.

The processing bath 900 has the same structure as that of the immersion bath 400. Specifically, the processing bath 900 has a bottom wall 901 and a side wall 902. Note that configurations of the bottom wall 901 and the side wall 902 are similar to the configurations of the bottom wall 401 and the side wall 402 of the immersion bath 400.

The processing bath 900 has a support column 911. The support column 911 supports the substrate W. Specifically, the support column 911 supports the lower surface Wb of the substrate W passed from the substrate holding portion 200. The support column 911 protrudes further upward than the upper surface of the bottom wall 901. The support column 911 is not particularly limited, but for example, has a cylindrical shape. A plurality of support columns 911 are provided on the bottom wall 901. The plurality of support columns 911 are disposed, for example, at the peripheral edge portion of the bottom wall 901. Note that the support column 911 and the bottom wall 901 may be integrally formed.

In addition, the substrate processing unit 10 includes a blocking mechanism 950. The blocking mechanism 950 includes the blocking member 960 and a lifting/lowering mechanism 970 that lifts and lowers the blocking member 960.

The blocking member 960 blocks the processing liquid on the upper surface Wa of the substrate W. In other words, the blocking member 960 suppresses overflow of the processing liquid from the upper surface Wa of the substrate W. Specifically, the blocking member 960 includes a ring-shaped contact portion 961 and a support plate 962 that supports the contact portion 961.

The contact portion 961 comes into contact with the circumferential edge of the substrate W over one turn. The contact portion 961 protrudes upward from the support plate 962. In the seventeenth modification example, the contact portion 961 has a circular cylindrical shape. In addition, the upper surface of the contact portion 961 is an inclined surface extending upward toward the radial outside. A lower portion of the upper surface of the contact portion 961 comes into contact with the substrate W to hold the substrate W. At least an upper portion of the upper surface of the contact portion 961 blocks the processing liquid.

The support plate 962 is, for example, a plate member having a circular shape. The support plate 962 is disposed horizontally. The support plate 962 horizontally supports the contact portion 961. In addition, the support plate 962 has a through hole 962a through which the support column 911 is inserted. The support plate 962 is movable up and down along the support column 911.

The lifting/lowering mechanism 970 is not particularly limited, but includes, for example, a shaft 971 and an actuator (not illustrated) that moves the shaft 971 in the up-down direction. In addition, the lifting/lowering mechanism 970 includes a case 972 that accommodates an actuator, etc., and a bellows portion 973 that covers the periphery of the shaft 971 and is capable of expanding and contracting in the vertical direction. The upper end of the shaft 971 is fixed to the lower surface of the support plate 962 of the blocking member 960. Note that the lifting/lowering mechanism 970 may be configured similarly to, for example, the lifting/lowering mechanism 310 of the moving mechanism 300.

Next, a substrate processing method using the blocking member 960 of the seventeenth modification example will be briefly described.

The substrate holding portion 200 places the held substrate W on the support column 911 and releases the holding of the substrate W. The substrate holding portion 200 is then retracted upward. At that time, the blocking member 960 is in a lowered state.

The lifting/lowering mechanism 970 lifts the blocking member 960. As a result, the contact portion 961 of the blocking member 960 comes into contact with the circumferential edge of the substrate W over one turn.

Thereafter, the first supplying portion 30 ejects the chemical liquid onto the upper surface Wa of the substrate W for a predetermined time, and then stops the ejection of the chemical liquid. As a result, the upper surface Wa of the substrate W is covered with the chemical liquid.

When a predetermined time elapses after the chemical liquid is ejected to the upper surface Wa of the substrate W, the lifting/lowering mechanism 970 lowers the blocking member 960. As a result, the substrate W is passed from the blocking member 960 to the support column 911.

Thereafter, the substrate holding portion 200 holds the substrate W and transfers the substrate W to another processing position Q.

As described above, the substrate W is processed by using the blocking member 960.

Other substrate processing methods of the seventeenth modification example are similar to those of the above preferred embodiments, etc.

In the seventeenth modification example, as described above, by providing the blocking member 960, it is possible to suppress the chemical liquid on the upper surface Wa of the substrate W from falling from the substrate W.

Other effects of the seventeenth modification example are similar to those of the above preferred embodiments, etc.

### Eighteenth Modification Example

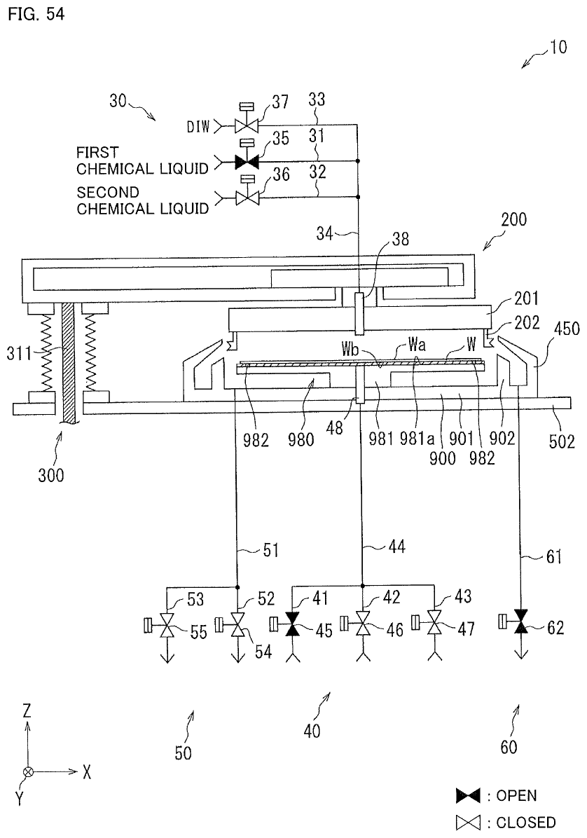

Next, a substrate processing apparatus 100 according to an eighteenth modification example of the present invention will be described with reference to FIG. 54. FIG. 54 is a schematic plan view of a substrate processing unit in the substrate processing apparatus 100 according to the eighteenth modification example. In the eighteenth modification example, unlike the seventeenth modification example, an example in which the lower surface Wb of the substrate W is processed will be described.

As illustrated in FIG. 54, the substrate processing unit 10 includes the processing bath 900 as in the seventeenth modification example. Note that, unlike the seventeenth modification example, the processing bath 900 does not include the support column 911.

The substrate processing unit 10 includes a substrate processing table 980 that supports the substrate W. The substrate processing table 980 includes a table 981 that supports the substrate W and a projection portion 982.

The table 981 has, for example, a circular shape in plan view. The table 981 has an upper surface 981a. The upper surface 981a has, for example, a diameter slightly larger than that of the substrate W. The table 981 is not particularly limited, but is formed in a substantially T-shape in side view in the eighteenth modification example. The projection portion 982 is provided on the upper surface 981a of the table 981. The projection portion 982 protrudes upward from the upper surface 981a of the table 981. The projection portion 982 supports the substrate W. Specifically, the projection portion 982 supports the lower surface Wb of the substrate W passed from the substrate holding portion 200. The projection portion 982 is not particularly limited, but has, for example, a cylindrical shape. In addition, a plurality of projection portions 982 are provided on the upper surface 981a. The plurality of projection portions 982 are disposed, for example, at a peripheral edge portion of the bottom wall 901. Note that the projection portions 982 and the table 981 may be integrally formed.

Here, the projection portion 982 is formed at a predetermined height. In the eighteenth modification example, the processing liquid is held between the upper surface 981a of the table 981 and the lower surface Wb of the substrate W. The height of the projection portion 982 is, for example, equal to or less than the thickness of the processing liquid when the processing liquid is held by surface tension. Specifically, the height of the projection portion 982 is several hundreds μm or more and several mm or less.

In the eighteenth modification example, the nozzle 48 of the second supplying portion 40 penetrates the table 981 in the up-down direction. Therefore, the nozzle 48 can eject the processing liquid to the upper surface 981a of the table 981.

Next, a substrate processing method using the substrate processing table 980 of the eighteenth modification example will be briefly described.

The substrate holding portion 200 places the held substrate W on the substrate processing table 980. At that time, the substrate W may be placed on the substrate processing table 980 in a state in which there is a chemical liquid on the substrate processing table 980. In addition, the substrate W may be disposed on the substrate processing table 980 in a state in which there is no chemical liquid on the substrate processing table 980, and the chemical liquid may be supplied between the lower surface Wb of the substrate W and the upper surface 981a of the substrate processing table 980 while the substrate holding portion 200 holds the substrate W.

The substrate holding portion 200 then releases the holding of the substrate W. As a result, the substrate W is held by the surface tension of the chemical liquid or the projection portion 982. At that time, the lower surface Wb of the substrate W is covered with the chemical liquid.

When a predetermined time elapses after the chemical liquid comes into contact with the lower surface Wb of the substrate W, the substrate holding portion 200 holds the substrate W.

Thereafter, the substrate holding portion 200 holds the substrate W and transfers the substrate W to another processing position Q. At that time, the chemical liquid may be ejected from the nozzle 48. With this configuration, the substrate W can be easily moved upward from the substrate processing table 980.

As described above, the substrate W is processed by using the substrate processing table 980.

Other substrate processing methods of the eighteenth modification example are similar to those of the above preferred embodiments, etc.

In the eighteenth modification example, by providing the substrate processing table 980 having the projection portions 982 as described above, for example, only the lower surface Wb of the substrate W can be processed with a chemical liquid.

Other effects of the eighteenth modification example are similar to those of the seventeenth modification example, etc.

The preferred embodiments of the present invention have been described above with reference to the drawings. However, the present invention is not limited to the above preferred embodiments, and can be implemented in various aspects without departing from the concept thereof. In addition, various inventions can be formed by appropriately combining a plurality of constituents disclosed in the above preferred embodiments. For example, some constituents may be deleted from all the constituents described in the preferred embodiments. Further, constituents across different preferred embodiments may be combined as appropriate. The drawings mainly illustrate the respective constituents schematically for ease of understanding and there are cases where thicknesses, lengths, numbers, intervals, etc., of the respective constituents illustrated differ from actual ones due to convenience of drawing preparation. The materials, the shapes, the dimensions, etc., of the respective constituents described in the above preferred embodiments are only examples, are not restricted in particular, and can be changed variously within a scope of practically not deviating from the effects of the present invention.

For example, in the above-described preferred embodiments, etc., an example in which the lifting/lowering mechanism 310 moves the substrate holding portion 200 has been described, but the present invention is not limited thereto. For example, the lifting/lowering mechanism 310 may move the immersion bath 400. That is, the lifting/lowering mechanism 310 may relatively move the substrate holding portion 200 and the immersion bath 400. At that time, the lifting/lowering mechanism 310 may move one of the substrate holding portion 200 and the immersion bath 400, or may move both of the substrate holding portion 200 and the immersion bath 400.

In addition, for example, in the third preferred embodiment, an example in which the substrate W is rotated when the processing liquid is ejected onto the substrate W has been described, but the present invention is not limited thereto. When the processing liquid is ejected onto the substrate W, the substrate W need not be rotated.

In addition, for example, in the fourth modification example, an example in which the delivery position R and the delivery table 150 are provided has been described, but the present invention is not limited thereto. For example, the delivery position R and the delivery table 150 may be provided in preferred embodiments, etc., other than the fourth modification example.

In addition, for example, in the first preferred embodiment, an example in which a drying liquid and a gas are not ejected to the substrate W when the substrate W is dried has been described, but the present invention is not limited thereto. In the first preferred embodiment, etc., a drying liquid and/or a gas may be ejected when the substrate W is dried.

In addition, in the above preferred embodiments, etc., an example in which the first chemical liquid, the second chemical liquid, and the rinse liquid are ejected from the same nozzle (for example, the nozzle 38 and the nozzle 48) has been described, but the present invention is not limited thereto. For example, a nozzle that ejects the first chemical liquid, a nozzle that ejects the second chemical liquid, and a nozzle that ejects the rinse liquid may be separately provided.

In addition, in the above preferred embodiments, etc., an example in which the chuck pin 202 is driven by the chuck driving mechanism 210 including the driving magnet 211, the driven magnet 212, and the lifting/lowering plate 213 has been described, but the present invention is not limited thereto. A chuck driving mechanism driving the chuck pin 202 is not particularly limited. For example, a motor (chuck driving mechanism) that rotates the chuck pin 202 may be provided on the spin base 201.

In addition, for example, in the thirteenth modification example to the sixteenth modification example, an example in which the temperature decrease of the processing liquid is suppressed by the lid 710, the lid 720, the lid 730, or the spin base 201 has been described, but the present invention is not limited thereto. For example, a flow path of an exhaust piping of the gas discharge portion 130 may be closed, or the driving of an exhaust fan may be stopped. Also in this case, since it is possible to suppress a gas from being drawn into the inner space 450a of the cup 450, it is possible to suppress a decrease in the temperature of the processing liquid in the immersion bath 400.

In addition, for example, in the third preferred embodiment, an example in which the processing liquid is stored in the immersion bath 400 by ejecting the processing liquid toward the substrate W has been described, but the present invention is not limited thereto. For example, in other preferred embodiments and modification examples, the processing liquid may be stored in the immersion bath 400 by ejecting the processing liquid toward the substrate W. In addition, in the above preferred embodiments, etc., an example in which two or four processing positions Q are provided has been described, but the present invention is not limited thereto. For example, three or five or more processing positions may be provided.

In addition, for example, in the second preferred embodiment, an example in which the plurality of processing positions Q are disposed around the turning axis L200 over about one turn and the substrate holding portion 200 turns one or more turns has been described, but the present invention is not limited thereto. For example, the plurality of processing positions Q may be disposed over less than one turn (for example, a half turn) around the turning axis L200, and/or the substrate holding portion 200 may turn less than one turn.

In addition, for example, in the fourth preferred embodiment, an example in which the chuck pin 202 is immersed in the rinse liquid stored in the cleaning bath 600 to clean the chuck pin 202 has been described, but the present invention is not limited thereto. For example, the chuck pin 202 may be cleaned by spraying a rinse liquid to the chuck pin 202 by using a spray nozzle.

In addition, for example, in the eleventh modification example and the twelfth modification example, an example in which the chuck member 802 that holds the substrate W by swinging about the coupling shaft 802c extending in the horizontal direction is provided has been described, but the present invention is not limited thereto. For example, similarly to the chuck pin 202 of the substrate holding portion 200, the chuck member 802 may be arranged to hold the substrate W by rotating about an axis extending in the up-down direction.

In addition, in the above-described preferred embodiments, etc., an example in which the substrate W is processed in a state in which the substrate W is horizontal has been described, but the present invention is not limited thereto. For example, the substrate W may be processed in a state in which the substrate W is made vertical or oblique.

The present invention is suitably used for a substrate processing apparatus.

What is claimed is:

1. A substrate processing apparatus comprising:
a chamber having a carry-in port through which an inside and an outside of the chamber communicate with each other and a substrate is carried in and a carry-out port through which the inside and the outside communicate with each other and the substrate is carried out;
a substrate holding portion that is disposed in the chamber and holds the substrates one by one; and
a turning mechanism that moves the substrate holding portion between a plurality of processing positions at which the substrate is processed with a processing liquid in the chamber by turning the substrate holding portion.

2. The substrate processing apparatus according to claim 1, comprising an immersion bath that is disposed at the processing position, stores the processing liquid, accommodates the substrate, and immerses the substrate in the processing liquid.

3. The substrate processing apparatus according to claim 2, wherein the immersion bath is provided with a support table that supports the substrate.

4. The substrate processing apparatus according to claim 1, wherein
the substrate holding portion is turned about a turning axis, and
the plurality of processing positions are located on a circle centered on the turning axis.

5. The substrate processing apparatus according to claim 4, wherein the substrate holding portion is turnable one or more rotations about the turning axis.

6. The substrate processing apparatus according to claim 4, wherein
the number of the plurality of processing positions is three or more, and
the substrate holding portion sequentially transfers the substrate to the plurality of processing positions in a predetermined turning direction about the turning axis.

7. The substrate processing apparatus according to claim 1, comprising a supporting member that is disposed inside the chamber and supports the substrate, wherein
a support position at which the supporting member is disposed is provided inside the chamber,
the support position is located closer to the carry-in port or the carry-out port than the plurality of processing positions, and
the substrate holding portion transfers the substrate from the support position to the processing position.

8. The substrate processing apparatus according to claim 1, wherein
the plurality of processing positions include a first processing position and a second processing position,
the substrate is processed with a first processing liquid at the first processing position, and
the substrate is processed with a second processing liquid different from the first processing liquid at the second processing position.

9. The substrate processing apparatus according to claim 1, wherein
the processing liquid includes a chemical liquid, and
the plurality of processing positions include at least two processing positions at which the substrate is processed with the same chemical liquid.

10. The substrate processing apparatus according to claim 1, wherein
the plurality of processing positions include a first processing position, a second processing position, and a third processing position,
the processing liquid includes a first chemical liquid, a second chemical liquid different from the first chemical liquid, and a rinse liquid,
the substrate is processed with the first chemical liquid at the first processing position,
the substrate is processed with the second chemical liquid at the second processing position, and
the substrate is processed with the rinse liquid at the third processing position.

11. The substrate processing apparatus according to claim 10, wherein
at the single third processing positions,
the substrate processed at the first processing position is rinsed, and
the substrate processed at the second processing position is rinsed.

12. The substrate processing apparatus according to claim 10, wherein
a plurality of the third processing positions are provided, and
the plurality of third processing positions include the third processing position at which the substrate processed at the first processing position is rinsed, and
the third processing position at which the substrate processed at the second processing position is rinsed.

13. The substrate processing apparatus according to claim 1, wherein
the substrate holding portion horizontally holds the substrate, and
the substrate holding portion includes a base that is disposed above the substrate and a plurality of chuck pins that protrude downward from the base and hold a circumferential edge of the substrate.

14. The substrate processing apparatus according to claim 1, comprising:
an immersion bath that is disposed at the processing position, stores the processing liquid, accommodates the substrate, and immerses the substrate in the processing liquid;
a processing liquid supplying portion that supplies the processing liquid to the immersion bath; and
a lifting/lowering mechanism that relatively moves the substrate holding portion and the immersion bath in an up-down direction, wherein
the lifting/lowering mechanism immerses the substrate in the processing liquid by moving the substrate holding portion or the immersion bath in a state in which the processing liquid is stored in the immersion bath.

15. The substrate processing apparatus according to claim 14, wherein
the substrate holding portion rotatably holds the substrate, and
the lifting/lowering mechanism immerses the substrate in the processing liquid stored in the immersion bath in a state in which the substrate holding portion rotates the substrate.

16. The substrate processing apparatus according to claim 14, wherein the lifting/lowering mechanism immerses the substrate in the processing liquid stored in the immersion bath in a state in which the processing liquid supplying portion supplies the processing liquid toward the substrate.
